(19) United States
(12) Patent Application Publication
(10) Pub. No.: US 2009/0073694 A1
(43) Pub. Date: Mar. 19, 2009

(54) Multifunction communications device

(75) Inventor: Robert F. Scannell, JR., Lebanon, NJ (US)

Correspondence Address: Deirdra M. Meagher, 24 Mine Street, Flemington, NJ, 08822, US

(73) Assignee: GlynnTech, Inc

(21) Appl. No.: 12/283,221

(22) Filed: Sep. 10, 2008

Related U.S. Application Data
(63) Continuation-in-part of application No. 11/062,039, filed on Feb. 18, 2005.

(51) Int. Cl. F21V 33/00; H05K 5/00

(52) U.S. Cl. 362/253; 361/730

(57) ABSTRACT

A decorative container includes: (a) a base; (b) a top component being removably attached to the base; (c) at least one access opening having a location being selected from the top, side, and bottom of the decorative container where the opening may be in at least one of the base and top component; (d) at least one electrical system component housing and at least one electrical system component requiring an electric power receptacle; and, (e) the decorative container is one of a plurality of decorative containers, each having local area network system communications capability for local area network system connection to at least one other decorative container. A pedestal is adapted to receive a nesting item atop it and adapted to perform at least one additional function in addition to pedestal. The pedestal includes: (a) a pedestal component having an enclosed structure with a bottom adapted to rest upon a horizontal surface, and having an electrical system component support within the enclosed structure, the pedestal component having a top with one of a male and a female nesting member adapted to receive the other of a male and female nesting member attached to a separate nesting item; (b) at least one electrical system component requiring an electric power receptacle; and, (c) the pedestal is one of a plurality of pedestals, each having local area network system communications capability for connection to at least one other the pedestal.

### REFERENCE TO RELATED APPLICATION

This application is a continuation-in-part of copending U.S. patent application Ser. No. 11/062,039, entitled “Multifunction-Adaptable, Multi-Component Devices, filed on Feb. 18, 2005, by the same inventor herein.

### FIELD OF THE INVENTION

The present invention relates to modular lamps, switch assemblies and enclosures that may be in various portable and non-portable forms, where such lamp fixtures, switch assemblies and enclosures: 1) may be associated with, in whole or in part, but are not limited to a floor lamp, table lamp, hanging lamp, wall fixture, desk lamp, boudoir lamp, track lighting system, ceiling light, recessed light, wall light, night light, chandelier and/or various forms of plant receptacle enclosures, urns, vases, figurines (The term “lamp” as used herein and in the claims is meant to include all of the foregoing lighting fixtures and any other lighting fixtures, including, but not limited to fixed (attached) and portable (movable) lighting fixtures, as well as fixed/portable hybrids and convertibles.); 2) may have one or more components with one or more of, but not limited to, the following characteristics: interchangeable, modular, adaptable, telescoping, inter-fastening, interlocking, and/or inter-connecting; and 3) may comprise components to support one or more of, but not limited to, the following functions: lighting, design, wireless communications applications, wireless sensor networking applications, security system applications, monitoring and intervention applications (surveillance, environmental, health and/or safety), home entertainment and sound system applications, a variety of switch activation functions, and other electronics-related applications. One of the primary utilities of the invention is to provide greater function, economic and environmental utility, design and variety for the end user or consumer (residential, commercial or governmental), and also the manufacturer, wholesaler, retailer, direct distribution provider, artisan and/or designer.

The present invention also relates to fixtures, appliances, scanners, enclosures, pedestals and/or bases with at least one interchangeable and modular component, where any one of the preceding may: 1) be or be associated with, but not limited to, lighting fixtures, air purifiers, sensors, bar code readers, radio frequency identification (RFID) tag readers, Optical Character Recognition (OCR) readers, dispenser containers (including, but not limited to, syringe dispensers), medicine or vitamin pill containers, vases, urns, figurines, sculptures, plant receptacles, flower pot receptacles, umbrella stands, mountings, and/or like containers, fixtures or housings; 2) have one or more components with one or more of, but not limited to, the following characteristics: interchangeable, modular, adaptable, processor-based, software-based, integrated, networked, telescoping, inter-fastening, interlocking, and/or inter-connecting; and 3) may comprise components to support one or more of, but not limited to, the following functions: lighting; medical/health; design; wireless and wire-based communications applications; wireless sensor networking applications; security system applications; monitoring applications (motion detection, surveillance, environmental or health/safety); home entertainment and sound system applications; air freshener and/or aromatic stress relief applications; air purifier, ionizer, and/or smoke filtering applications; insect, bug or pest repellent and/or insecticide applications; electrical outlet power strip applications; electrical cord applications; a variety of switch activation functions, and other electronics-related applications. One of the primary utilities of the invention is to provide greater function, economic and environmental utility, safety, design and variety for the end user or consumer (residential, commercial, hospital, institutional or governmental) with respect to utilizing many of the applications stated in the preceding sentence, and also provide greater function and utility for a variety of constituents or entities associated with the industries represented in the preceding sentence.

### INFORMATION DISCLOSURE STATEMENT

The following prior art references relate to the present invention fields of endeavor, and are of interest as prior art:

U.S. Pat. No. 4,167,080 to Richard C. Mickelson describes a plant carrier that is disclosed herein for holding a plant and it soil which includes an open-ended enclosure having a bottom integrally formed at its peripheral edge with an upwardly projecting continuous sidewall diverging outwardly from the bottom. The bottom further includes a downwardly depending cup-like portion having a plurality of holes or openings formed in the annular sidewall thereof for drainage purposes. A central opening is provided in the cup-like portion which is releasably matable with a projection centrally located on a dish member so that a snap-lock releasable engagement is produced. The releasable snap-lock members cooperate not only for releasably holding the dish member to the cup-like portion but serves as a self-locating system for aligning the dish member with the cup-like portion.

U.S. Pat. No. 5,353,546 to Ronald F. Bock describes a combination vase and air fragrance dispenser comprised of two interconnecting vessels, one to hold natural or artificial flowers, the other to hold air treatment material and dissipate fragrance to the atmosphere. Its two-vessel construction makes it possible to completely separate flowers and air treatment material, preventing contamination of the flowers.

U.S. Pat. No. 5,477,620 to Reinhold Holtkamp, Jr. describes a fragrance emitting plant watering system having a bottom vase providing a reservoir for water supply for a potted plant, an air freshener cartridge supported on the vase, a cap adapted to overtie the cartridge and having a central section for supporting a plant, and wherein the cap is adjustable relative to the vase for movement between a first position in which the cap is raised to variably expose the cartridge to emit fragrance, and a second position in which the cap substantially covers the cartridge to seal the cartridge and inhibit fragrance emission.

U.S. Pat. No. 6,315,434 B1 to Alan M. Long describes a one-piece, collapsible lampshade that is disclosed. The invention comprises an upper and lower ring, between which a shade is attached. Supports are permanently attached to one ring, with each support having a hinge part-way along its length. Receptacles are mounted on the opposite ring to receive the unattached end of the supports. The shade may be shipped and stored in the collapsed state by removing the unattached end of the supports from the receptacles and folding the supports flat. Because the shade is shipped and stored in one piece, it is easily and quickly assembled by the purchaser, without the risk of losing parts or of damage during shipment due to the movement of loose parts against one another.

U.S. Pat. No. 6,478,440 B1 to Thomas Jaworski et al. describes an air freshener dispenser that is taught having plug-through capability as well as a night light. The dispenser is a plug-in diffuser for such active materials as fragrances and air fresheners, and eliminates the consumer problem of loss of an electrical outlet, by providing a receptacle into which another plug may be inserted. The dispenser uses replaceable cartridges of material to be dispensed, and provides a night light for those who desire such.

U.S. Pat. No. 6,548,967 B1 to Kevin J. Dowling et al. describes a present invention that relates to smart lighting devices bearing processors, and networks comprising smart lighting devices, capable of providing illumination, and detecting stimuli with sensors and/or sending signals. Sensors and emitters can, in some embodiments, be removed and added in a modular fashion. Smart lighting devices and smart lighting networks can be used for communication purposes, building automation, systems monitoring, and a variety of other functions.

Unites States Patent Application Publication No. US 2001/0053283 A1 describes the present invention that suitably provides a method and apparatus for controlling the temperature of a liquid vaporizer heating element, and thereby the rate of evaporation and level of fragrance deliver for the same. In accordance with one exemplary embodiment of the present invention, the device may include a switch that suitably allows the temperature of various types of heating elements to be controlled for different levels of fragrance output. For example, an exemplary embodiment may include a two-pronged plug adaptable to typical outlets that might be found in residential homes or businesses. In accordance with another exemplary embodiment of the present invention, the electrical switch generally provides varying resistance values to the electric circuitry of the vaporizer such that, by changing the switch setting, the operating temperature of the wick is controlled and thus the rate of fragrance evaporation from the vaporizer.

United States Patent Application Publication No. US 2002/0080607 A1 describes a lamp securing device for securing a lamp to a housing including a retainer including a peripheral portion that bounds an opening of sufficient size for receiving a neck of the lamp. The retainer includes a plurality of flanges along the opening which engage the neck of the lamp to securely attach the retainer to the lamp.

Unites States Patent Application Publication No. US 2003/0156062 A1 describes a collapsible lamp shade that is provided, having removable supports to engage an upper ring and lower ring assembly in an interference fit.

Notwithstanding the above references, the present invention is neither taught nor rendered obvious thereby.

### SUMMARY OF THE INVENTION

The present invention provides for the means to have lighting fixtures, switch assemblies, and enclosures have one or more components or interconnected components that may be modified or replaced by, but not limited to, the end user or consumer without the need for such user to replace or not utilize all or most of the original remaining components (for example, a consumer, currently buying a new light fixture because of a better base design, replaces the original fixture, excluding the lamp shade). Advantageously, such lighting fixture, switch assembly and enclosure is adapted with one or more interconnecting, interlocking or inter-fastening component(s) to allow for lighting fixture, switch assembly and/or enclosure component modification or replacement. The modifications for such lighting fixture and components may allow for greater lighting and design utility, as well as other utilities and applications (non-lighting) that may be advantaged by one or more of the following lighting fixture's characteristics: prevalence and location in most interior and surrounding exterior living and working spaces; greater economy, design and function from utilizing the lighting fixture's structure and associated power source(s); and utilizing decorative and functional enclosures and related interconnected components that may be redeployed for the same or other utilities. In addition, the decorative and functional enclosures contemplated in this invention may also apply solely to plant container and/or receptacle enclosures where such enclosures provide the means for supporting the following conditions: support a variety of designs, components and materials that are not as optimally supported in prior art; allow for convenient attachment and detachment of the plant system (plant—cut and potted—and plant receptacle(s)) to and from the enclosure; and may also allow for interconnected and interchangeable components such as, but not limited to, enclosure rings (that will be described and illustrated in the Detailed Description and Drawings sections) that allow for facilitating plant care, as well as changing the enclosure configuration without the need to replace the entire configuration.

The present invention also provides for the means to have a variety of fixtures, appliances, dispensers, enclosures (including cabinetry), pedestals and bases function with greater utility (or function with multiple utilities that may not be associated with such embodiments in their present form) to enhance the end user's use, safety, convenience and pleasure of a living or work space. Such invention products and/or systems may have one or more components or interconnected components that may be modified, replaced, or added to such product or system by, but not limited to, the end user or consumer as the user desires.

A present invention decorative container includes: (a) a base; (b) a top component, including at least a hollow housing, the top component being removably attached to the base; (c) at least one access opening having a location being selected from the top, side, and bottom of the decorative container where the opening may be in at least one of the base and top component; (d) at least one electrical system component housing and at least one electrical system component requiring an electric power receptacle located on at least one of the base and the top component above, the at least one electrical system component being selected from the group consisting of a lighting fixture, a power receiving receptacle, an electrical device, an electronic device, and a communications device, the power receiving receptacle being connected to a power source having power for providing appropriate voltage and current to power at least one electronic device selected from the group consisting of an AC powered device, a wireless phone, a timer, a sensor device, and a low voltage rechargeable electronic device; and, (e) the decorative container is one of a plurality of decorative containers, each of the decorative containers having local area network system communications capability for local area network system connection to at least one other decorative container.

In some preferred embodiments of the present invention, the decorative container of is selected from the group consisting of urns, pot enclosures, vases, umbrella holders and storage containers.

In some preferred embodiments of the present invention, the decorative container comprises the power receiving receptacle where the power receiving receptacle provides sufficient voltage and current to recharge a portable low voltage rechargeable device.

In some preferred embodiments of the present invention, there are at least two top components, each having at least one different characteristic from the other, the different characteristic being selected from the group consisting of dimension, color, shape, design, and function the at least two top components being interchangeable with one another.

In some preferred embodiments of the present invention, the top component is removably attached to the base with quick release attachment means selected from the group consisting of threads, springy snap latches, pins, screws and twist and lock keys and keyways.

In some preferred embodiments of the present invention, the light fixture includes at least one socket, an on/off means and means for an electrical circuit connection.

In some preferred embodiments of the present invention, the base has a circular recess adapted to removably connect to the top component, and the top component has a circular bottom adapted to removably fit into the circular recess.

In some preferred embodiments of the present invention, the base has at least one non-circular recess adapted to removably connect to the top component and the top component has a bottom adapted to removably fit into the at least one non-circular recess.

In some preferred embodiments of the present invention, there is at least one electric power receptacle and it is located on the base.

In some preferred embodiments of the present invention, the at least one electric power receptacle and it is located on the open top component.

In some preferred embodiments of the present invention, the at least one of the base and the top component includes housing and means for an electrical circuit connection to provide power to at least two the electrical system components, at least one of the power-consuming components being a light fixture, and at least one of the power-consuming components being selected from the group consisting of entertainment components, local area networked components, wide area networked components, communications components and portable electronic devices.

In some preferred embodiments of the present invention, one of the electrical system components is an entertainment component being selected from the group consisting of an electronic audio playing device, a radio, an embodiment that comprises an amplifier, a speaker, and a communications circuit connection, an electronic game apparatus, and a video apparatus.

In some preferred embodiments of the present invention, one of the electrical system components is a communications component being selected from the group consisting of an embodiment that comprises a phone, a data communications transceiver, a data communications router, a data communications access point, and a wireless remote control unit.

In some preferred embodiments of the present invention, one of the electrical system components is an electronic device having a central processor and memory.

In some preferred embodiments of the present invention, one of the electrical system components is an electronic audio playing device selected from the group consisting of satellite radios, CD players, players with storage media, and personal digital assistants.

In some preferred embodiments of the present invention, one of the electrical system components is at least one local area networked component being selected from the group consisting of wirelessly controlled device, a reduced function device, a full function device, a timer, and a high speed data networked device.

In some preferred embodiments of the present invention, there are at least two diverse electrical system components selected from the group consisting of entertainment components, local area networked components, wide area networked components, communications components and portable electronic components.

In some preferred embodiments of the present invention, the at least two power-consuming components are powered by AC electricity.

In some preferred embodiments of the present invention, the power is from a power source selected from the group consisting of batteries, solar cells, fuel cells and combinations thereof.

In some preferred embodiments of the present invention, one of the electrical system components is an alarm, an air freshener, an air ionizer, an air purifier, and an air deodorizer.

In some preferred embodiments of the present invention, the decorative container also includes at least one activation means of at least one of the power-consuming components where the activation means is selected from the group consisting of a motion sensor, a gaseous element detector, a timer, an ambient sensor, and a communications processor.

In some preferred embodiments of the present invention, the electrical system component is selected from the group consisting of security devices, sensors, bar code readers, radio frequency identification tag readers, and optical character recognition readers.

In an alternative embodiment of the present invention, a pedestal is adapted to receive a nesting item atop it and adapted to perform at least one additional function in addition to pedestal. The pedestal includes: (a) a pedestal component having an enclosed structure with a bottom adapted to rest upon a horizontal surface, and having an electrical system component support within the enclosed structure, the pedestal component having a top with one of a male and a female nesting member adapted to receive the other of a male and female nesting member attached to a separate nesting item; (b) at least one electrical system component requiring an electric power receptacle located on at least one of the pedestal component and the separate nesting item above, the at least one electrical system component being selected from the group consisting of a lighting fixture, a power receiving receptacle, an electrical device, an electronic device, and a communications device, the power receiving receptacle being connected to a power source having power for providing appropriate voltage and current to power at least one electronic device selected from the group consisting of an AC powered device, an air freshener, a sensor device, a timer, and a low voltage rechargeable electronic device; and, (c) the pedestal is one of a plurality of pedestals, each of the pedestals having local area network system communications capability for local area network system connection to at least one other the pedestal.

In some preferred embodiments of the present invention pedestal, the pedestal is selected from the group consisting of cubic pedestals, square top footprint pedestals, vertically elongated pedestals and horizontally elongated pedestals.

In some preferred embodiments of the present invention pedestal, the power receiving receptacle provides sufficient voltage and current to recharge a portable low voltage rechargeable device.

In some preferred embodiments of the present invention pedestal, there are at least two interconnecting pedestal components, each having at least one different characteristic from the other, the different characteristic being selected from the group consisting of dimension, color, shape, design, and function, the at least two interconnecting pedestal components being interchangeable with one another.

In some preferred embodiments of the present invention pedestal, the pedestal includes a base and the pedestal component is removably attached to the base with quick release attachment means selected from the group consisting of threads, springy snap latches, pins, screws and twist and lock keys and keyways.

In some preferred embodiments of the present invention pedestal, the light fixture includes at least one socket, an on/off means and means for an electrical circuit connection.

In some preferred embodiments of the present invention pedestal, the base has a circular recess adapted to removably connect to the pedestal component, and the pedestal component has a circular bottom adapted to removably fit into the circular recess.

In some preferred embodiments of the present invention pedestal, the base has at least one non-circular recess adapted to removably connect to the pedestal component and the pedestal component has a bottom adapted to removably fit into the at least one non-circular recess.

In some preferred embodiments of the present invention pedestal, there is at least one electric power receptacle and it is located on the base.

In some preferred embodiments of the present invention pedestal, there is at least one electric power receptacle and it is located on the pedestal component.

In some preferred embodiments of the present invention pedestal, the pedestal component includes housing and means for an electrical circuit connection to provide power to at least two electrical system components, at least one of the electrical system components being a light fixture, and at least one of the electrical system components being selected from the group consisting of entertainment components, local area networked components, wide area networked components, communication components and portable electronic devices.

In some preferred embodiments of the present invention pedestal, one of the electrical system components is an entertainment component being selected from the group consisting of an electronic audio playing device, a radio, an embodiment that comprises an amplifier, a speaker, and a communications circuit connection, an electronic game apparatus, and a video apparatus.

In some preferred embodiments of the present invention pedestal, one of the electrical system components is a communications component being selected from the group consisting of a wireless phone and base, a data communications transceiver, a data communications receiver, a data communications router, a data communications access point, and a wireless device controller.

In some preferred embodiments of the present invention pedestal, one of the electrical system components is an electronic device having a central processor and memory.

In some preferred embodiments of the present invention pedestal, one of the electrical system components is an electronic audio playing device selected from the group consisting of satellite radios, CD players, players with storage media, and personal digital assistants.

In some preferred embodiments of the present invention pedestal, one of the electrical system components is a local area networked component being selected from the group consisting of a wirelessly controlled device, a wireless remote controller, a reduced function device, a full function device, and a high speed data networked device.

In some preferred embodiments of the present invention pedestal, there are at least two diverse electrical system components selected from the group consisting of entertainment components, local area networked components, wide area networked components, communications components and portable electronic components.

In some preferred embodiments of the present invention pedestal, the at least two electrical system components are powered by AC electricity.

In some preferred embodiments of the present invention pedestal, the power is from a power source selected from the group consisting of batteries, solar cells, fuel cells and combinations thereof.

In some preferred embodiments of the present invention pedestal, one of the electrical system components is selected from the group consisting of an alarm, a wireless communications device, a wired communications device, an air freshener, and an air deodorizer.

In some preferred embodiments of the present invention pedestal, the pedestal also includes at least one activation means of at least one of the electrical system component where the activation means is selected from the group consisting of a motion sensor, a gaseous element detector, a timer, an ambient sensor, and a communications processor.

In some preferred embodiments of the present invention pedestal, the electrical system component is selected from the group consisting of air fresheners, air filters, air purifiers and air ionizers.

In some preferred embodiments of the present invention pedestal, the component is operatively integrated with at least one modular component being selected from the group consisting of a motion sensor, a timer, a communications device, an ambient sensor, and a gaseous element detector.

In some preferred embodiments of the present invention pedestal, which further includes at least one speaker nestable on the top of the pedestal.

One of the major advantages of the present invention is to utilize the numerous functions that are available from a variety of electronics (including, but not limited to switches, processor-based and/or electrically powered) and communications products in a more adaptable, integrated and enhanced means with new utilities without the need for purchasing such products in an integrated system all at once or cluttering the living and work space with such items when purchased incrementally in standalone form. One of the means for providing such utilities is to incorporate such numerous functions in systems comprising at least one or more modular components adapted for being comprised, integrated, networked or connected of, in or with other components, fixtures, appliances, dispensers, enclosures, cabinetry, pedestals and bases or be integrated or networked with other such systems with the parts, materials and characteristics described herein.

Advantageously, the invention embodiments may be adapted with one or more interconnecting, integrated, networked, interlocking or inter-fastening component(s) with associated electrical, communications (such as, but not limited to, ZigBee™), data interface and/or circuitry connections (such as, but not limited to, USB for certain data and networked connections), as appropriate, to support interaction (in a variety of forms), modification, upgrade or sub-component replacement.

### BRIEF DESCRIPTION OF DRAWINGS

The present invention should be more fully understood when the specification herein is taken in conjunction with the drawings appended hereto wherein:

FIG. 1 is an illustration of one embodiment of a present invention table lamp with interchangeable modular components;

FIGS. 2, 3, 4 and 5 illustrate another embodiment of a present invention table lamp with a ring component, in various stages of assembly;

FIGS. 6, 7, 8 and 9 illustrate another embodiment of a present invention table lamp without a ring component, in various stages of assembly;

FIGS. 10, 11, 12 and 13 show another present invention table lamp in various stages of assembly;

FIG. 14 shows a side view of a base component that may be included with present invention lamps, pedestals, decorative containers and other present invention devices;

FIGS. 15, 16 and 17 show a side view, a top view and a bottom view, respectively, of one preferred lower component of present invention lamps, pedestals, decorative containers and other present invention devices for modular assembly therewith;

FIG. 18 shows a front view of one embodiment of a present invention central shaft configuration with electronic power supply and/or electronic component capabilities for modular inclusion of present invention lamps, pedestals, decorative containers and other present invention devices;

FIG. 19 shows a front view of a present invention electrical/electronics housing component for the central shaft configuration with electronic power supply and/or electronic component capabilities for modular inclusion of present invention lamps, pedestals, decorative containers and other present invention devices;

FIG. 20 shows a front view of another embodiment of a present invention top 1 shaft configuration with electronic power supply and/or electronic component capabilities for modular inclusion of present invention lamps and other present invention devices;

FIG. 21 shows a front view of another embodiment of a present invention top shaft configuration with electronic power supply and/or electronic component capabilities for modular inclusion of present invention lamps and other present invention devices;

FIGS. 22, 23 and 24 show electrical/electronic assembly components for a present invention device with lighting;

FIGS. 25 and 26 show a present invention modular lamp with interchangeable parts and a present invention modular vase enclosure with interchangeable parts, having the same lower component, respectively;

FIGS. 27, 28, 29 and 30 show another present invention modular lamp with interchangeable parts and a present invention modular urn with interchangeable parts, having the same lower component, respectively;

FIGS. 31, 32, 33, 34, 35, 36 and 37 show various stages of a present invention modular table lamp and a modular table flower pot enclosure system with interchangeable components;

FIGS. 38, 39 and 40 show a top view of a present invention modular table lamp in various stages of assembly where the assembly means may apply to a present invention lamp, pedestal, decorative container or other present invention device;

FIGS. 41, 42 and 43 show another present invention modular table lamp in various stages of assembly where the assembly means may apply to a present invention lamp, pedestal, decorative container or other present invention device;

FIGS. 44, 45, 46, 47, 48 and 49 illustrate a present invention modular standing floor lamp with interchangeable components in various stages of assembly being converted to a floor lamp with a table and magazine rack;

FIG. 50 shows one embodiment of a present invention hanging modular chandelier with interchangeable components;

FIGS. 51 and 52 illustrate a present invention ceiling lamp with interchangeable modular components;

FIGS. 53 and 54 show a present invention modular wall lamp with interchangeable parts;

FIG. 55 shows a present invention planter enclosure component.

FIGS. 56, 57 and 58 illustrate various aspects of a present invention multi-utility lamp fixture with multi-utility electrical and electronic assembly and housing components and FIG. 59 illustrates the legend for these figures;

FIGS. 60, 61, 62 and 63 show some alternative and some identical components with the support illustrations of FIGS. 57 and 58 above;

FIGS. 64, 65 and 66 show various present invention embodiments of motion sensor and wireless communication modules having interchangeable components that may be included with present invention lamps, pedestals, decorative containers and other present invention devices;

FIGS. 67 and 68 illustrate a present invention vase enclosure system with a vase enclosure ring and motion detector, timer, aromatic dispenser and oil cartridge modules;

FIGS. 69, 70, 71 and 72 illustrate present invention vase enclosure components and infrastructure that support motion detector, timer, aromatic dispenser, oil cartridge modules;

FIGS. 73, 74, 75, 76, 77 and 78 illustrate various present invention interchangeable modular component pedestal systems;

FIGS. 79, 80, 81, 82, 83, 84 and 85 show various present invention pedestal system modules and infrastructure that may also apply to present invention lamps, decorative containers and other present invention devices;

FIGS. 86, 87 and 88 illustrate various embodiments of a present invention urn with interchangeable modular components;

FIGS. 89, 90 and 91 show various stages of the present invention modular collapsible lamp with interchangeable components;

FIGS. 92, 93, 94, 95 and 96 show structural details of the present invention modular collapsible lamp with interchangeable components;

FIGS. 97A, 97B and 97C show a schematic of a present invention pedestal.

### DETAILED DESCRIPTION

Currently available lighting fixtures and related components serve limited utility and design functionality. They are purchased, often amongst limited varieties, to best serve a certain set of utility and/or design needs and often unnecessarily replaced in their entirety when only a subset of such utility and/or design needs change. In other instances (when the end user may change other utility and/or design aspects of a room, living space, or work space), lighting fixtures and components that may not best fit the utility and design functions of a revised room, living space or work space, may remain for a variety of reasons, such as those attributed to economic, inconvenience or limited alternative factors. In addition, other room systems' components that may benefit the end user's utility and/or safety in a living, shopping, leisure, entertainment or work space may not be deployed in such area due to limited space for such component, proximity to power outlets, incompatibility with room design, and/or other factors noted herein. Therefore, it is an object of this invention to facilitate synergistically enhanced utility and/or design for lighting fixtures and surrounding room systems and/or components by providing means for removing and/or adding and/or interchanging one or more interconnecting components that best satisfy the utility and/or design requirements for such lighting fixture and room system(s) without the need to replace most or all of an entire lighting fixture or forego the benefits of increasing the utility of various room systems (such benefits and room systems are noted in this section).

An application of this invention, though this invention is not limited to such application, is to allow artisans, designers, media, and/or entertainment companies to extend their works, product lines, properties or designs in other forms. For example, in accordance with the present invention devices, an artisan or designer may offer lighting fixture lower lamp and/or base components that may be interchangeable with other lower lamp and/or base components and match with a variety of other room or living space products and design themes. Such artisan or designer would offer the consumer (residential or commercial) a greater variety of design and utility to choose from, and interchange with, for a variety of design or event themes that may pertain to, but are not limited to, holiday, celebration, memorabilia, seasonal, sports, various collectibles, souvenirs, alma mater and/or charities. Such design themes may be extensions from, but not limited to, drapery or linen patterns, pillow, furniture, throw, placeware, chinaware, figurines, crystalware, wall patterns, wallpaper, paint, stucco, personal family or other theme related presentations, e.g. alma mater, favorite pro team, hobby or the like. In fact, the present invention devices allow for the use of any design, color or other characteristic that suits the imagination of the designer or customer.

Another application of this invention, though this invention is not limited to such application, is to allow for a replaced lighting fixture component to be utilized in another manner. For example, a table lamp may have a lower lamp portion, base and components that may be interchangeable with another lower lamp portion, base and components. One of the replaced base components may function as an enclosure for a vase, as a vase for dry floral arrangements, or be adapted (by plugging apertures with components to enable the holding of water) to be a vase for cut flowers. Such vase enclosure may also have a ring enclosure at its top area. Such vase and ring enclosures may be in various forms and designs. An example of one of the designs and functions contemplated in this invention is to allow for the user to have a container and/or container enclosure with ornate designs and figures that is easy to maintain and clean and minimizes concern of chipping and breaking as one cleans, stores or handles flowers in such container. For further illustration, popular prior art consists of containers that have floral shapes, such as daffodils, in various forms and shapes at the top of the container. Such top edge configurations are apt to be chipped or broken, as one cleans or handles such container. Some present invention embodiments may have container configurations utilizing the same preceding floral design that allow for more convenient cleaning while minimizing concern and likelihood of breakage, because the top of the container with the orriate floral shapes may consist of a vase enclosure ring or vase ring (depending on the application) that may be removed from the top of the vase or vase enclosure to enable easier container cleaning and storage and minimize breakage. Such interconnected vase and ring configuration also allows for economical utility and variety of design. For example, the user may utilize the same vase or vase enclosure base and adapt a variety (shapes and patterns) of ring enclosures to such base to change the overall appearance of the container. It is also contemplated in this invention that such vase or vase enclosure and ring configuration may be designed either as part of the invention light fixture system with interchangeable components or solely as a vase or vase enclosure system with interchangeable ring components.

Another example of the interchangeable and utility concepts stated in the preceding paragraph is utilizing enclosure or base components as urns. Such urn may have a base and/or urn ring component that may support or enclose modules that may perform, for example, integrated motion detector, timer, communications, and air freshener functions, as well as security functions, where the modules may reside in and/or be networked with the urn and/or urn components.

Another example of the interchangeable and utility concepts contemplated in this invention is utilizing enclosure or base components, base rings and base stands for a variety of applications such as, but not limited to, ornamental mood lights, night lights, event or holiday (such as a lit jack-o-lantern) illuminated enclosures. In this application, one or some of the components of this illuminated enclosure configuration may have originally been part of a table lamp, such as, but not limited to, a lower lamp component and/or base.

Another application of this invention, though this invention is not limited to such application, is to allow the consumer (residential, commercial, industrial or governmental) to utilize a variety of lighting designs and utility components as desired, while minimizing the use of space and storage requirements for non-utilized components. For example, rather than having to store an entire theme or holiday lamp, one may only be required to store a lower lamp and/or base component. As previously noted, even such lower lamp and/or base may support another utility function, such as a storage component. Such lower lamp and/or base storage component may also be fashioned with a variety of rings for open or closed storage applications.

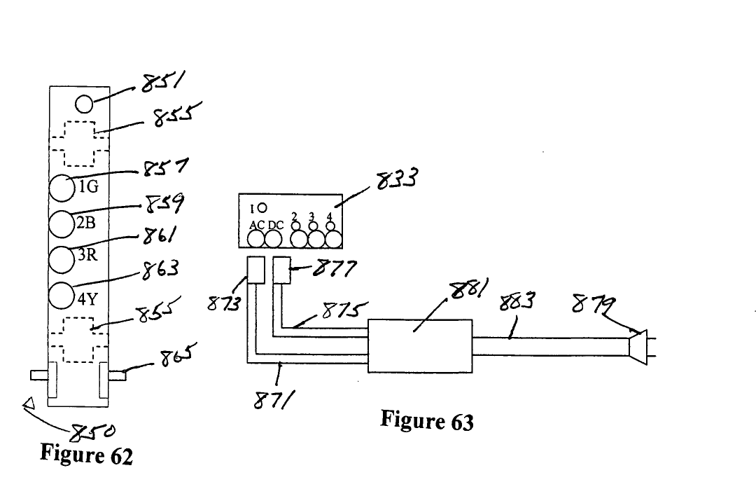

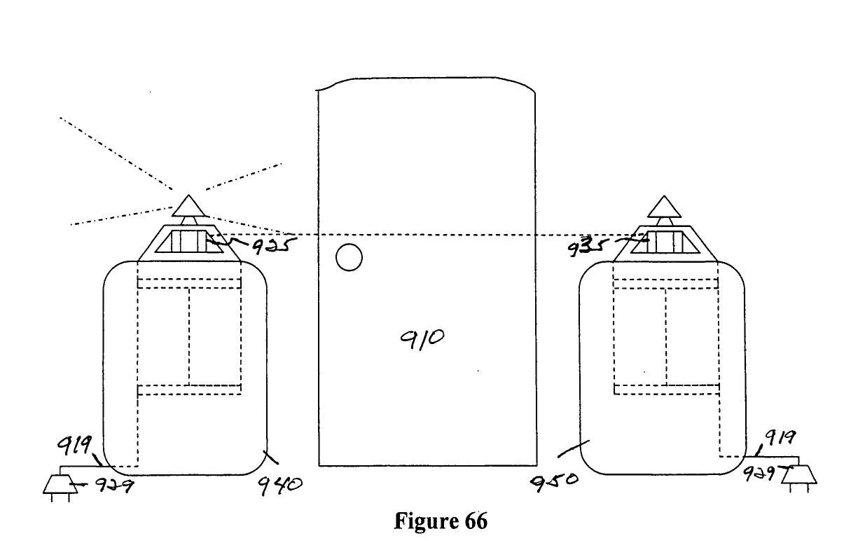

Another application of this invention, though this invention is not limited to such application, is to provide the consumer a more economical alternative to upgrading lighting fixtures or changing lighting fixtures. For example, the user may only be required to purchase a lower lamp and/or base component rather than entire lamp. In addition, the user may also purchase more value, because the user may purchase a lower lamp or lighting enclosure that is a greater work of art or provides greater economy in comparison to the price of paying for an entire lamp. One example of the economical options and utility of this invention is a sample floor lamp version of this invention (see FIGS. 62 through 67 inclusive) with a variety of components such as, but not limited to, a top component portion, an upper component portion, a lower component with one or more ring(s), a bottom base portion, all modular and interchangeable, and an optional removable mid table portion and/or a magazine rack portion (FIGS. 66 and 67). The user may initially purchase this example of a present invention floor lamp without the table or magazine rack components, and may subsequently opt to purchase a mid table portion (from a variety of styles and craftsmanship) at a later date. In addition, some users may wish to add a magazine rack while others may not.

Another application of this invention, though this invention is not limited to such application, is to utilize space, such as, but not limited to, desk, table, bureau or breakfront space, more efficiently and utilize and/or display items, themes or images that appeal to the user. For example, a present invention device base component may have or be comprised of, but not limited to, one or more of the following components and/or shapes: display case; clock(s); ornament(s); figurine(s); doll(s); carousel(s); building/housing/castle structures; pictures; paintings; prints; lithographs; stained glass; illuminating components (internal and/or external top portion, lower portion and/or base components—from bulb to light-emitting fiber optic components); battery component(s) to provide back-up lighting or power for other uses; picture and/or photograph enclosures, frames, and/or inserts; shadow boxes; display screen(s); software; audio; sports themes; nature themes; book, movie or television media, figurines, assemblies or themes; vase; urn; wooden; china; porcelain fixtures; timer; alarm; and temperature and/or other measuring instruments; flower pots; and planters.

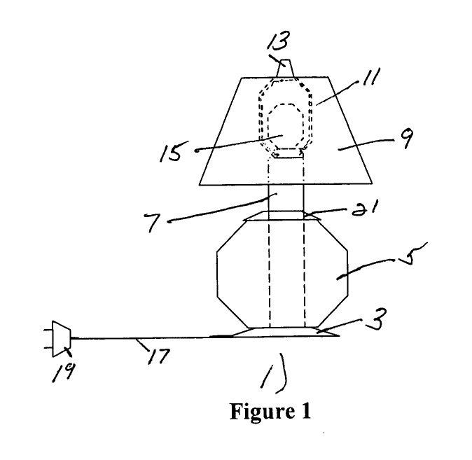

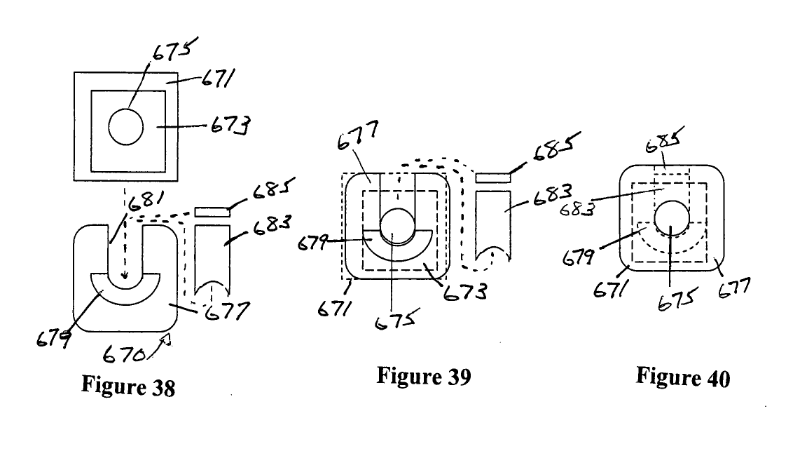

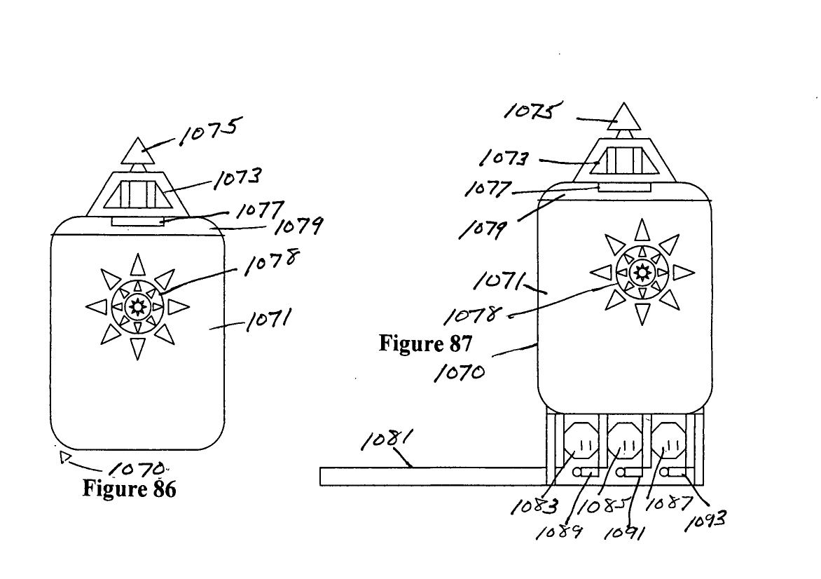

Another application of utilizing the lower lamp component as a means to improve utilization of space is to leverage other lighting fixture components in conjunction with the lower lamp component to add utility to the lighting fixture and/or surrounding room system(s). For example, a lower lamp component, may serve as an enclosure for a wireless network router, where such router component may interface to an electrical/electronics housing component 829 (FIG. 60), as described further in the narrative, through an aperture 859 (FIG. 62) in a lamp central shaft component 850 (FIG. 86)), where such router component may have a user interface that may be accessed by lifting a ring component 21 (FIG. 1) from the top of the lamp lower portion component 5 (FIG. 1). Another example of, but not limited to, a lower lamp component configuration that may facilitate access to (a) user interface(s) of electronics and/or communications equipment that, in whole or in part, may be housed in a lower lamp component is illustrated in FIGS. 38 through 43, where such lower lamp enclosure is interconnected to the shaft and/or base stand component(s) from the side of the lamp shaft. Such configuration may support access to, but not limited to, one or more user interface components by opening the side of the lamp lower portion or top of the lamp lower portion.

It is contemplated in this invention that certain upper portion, lower portion and base components, working together or separately, and where only one or the other or both the lower component and base component may comprise and/or enclose, in whole or in part, some of, but not limited to, the following components: equipment to support or interconnect with wireless sensors (such as, but not limited to “smart dust”, where such smart dust/computerized or nano-technology-based sensors may be interconnected to an appropriately loaded light fixture power source component to enable such sensor to be in an on-state condition—one of the limitations of “smart” dust is that they are in an off-state condition for most of the time; interconnecting such computerized sensors to light fixtures, having certain components that are connected to a certain power source and, in some cases, protected from heat disbursement from a light fixture, that enables the sensor to be in an on-state, would enable an on-state network of sensors or “motes” to perform a variety of applications with increased utility due to being in an on-state—from security to environmental to health to safety applications for commercial, environmental, governmental, security, industrial, elder and/or patient care and residential use—the prevalence and locations of light fixtures in interior and surrounding exterior spaces strongly complements such wireless sensor networks and the interconnection to other wireless sensor networks that may be powered via battery sources or intermittent power sources); security system equipment (such as, but not limited to, hidden audio or video equipment); monitoring equipment (such as, but not limited to monoxide detectors); and/or home entertainment electronics, speaker or amplifier equipment.

Another application of the present invention, though this invention is not limited to such application, is to allow for a variety of lighting technologies, switches, housings, bulbs and/or room system applications (such as, but not limited to, the applications noted in the preceding paragraph) in a modular, interchangeable and more economical fashion as the user desires, to minimize the need for the user to replace or buy an entire portable or non-portable lighting fixture, lighting accessory, lighting projector product or other room system product(s). Such lighting technologies may consist of, but are not limited to, LED, incandescent and/or fluorescent components. Such switches may be, but are not limited to, lighting illumination settings, timer settings, multiple switch settings for multiple light bulb housings, blinking interval settings, wireless and/or radio frequency signal activation, remote control activation, room light activation, motion detector activation, sound wave or voice recognition activation, and/or touch activation. Such housings may consist of, but are not limited to, single or multiple bulb sockets and enclosures to accommodate a variety of bulb and lighting applications. Such applications may be comprised of, but are not limited to, one or more of the following components: basic lamp lighting; projected lighting; projected image lighting; and/or projected display lighting. Other such applications may be associated with, but are not limited to, wireless applications, such as, but not limited to, cordless phone signal repeaters, transmitters or receivers, or Wi Fi or related technology signal repeaters, transmitters or receivers or sound wave signal repeaters, transmitters or receivers, or home entertainment applications, such as, but not limited to, speakers. For example, this invention accounts for, but is not limited to, interconnecting, modular components that may be comprised in a table lamp or other portable or non-portable lighting fixture that is advantageously positioned in the surrounding room area and may consist of sensor(s) (such as, but not limited to, those stated in the preceding paragraph), (an) antenna(e), microphone(s), camera(s), a speaker(s) and other associated equipment to facilitate environmental monitoring, cordless, wireless and/or radio transmissions as well as audio, video and/or security system communications or home entertainment. It is contemplated, but not limited to such contemplation, that the upper portion of the lighting fixture may support and/or house the components, in whole or in part, stated in the preceding sentence.

Another application of this invention, though this invention is not limited to such application, is to allow for a greater variety of lighting enclosure or display products, as the user desires, without the need for the user to replace or buy an entire lighting or lighting accessory product. Such enclosure products may be comprised of, but are not limited to, lamp shades, or glass, crystal, or plastic enclosures or fiber optic components that may perform one or more of the following functions: illuminate, display, mirror, or project light. Such lighting enclosure products may have a variety of unique designs such as those depicting large floral leaves that may be interconnected to and illuminate light over a functional flower pot base that contains flowers, dirt, and/or means for growing plants. Such lighting and lighting enclosure products may also function as a sub-component of a lighting fixture system. For example, a floral leaf lighting enclosure may display (a) figurine(s) that is (are) interconnected or in close proximity to the lighting fixture in order to be illuminated or considered as part of the lighting fixture theme design.

Another application of the present invention, though this invention is not limited to such application, is to allow for a variety of lighting fixture illumination and/or heights as the user desires, without the need for the user to replace or buy an entire lighting or lighting accessory product. Such utility is possible, because the lighting fixture may have an interconnecting component comprised of a telescoping and/or modular pole or shaft which may have means for other poles or shafts to interconnect in a horizontal, vertical or diagonal fashion. In additional to removable and interchangeable sections and to telescopic sections with or without the separate multiple sections, various folding and/or hinged sections may be included to adapt the present invention devices to both vertical and non-vertical dimensional and positional changes. Such units may include electrical, electronic and light and sound interconnecting components to allow for powering the various optional electrical and electronic components, lighting units, etc. that may interconnect to such poles or shafts.

As mentioned, the present invention device interconnecting power connection components described herein may include electrical interconnecting components to allow for powering and protecting the lighting unit(s) and other electronics component(s) associated with this invention. Such interconnecting components are comprised of any known and acceptable electrical conducting and resistance materials such as, but not limited to, copper, other metallic conducting elements and durable plastic and heat resistant elements.

Another application of the present invention relates to its interchangeable and interconnected components supporting other utility functions. For example, a table lamp lower component may be replaced and utilized, separately or with other different utility components and rings and other components, such as a flower pot or plant container and/or other enclosure. Such flower pot lower component and ring enclosures may be in various forms and designs and may comprise or support various components and functions. It is also contemplated in this invention that flowerpot base and plant receptacle enclosures also may be available in various forms and designs and may comprise or support various components and functions.

One of the benefits of such plant receptacle enclosure system is to support a greater variety of aesthetic design while allowing for easy and appropriate care of plants. For example such ring, lower component and/or base and/or bottom enclosure material, whole or in part, may be, but are not limited to, porcelain or inlaid woods. They may reflect design patterns from, but not limited to, china, fabric, drapery or linen patterns and/or shapes that may complement furniture pieces or other living or work space shapes. They may also comprise components that may serve other utilities such as, but not limited to, monitoring systems, solar power, and various electronics or communications systems as previously stated in this narrative, along with surge and lightning protectors. Such enclosures could be collectible limited editions. Such enclosures would be convenient to interlock or interconnect to allow for easy plant care.

Another application of the utility of such enclosure system is to support a variety of nutrient components and systems to the plant system without disturbing the aesthetic appearance of such system. For example, one ring enclosure design may have a width and depth to not only cover the top and inner side of the plant receptacle, but also be wide enough (or have varying degrees of width) to encase, in whole or in part, nutrient and water packages or watering tubes that may rest on or within the soil of such plant system and release contents over time. This type of application maintains the aesthetic appearance and intent of the plant system and container while providing minimal maintenance and labor cost and/or time to both commercial and residential users.

Other applications of this type of present invention enclosure system are, but not limited to, table centerpieces, party themes, seasonal designs, holiday designs, shapes, and personal preference features, such as described above, that may encase around a plastic plant or terra cotta assembly instead of traditionally shaped enclosures that allow for the enclosed planter or flower pot to be seen. Such interconnected plant receptacle base enclosure and ring configuration also allows for economical utility and variety of design. For example, the user may utilize the same lower component and/or base enclosure and adapt a variety (shapes and patterns) of ring enclosures to such base to change the overall appearance of the container and nutrition maintenance of the plant system (as noted in the preceding paragraph).

Another component of this invention is to provide an optional lower component enclosure insert or plant receptacle/flower pot stand (which may be height adjustable), in those instances when the plant receptacle may not have sufficient height to support the proper height alignment of the plant system in relation to the top of the receptacle and ring enclosure system. It is also contemplated in the present invention that such plant receptacle enclosure and ring configuration may be designed either as having interchangeable components associated with the invention light fixture system or solely as a plant receptacle enclosure system with interchangeable ring components.

Another application of the present invention is to provide utility for commemorating or communicating events (including, but not limited to, personal, professional, corporate or sports), holidays, celebrations, retreats, vacations, inspiration or advertising by providing lamp base, vase, vase enclosure, urns, flower pot enclosures or plant receptacle enclosures and/or enclosure rings with one or more of, but not limited to, the following on such enclosure: verse, design themes, scenes, pictures, logos, dates and/or personalized engraving, plaques and/or print. Such verse may come from a variety of sources, such as poetry, greeting card(s), scripture, quotes, and/or books.

It is also contemplated in the present invention that the modular components stated herein that are associated with the light fixtures and plant receptacle enclosures stated herein may also be comprised in light fixtures and plant receptacles and enclosures as non-modular integral components, whereas such components do not exist in prior art light fixtures and plant receptacle and enclosures.

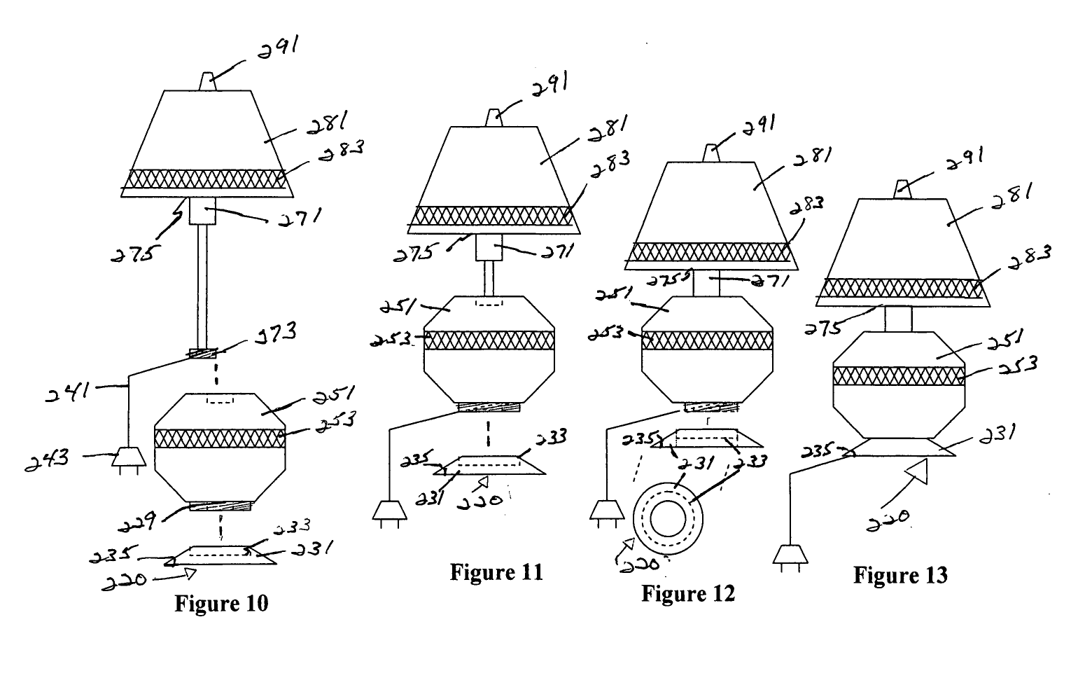

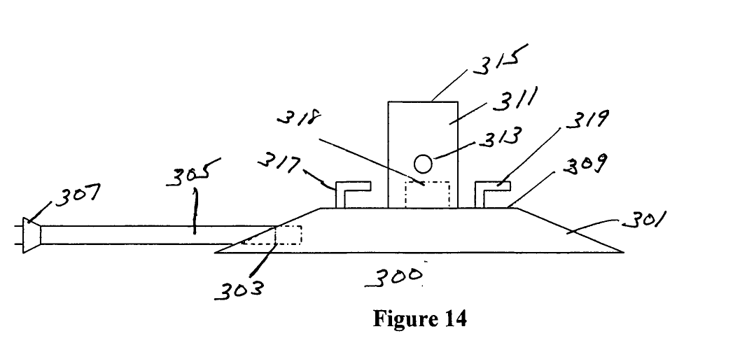

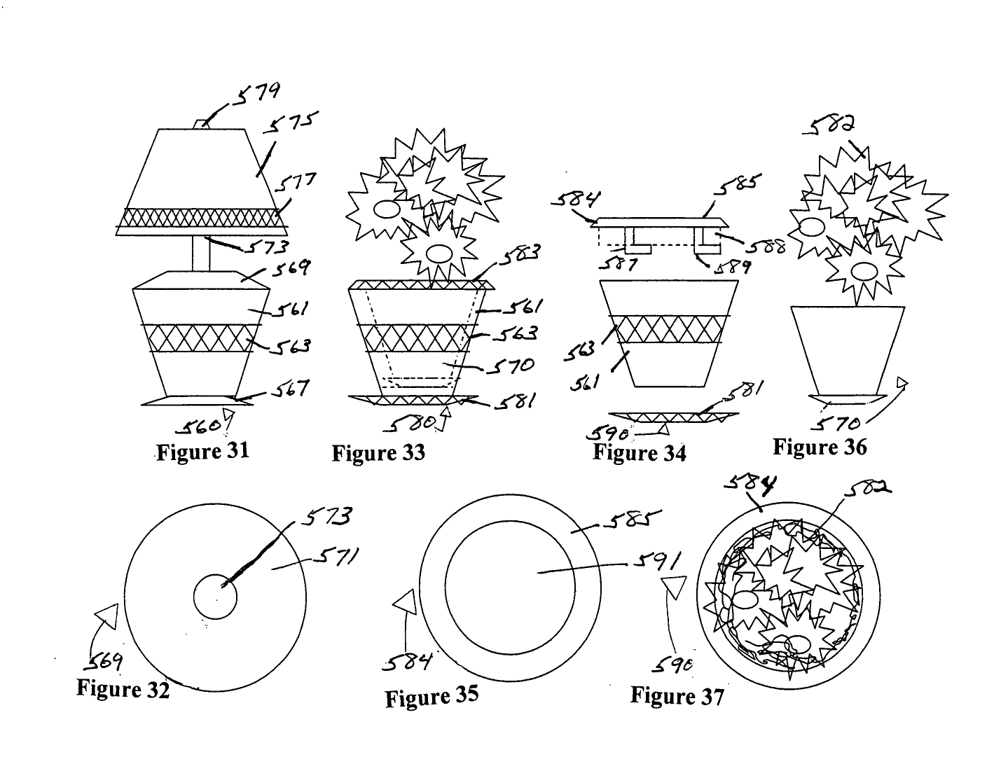

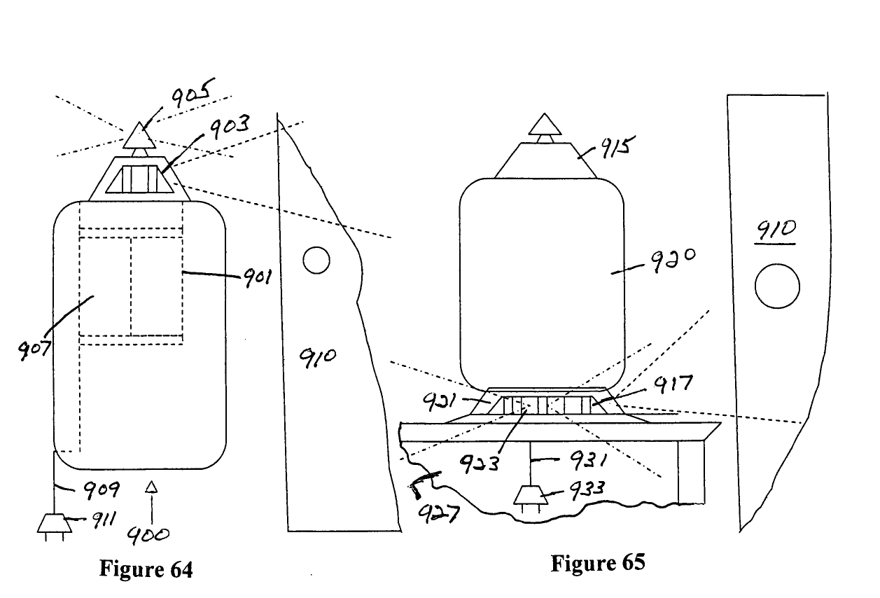

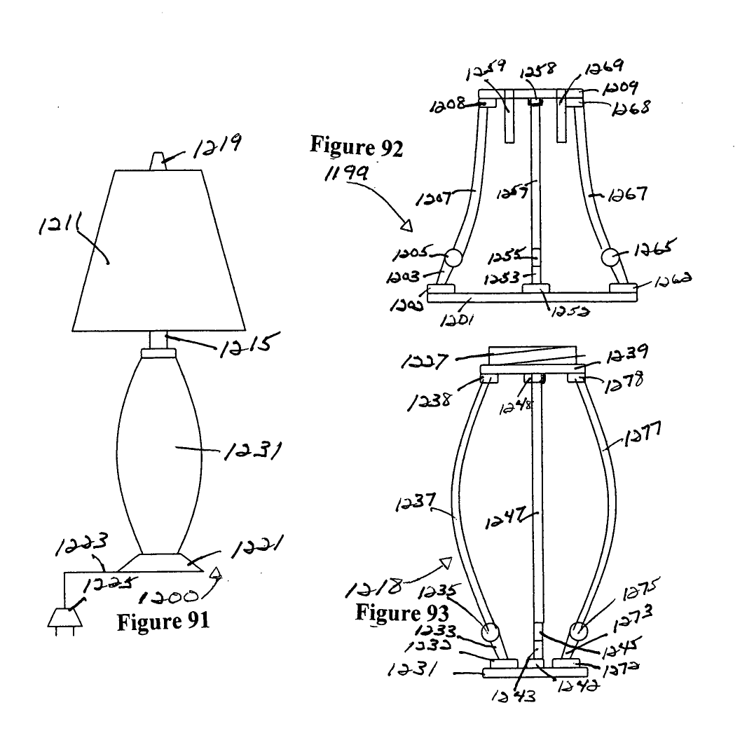

For purposes of the present invention, a decorative container is defined to be a receptacle that contains something and has some exterior ornamentation. More specifically, the decorative container includes urns, pot enclosures, vases, umbrella holders and storage containers. Referring to the following Figures being representative, but not limited to, FIGS. 14 through 28 show decorative containers components; FIGS. 31 through 37 show decorative flower pots; FIGS. 64 through 66 and 86 through 88 show urns; FIGS. 10 through 13 show pot enclosures being the lower lamp components; and, FIGS. 91 through 96 show vases.

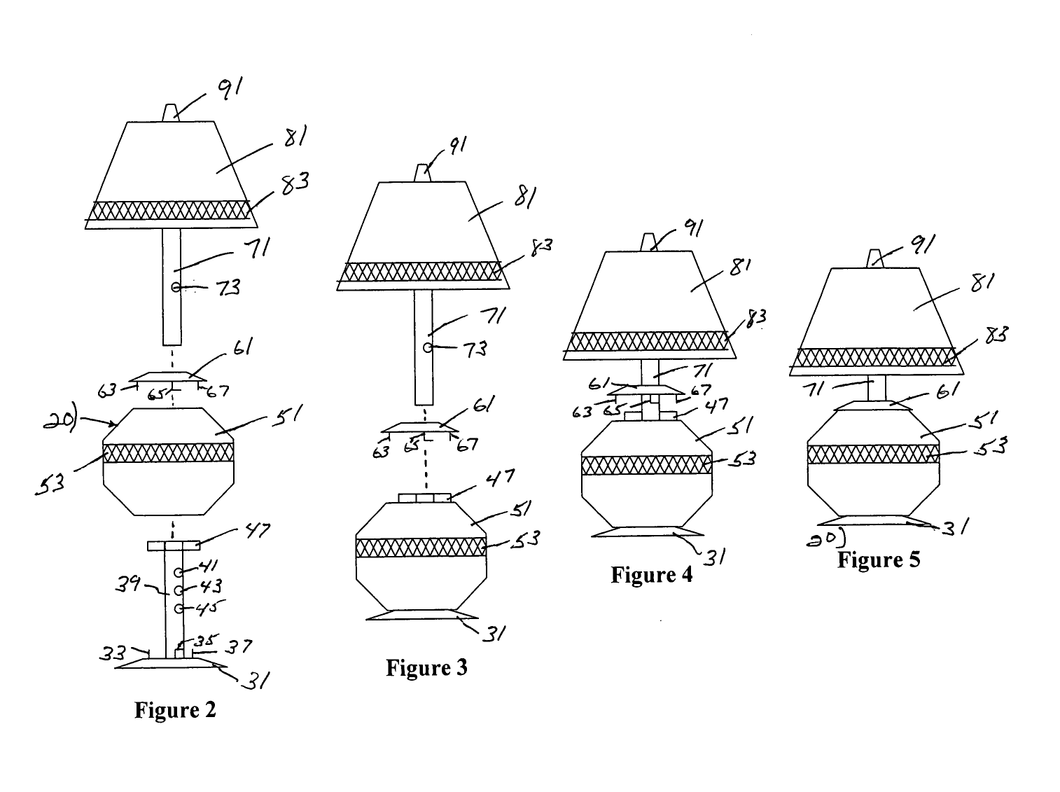

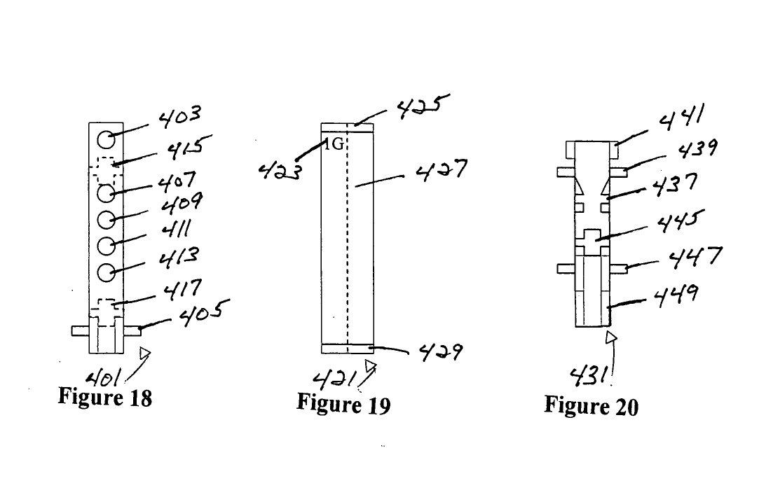

An electrical system component is defined to be a component that consumes electrical power. More specifically, it includes a lighting fixture, a power receiving receptacle, an electrical device, an electronic device, and a communications device. The power receiving receptacle is connected to a power source having power for providing appropriate voltage and current to power at least one electronic device selected from the group consisting of an AC powered device, a wireless phone, a timer, a sensor device, and a low voltage rechargeable electronic device. Referring to the following Figures being representative, but not limited to, FIGS. 10 through 13, and 22 through 24 show a lighting fixture; FIG. 62 show a power receiving receptacle being docking mechanism; FIGS. 18 through 21, 56 through 63 show electrical/electronic devices; and FIGS. 64 through 66 show communication devices. Referring to the following Figures being representative, but not limited to, the electrical system component has a housing which is shown in FIGS. 2, 14, 18 through 21, 56 through 63, and 74.

A power-receiving receptacle is an enclosure which includes means for obtaining electric power. An electronic device is an electrical device that has a transistor(s) and/or fuses.

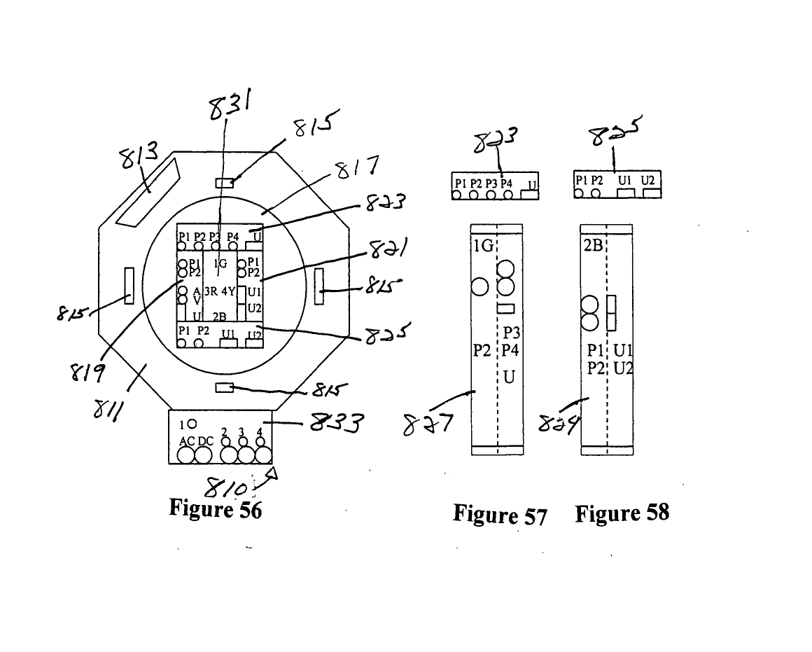

An electrical system component housing is shown by modular electrical system component housings of FIGS. 56 through 63. For example, FIG. 56 shows a present invention multi-utility lamp with electrical/electronic assemblies, housing components and base 810. The electrical housing components are show by elements 819, 821, 823 and 825. FIG. 59 shows a legend for the port abbreviations. A motion detector 813 is shown as the electrical system component in FIG. 56.

Nesting is defined to be to fit compactly together or within one another. Thus, a pedestal component with one of a male and female nesting member is a male or female connection that provides for a fitting within of the other of a male and female connection that is a complementary nesting member.

The present invention decorative containers and pedestals include a plurality of decorative containers and a plurality of pedestals, respectively. Each decorative container and pedestal includes local area network connection for local area connection to at least one other decorative container and pedestal, respectively. The local area network connection. Referring to the following Figures being representative, but not limited to, local area networks are supported by FIGS. 56 through 65, FIG. 70, FIG. 72, and FIGS. 97A and 97C.

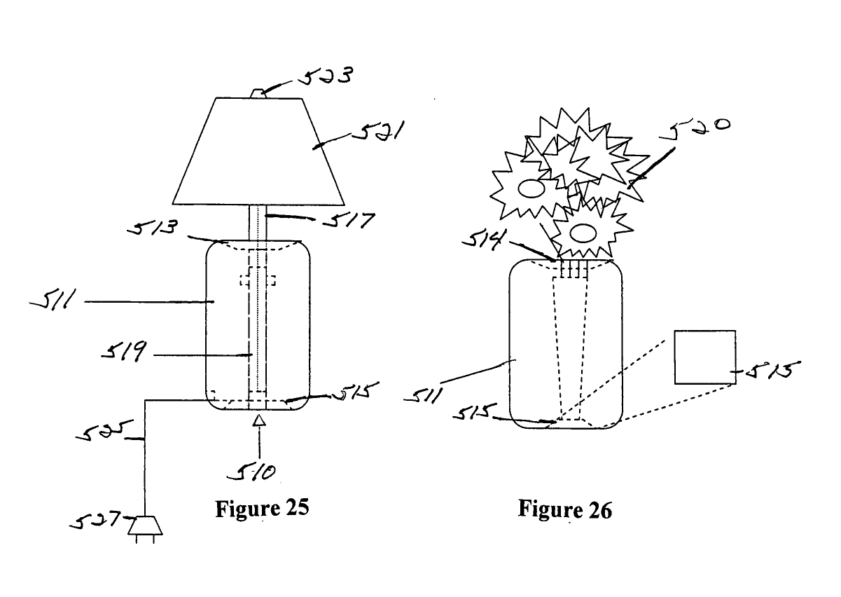

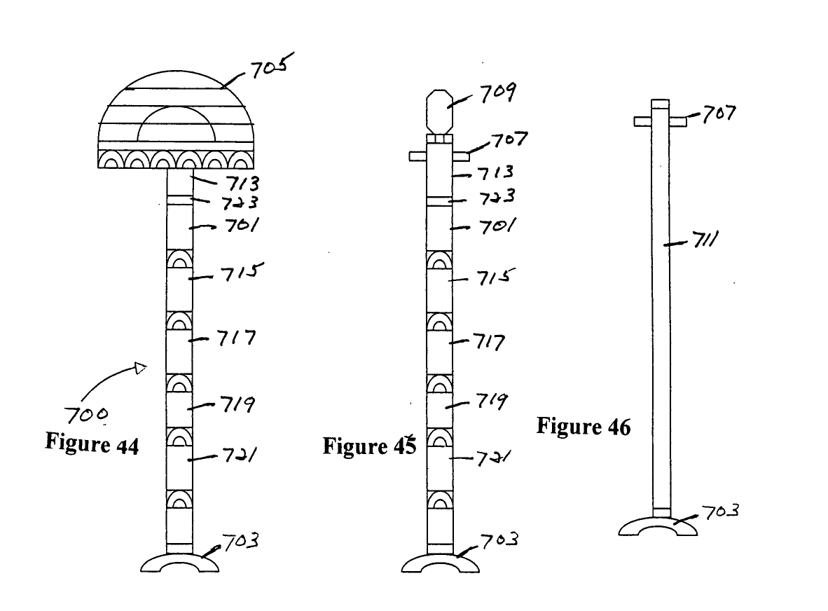

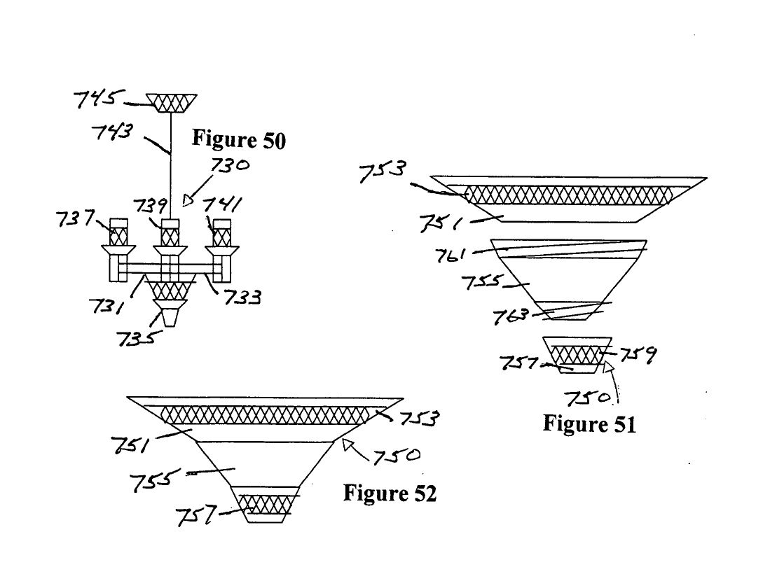

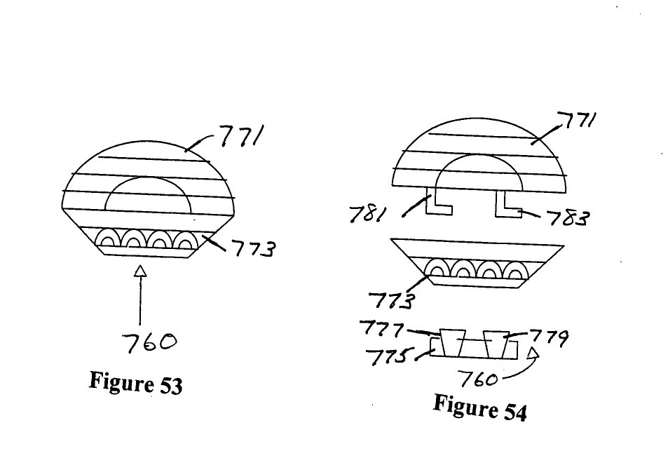

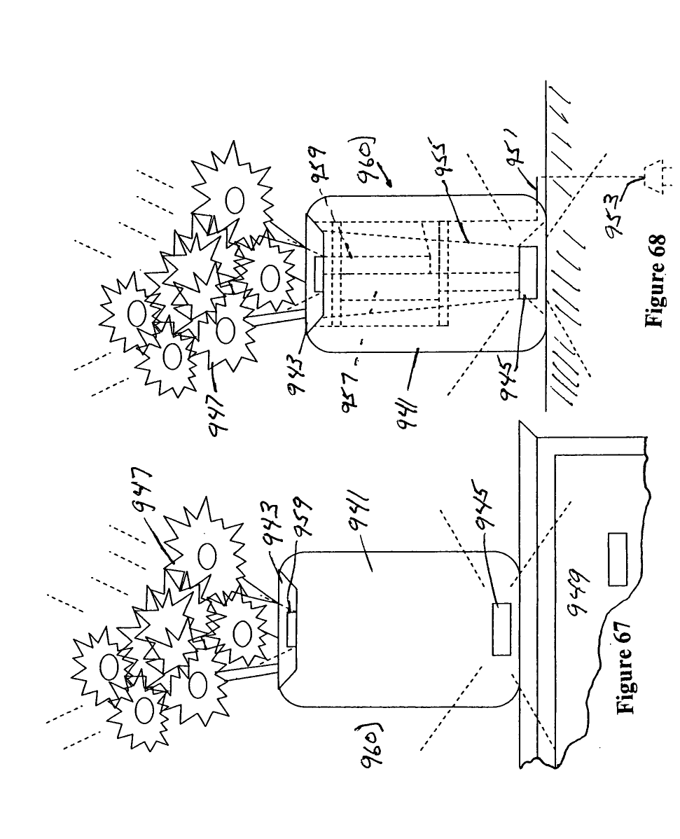

With further reference to the figures for purpose of illustration, it should be noted that detailed parts lists for every Figure are set forth below, and will be understood from the previous text above, the present discussion, the discussions below and the parts lists and Figures taken together. This narrative shall include some discussion of various Figures from time to time, in addition to the comprehensive parts lists below. Hence, the present invention is in, but not limited to, the following embodiments and is represented in the various Figures. As examples: a table lamp (FIG. 1); a vase enclosure configuration (FIGS. 68-72); an urn configuration (FIG. 87); a flower pot enclosure configuration (FIG. 25); a floor lamp (FIGS. 44-49); a hanging lamp (FIG. 50); a ceiling light (FIG. 52); and a wall lamp (FIGS. 53 and 54).

The table lamp of FIG. 1 may consist of the following interconnected, modular and interchangeable components: lamp lower portion 5 (as an at least partially hollow body or a pole or a combination thereof) and electrical housing(s) and related components; lamp upper portion 7; lamp base 3; ring component 21; lamp central shaft component 401 (FIG. 18) (in addition to or as part of the upper 7 and/or lower 5 components); lamp central electrical/electronics assembly(ies) and housing(s) component(s) 421 (FIG. 19); lamp top shaft electrical/electronics housing component 431 (FIG. 20); lighting electrical assembly(ies) component and enclosure frame 471 (FIG. 22); and a lamp shade or enclosure brace component 9 (FIG. 1). These components may be comprised of durable plastic and metallic materials, and other synthetic, composite and spun materials such as fiber glass and graphite fiber, as well as natural materials such as woods, clays and pottery materials. Materials of choice include spun aluminum, stainless steel, molded plastics, cast pottery and fine wood materials such as cherry wood and mahogany. Combinations of these various materials are also desirable Choices should be made taking into account physical needs, such as water exposure, water retention, electrical insulation, conduction and resistance, environmental conditions, e.g., outdoor use, marine environment, etc. as applicable.

The lamp lower portion 5 and base 3 (FIG. 1) may provide the means for, but are not limited to, a lamp lower component, a lamp central shaft component 401 (FIG. 18), and (a) lamp central electrical/electronics assembly(ies) and housing(s) component(s) 421 (FIG. 19) to be interconnected, fastened, or secured to the base 3 (FIG. 1) and its associated components. The means for such interconnections are comprised of connecting and receiving components such as, for example, a lamp base shaft-receiving cylinder 311 (FIG. 14) with an interconnecting aperture or connection receiver 313 (FIG. 14) for securing the lamp central shaft component 401 (FIG. 18) to the base 3. The present invention lamp base may come in various models based on the quantity, electrical loading component requirements (including battery backup) and application components that may be contemplated by the user. For example, a user may purchase the invention lighting fixture table lamp system that may initially be utilized for lighting, but may have a configuration system that consists of a lamp base stand and electrical housing components and a central shaft component infrastructure that may support additional lighting and non-lighting application components without the need to buy such application components at the time of purchase. A sample configuration system and associated components for supporting both lighting and non-lighting functions is illustrated in FIGS. 56 through 63 (such additional applications may be, but are not limited to, Wi Fi repeaters, wireless/remote switch activation, cordless phone repeaters and networked audio and video apparatuses).

The lamp base stand may also have a basic design and utility function to support the interchange of lamp base components. In this function, it may also have a variety of designs and means such as, but not limited to, the designs and means noted in the preceding illustrations and also in FIGS. 10 through 13 inclusive. These Figures illustrate the interchange of various components by providing the means for a lower component frame to be detached and connected or screwed on and off from an upper component frame that fits inside the lower component frame. Thus, the lower component frame consists of an enclosure for an insertion portion of the upper component to reside in. With reference to FIG. 12, the second figure schematic of the top row depicts a top view of the base. The dotted inner circle of this top view schematic illustrates the residing component for the base insertion portion. Upon the detachment of the lower component frame from the upper component, the lamp base component may be removed from the lighting fixture as illustrated in FIG. 10.

The lamp lower portion (FIGS. 1 through 10,) provides for the means to be interconnected or fastened to, but not limited to, a lamp upper component (FIG. 2) and electrical housing(s) and central shaft components (FIGS. 2, 18 through 21, 25, 28, and 56 through 62), a lamp lower portion and shaft ring component (FIGS. 1 through 5, 25, 27, 28, and 31), other types and forms of lower portion or component rings that may be utilized for different functions (some of which are noted in the illustrations of FIGS. 25 through 37), or a lamp base stand and shaft (FIGS. 38 through 43).

The lamp lower portion and shaft ring component (FIGS. 1 through 5, 25, 27, 28, and 31) provides for the means to be interconnected, inter-fastened, secured or fit to, but not limited to, the lamp lower components and upper components, e.g. vase or vase enclosure conversion components, urn conversion components and various planter or flower pot enclosure components, respectively.

The lamp central shaft component (FIGS. 1, 2, 18 and 62) provides for the means to be interconnected to, fastened to, enclosed over or enclose, but not limited to, (the) lamp lower component and/or base stand and/or an electrical housing component (FIG. 19), and/or various types and quantities of lamp central electrical/electronics and assembly(ies) housing(s) components (FIGS. 19, and 56 through 61) and various types of top shaft electrical/electronics housing(s) components such as (FIGS. 1, 20, 21).

The lamp central electrical/electronics and assembly housing component (FIGS. 19, and 56 through 61) may be in various forms and be comprised of various components to support various applications such as, but not limited to, various types of wireless communications repeaters, receivers or transmitters; wireless or wired speakers; security system, monitoring, sensor, surveillance and/or switch applications. These housing components provide the means to be interconnected, inter-fastened, guided to, or guided through, but not limited to, the lamp central shaft component, a lamp upper portion component, the lamp base stand and electrical/electronics housing(s) component, and various types of top shaft electrical/electronics housing components (FIGS. 1, 20, 21), and various types and quantities of lighting electrical assembly(ies) components (FIGS. 1, 22, 23, and 24).

The lamp top shaft electrical/electronics housing component may be in various forms to support various applications such as, but not limited to, various wireless communications repeaters, receivers or transmitters; wireless speakers; antennae; switch applications; and/or other applications noted in this narrative, such forms as, but not limited to those shown in FIGS. 1, 20, and 21. These components provide the means to be interconnected, inter-fastened or enclosed over, but not limited to, the lamp central electrical/electronics and assembly(ies) housing component(s) FIGS. 19, and 38 through 61), the lighting electrical/electronics assembly(ies) component(s) (FIGS. 1, 22, 23, and 24), the lamp shade or enclosure harp component (FIGS. 1, 6, and 7), and other components, such as, but not limited to antenna(ae) and/or networked intelligent speaker apparatuses to support the applications noted in this narrative.

The lighting electrical/electronics assembly(ies) component(s) (FIGS. 1, 22, 23, and 24) may be in a variety of forms to support various types and quantities of lighting, switch designs and utilities and other applications previously noted in this narrative. These components provides the means to support and/or interconnect with the following: the light bulb socket(s) and enclosure(s); the central shaft electrical/electronics housing and assembly component (FIGS. 19, and 56 through 61), and the top shaft electrical/electronics housing component (FIGS. 1, 20, and 21).

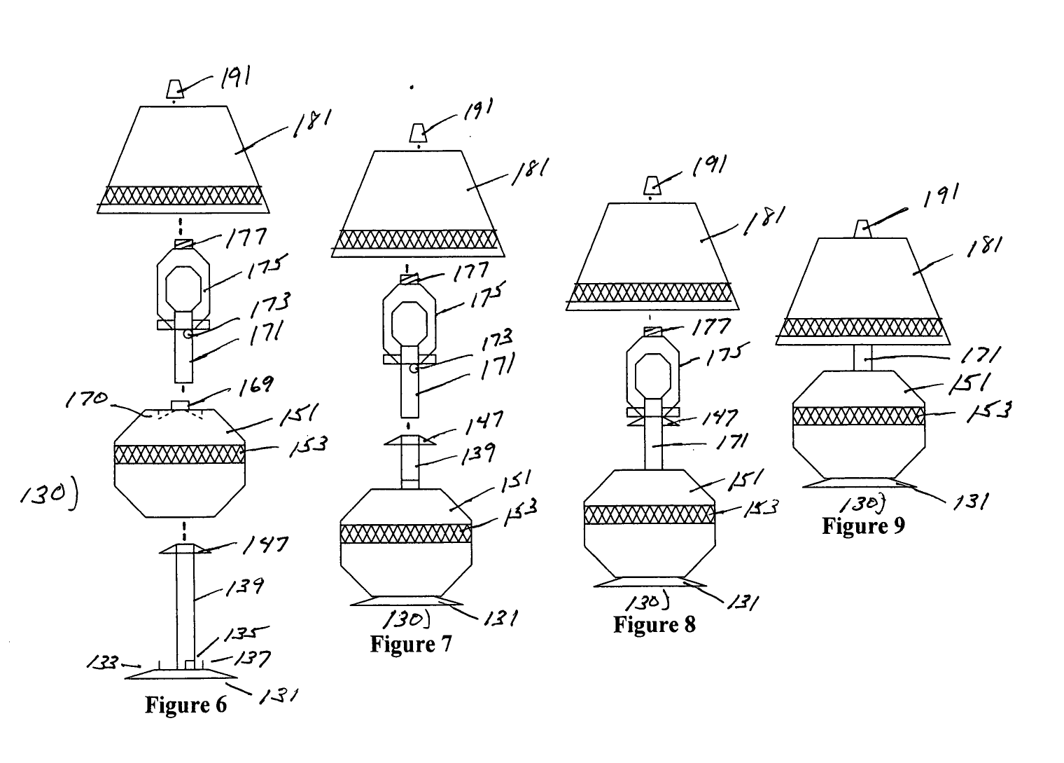

The lamp shade or enclosure harp component (FIGS. 1, 6) interconnects with the top shaft electrical/electronics housing component (FIGS. 1, 20, and 21) and the lamp shade or top lamp enclosure. This brace may also be comprised in the lamp shade or top lamp enclosure component and may interconnect or inter-fasten to the top shaft electrical/electronics housing component (FIGS. 1, 20, and 21) below the light bulb. The top shaft housing components may have a slightly different configuration or design from what is illustrated in these Figures to support such interconnection. The structure would account for having a support (for the center of the lamp shade brace) that would reside between the top portion of the housing component and below the bulb socket and enclosure. Such support could comprise a hub ring that could be flush against or nested around the bulb enclosure to enable a properly mounted lamp shade. Such hub ring may be hinged to at least one component or rib of the support with receiving portions to allow for the securing of other support braces or ribs, where the configuration may support a collapsible lamp shade and/or lamp embodiment(s).

Other illustrations of the interconnected, interchangeable and/or modular functionality of the invention light fixture system and enclosures, some of which have been previously noted in the narrative, are depicted in FIGS. 2 through 3, 25 through 49 and 56 through 62.

FIGS. 2 through 5 depict the means to detach a lamp lower component, upper component, lower component shaft ring and base from the light fixture and replace these components with other substitute components as desired. With reference to these Figures, two actions may initially take place: the lower component shaft ring is turned and lifted from the lamp lower component; and the central shaft interconnecting components (spring loaded) are depressed which enables the upper lamp component to be detached and lifted from the central shaft component and base. The preceding actions enable the lower component, lower component shaft ring as three separate, individual items, to be interchangeable with their like counterparts to be removed from the upper lamp component. The next action may be to remove and lift the lower component from the base stand and central shaft component. The new substitute lower component may be lifted over the base stand and central shaft component. The ring may then be positioned on the lower component, and the lower shaft portion of the upper lamp component is then inserted into the central shaft component and base stand and secured into the assembly through the central shaft interconnecting components. The final interconnecting action may be inserting the lower portion of the new lower component shaft ring into the new lamp lower component. This results in a new present invention light fixture device.

The lower component shaft ring component may be comprised of a variety of materials and finishes that match with the materials and finishes of the lamp lower component, such as, but not limited to, porcelain, wood, ceramic, plastic, clay, pottery, bronze, copper, lacquer, and/or glazed, as well as others mentioned above and below. The preceding materials and finishes may also apply to the ring and lower portion enclosure components for, but not limited to, flowerpots and plant receptacles and/or, vases and/or storage containers. These components may also be in a variety of shapes and sizes with apertures and/or components to facilitate the turning and removal or placement of such ring from or onto the interconnecting portion of the lamp lower component or containers/container enclosures.

FIGS. 6, 7, 8 and 9 illustrate another means for replacing lamp components from and to the lighting fixture system. This illustration differs from what is illustrated in the preceding Figures in the following manner: 1) a lamp lower component without a lower component shaft ring (but with a top insertion portion for fitting under the top shaft electrical/electronics housing component may be removed from the lighting fixture (note that such lower component version may have more limited inner component access as well as interchangeable utilities with a smaller opening (opening for the central shaft) at its top, e.g. without the interconnection means to support a variety of ring components); 2) and the central shaft interconnecting components are located on the upper component and above the lower component configuration and are hidden by the lamp shade from a side view. With reference to these illustrations, two actions may initially take place: 1) the lampshade is removed from the lampshade brace (note that this action is optional); and 2) the central shaft interconnecting components (spring loaded) are depressed. The preceding actions enable the upper lamp component to be detached and lifted from the central shaft component and lower component and base stand. If desired, the top shaft electrical/electronics housing component may be lifted over the top insertion portion of the lower component. The next action may be to remove and lift the lower component from the base stand and central shaft component. Next, a new lower component may be lifted over the base stand and central shaft component. The lower component may comprise an inner funnel or guide such as an interlocking component funnel 170 (FIG. 6) to enable an interlocking mechanism, such as, but not limited to, a spring loaded interlocking mechanism to compress its respective spring loaded side elements to support the insertion of the interlocking component and its respective central shaft through the collar portion 169 orifice (FIGS. 6 and 7) of the upper part of the lower component. The remainder of the components may be reassembled as originally configured, or any or all of the individual components may be replaced by counterpart substitutions. Such formidable user options could generate a multitude of new, attractive, modular, interchangeable lamp devices with a variety of lighting and non-lighting functions.

FIGS. 10 through 13 illustrate another means for replacing lamp lower components from and to the lighting fixture system. These illustrations differ from what is depicted in the earlier Figures in the following manner: 1) they support the replacement of, but not limited to, a lamp lower component from the bottom of the light fixture, by providing the means for an outer base stand frame to be detached and connected or screwed on and off from an inner bottom portion, as shown; 2) they introduce an application of an insertion portion of the lamp lower component to be utilized at the bottom (the outer base stand frame consists of an enclosure for an insertion portion of the lower component to reside in); 3) they introduce a female insertion portion at the top of the lower component 3; 4) they introduce a shaft ring with an insertion portion at the top of such ring; and 5) they supports options for the consumer to purchase a basic configuration assembly consisting of a top and central shaft, electrical housing and assembly, and an inner base stand with electrical cord as one component or purchase these items as separate components. With further reference to these Figures, two actions may initially take place: 1) the lamp is lifted in its entirety; and 2) the outer base stand frame (lamp lower component) is detached or unscrewed (this lower component has inner grooves analogous to those of a bottle top that are not discernable in the illustration views) from the inner bottom stand portion of the upper component (which has outer grooves). The preceding actions enable the lower component to be released from the base component (the resting component for the bottom insertion portion of the lower component) and removed. The next action is to remove the lower component in a downward position to and under the bottom of the remaining light fixture or interconnected light fixture structure. Next, a new lower component, and optional new base are assembled with the remainder of the original parts to provide a new present invention modular lamp with interchangeable parts.

FIGS. 25 and 26, as previously noted in this narrative, illustrate the interconnected, interchangeable and/or modular functionality of the invention by depicting an alternate utility of a lamp lower component as an interconnected component of a vase enclosure and ring configuration. In this illustration, the lamp lower component is part of a present invention configuration that is comprised of the essential components of the invention lamp depicted in FIGS. 2 through 4 above. The distinctions from the FIG. 2 through 4 illustrations are the following: 1) FIGS. 25 and 26 account for a recessed lamp lower component and shaft ring component; and 2) the lamp lower component of FIGS. 25 and 26 conceal the central shaft component (upper component) and a recessed base (FIGS. 25 and 26 lower component has a recessed section for the power cord and supports interconnecting components to the base). In order for the user to initially get to a flower vase configuration from a lamp configuration, the lamp lower component and lower component shaft ring may be removed from the remaining light fixture components in the same basic manner as they are removed in FIGS. 2 through 5. The lamp lower component being removed from the light fixture (FIG. 25), and supporting a different utility, is identified as a vase enclosure component (FIG. 26). The lower component may be lifted over a vase filled with water and placed down and enclosed around such vase. A recessed lower component/vase enclosure ring (selected out of a variety of rings) may then be interconnected onto the lower component/vase enclosure. Finally, the flowers may be placed in the vase of water. Another configuration optional component is a lower component/vase enclosure bottom insert component. The purpose for this insert component is to support the vase in an application where the user desires to have the vase fully contained and supported in the lower component/vase enclosure (instead of having the lower component with an open bottom section). Such insert component may be placed in the bottom of the base/vase enclosure before placing the vase in the enclosure.

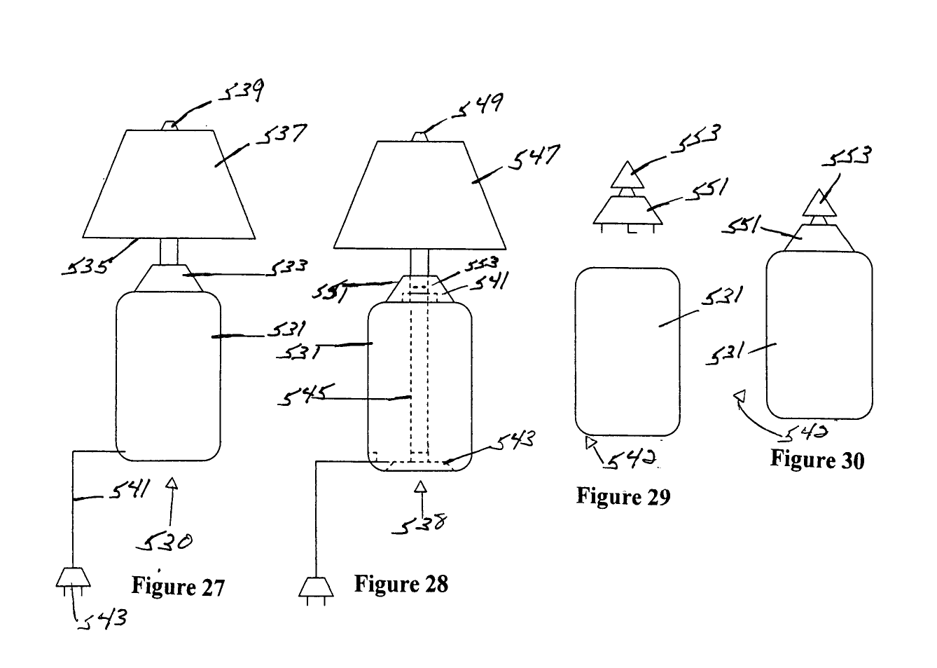

FIGS. 27 through 30, also previously noted in this narrative, illustrate the interconnected, interchangeable and/or modular functionality of the invention by depicting an alternate utility of a lamp lower component as an interconnected component of an (lower component) urn and ring configuration. In this illustration, the lamp lower component is part of a present invention configuration that is also comprised of the essential components of the invention lamp depicted in FIG. 2. The distinctions from the FIG. 2 illustration are the following: 1) the lamp lower component of the currently discussed Figures conceals the central shaft component (upper component) and base. The lower component has a recessed section for the power cord and supports interconnecting components to the base. In order for the user to initially get to the urn configuration from the lamp configuration, the lamp lower component and lower component shaft ring may be removed from the remaining light fixture components in the same basic manner as they are removed in FIG. 2 discussion. The lamp lower component (FIG. 27), being removed from the light fixture, and supporting a different utility, is identified as an urn lower component (FIG. 29). Finally, the lower component and urn ring component (selected out of a variety of the lower component and urn rings) may then be interconnected onto the lower component and urn component to comprise the entire configuration.

FIGS. 31 through 37, also previously noted in this narrative, illustrate the interconnected, interchangeable and/or modular functionality of the present invention by depicting another utility of a lamp lower component as an interconnected component of a flower pot enclosure configuration. In these illustrations, the lamp lower component is part of an invention configuration that is also comprised of the essential components of the invention lamp depicted in FIGS. 2 through 5. In order for the user to initially get to the illustrated flower pot enclosure configuration from the lamp configuration, the user takes the same steps noted in the previous paragraph and in FIG. 2 forward, to obtain a lamp lower component as a standalone component. A conventional basic flowerpot with flowers or other plants comprised of any standard materials, such as plastic or terra cotta (with or without its bottom dish container), and which may be selected from any prior art commercially available flower pot, may be placed in the (previously lamp) lower component. An enclosure ring (selected from a variety of such rings) may be placed over the flower pot, enclosed over the outer top, top, and inner top portions of such pot, and interconnected to the lower component. The lower component may reside with or be placed on a flower pot enclosure dish that may match with the ring and lower component design. The illustrations depict top views of the lamp lower component and shaft ring, the lower component and flower pot enclosure ring, and the ring enclosed over the flower pot. The purpose for such views is to illustrate the inner diameter difference of each ring component (difference based on utility—lamp shaft enclosure versus flowerpot enclosure) and the depth of the inner side of the ring component (to support the utility of concealing the flowerpot and embodiments within the flowerpot that may facilitate plant care). As previously noted, this ring may be in a variety of dimensions, shapes and components, based on the utility functions for such ring (for example, as previously noted, a nutrient enclosure and/or a hanging plant enclosure).

FIGS. 38 through 43 illustrate a diagram of a lamp lower component connecting and/or disconnecting to and/or from its light fixture components along the side of the light fixture shaft and/or base stand. In the first step, the lower lamp portion is away from and facing the light fixture components with its side portions open to the lighting fixture. The lower lamp portions that are open to the light fixture components are the following: the lower lamp side portion cover and/or connecting component (this may also be the lower lamp side door and/or connecting component—pending on user model selection); and the lower lamp top portion cover and/or connecting component (this may also be the lower lamp top portion cover/door and/or connecting component-pending on user model selection). In the next step, the lamp shaft is in the lower lamp portion with the side portions open. The lower lamp portion may be secured along or into the shaft and or shaft and base stand component through a variety of means such as, but not limited to, through vertical interconnecting guides at the bottom of the lower lamp portion and top of the base stand or through interconnecting male components at the top of the base stand, and lower lamp portion apertures at the bottom of the portion. Next, all lower lamp portions are closed, thus enclosing the lower and central, in part or in whole, portions of the lamp shaft, and any components, such as a user interface as described previously, that may be desired to be enclosed in the lower lamp portion.

FIGS. 44 through 49 illustrate a sample of a present invention floor lamp configuration. This lighting fixture example also illustrates the invention's utilities by depicting a sample of interconnected, interchangeable and modular components that may be added when and as the user desires to upgrade his/her configuration to a configuration having, for example, a table and/or magazine rack. Like similar illustrations, the lamp upper component, lower component and base component are modular, with interchangeable counterparts and substitutions, and have the essential components of the invention lamp depicted, for example, in FIGS. 6 through 9. One main distinction is the type of lamp forms—table versus floor. In order for the user to upgrade to the table/magazine rack configuration from the first configuration, the user initially removes the decorative light enclosure and brace from the top portion of the lighting fixture and depresses a central shaft interconnecting component (spring loaded). The user then removes the top portion housing and slides the lamp upper and lower sections of these components up and over the central shaft component while the central shaft interconnecting component is in a depressed mode. (In another floor lamp version, utilizing the configuration basics illustrated in FIG. 4, the lower component, as one or plural sections, may slide down the central shaft component and an inner base stand portion, upon the detachment or turning of an outer base stand portion from the inner base stand portion.) Other components and accessories that may then be slid down the central shaft of component are: a ring; a bottom lower component portion; a magazine rack portion; a mid-base portion; a mid table portion; sections of an upper top portion; and another ring. Finally, with interconnection of the top portion and lighting enclosure and brace to the top shaft component the upgraded configuration is complete. Not only does this embodiment afford conversion from one to any of other configurations for added and/or removed pieces and functions, but any one or more of the individual components may be substituted with like components of different designs, colors, shapes and other appearances and functions of choice, including non-lighting functions.

FIGS. 50 through 52 illustrate samples of a present invention hanging lamp and ceiling light fixture. These lighting fixture examples also illustrate the invention's utilities by depicting a sample of interconnected, interchangeable and modular components. In this illustration, the hanging lamp and ceiling light components have interconnecting means such as, but not limited to, inner and outer grooves. The ceiling light illustration depicts such grooves on the top and bottom portions of the light enclosure for turning/securing the light enclosure into the top and bottom enclosure frames (having inner grooves). This interconnecting functionality is also utilized with the hanging lamp components. It is noted under these illustrations of the hanging lamp, which is depicted in its entirety, that the lamp components with diamond patterns have grooves for turning/securing such components into their respective top and bottom enclosure frames. As previously noted, it is to be appreciated that placeware, glassware and hanging flower pot enclosure configurations, as well as other household items having the same or matching design pattern as the top row hanging lamp and ceiling light fixtures may also be purchased or utilized by the consumer at different times to illustrate the utility and economy of supporting interchangeable and modular components.

FIGS. 53 and 54 illustrate present invention wall lamp and floor lamp configurations. These lighting fixture examples, again, illustrate the invention's utilities by depicting a sample of interconnected, interchangeable and modular components. In this illustration, the wall lamp is shown in its entirety and also by its interconnecting and modular components: an interconnecting lamp base support frame and electrical housing component; a lamp lower component; and an upper lamp component with lamp lower component interconnectors. Upon mounting the upper component to the wall frame unit and electrical receptacle, the lamp lower component interior protruding element may be inserted into the center of the lamp base support frame. After the lower component is secured to base support frame component, the upper lamp component may be interconnected into the top apertures of lower component and the lighting enclosures of the base support frame and the electrical housing component. The wall lamp is depicted as having the same design patterns as the previous floor lamp to illustrate modular design, interchangeability and economy.

FIGS. 56 through 62 illustrate some of the key invention components for supporting multiple utilities and applications through the invention lighting fixture. The sample configuration supports four applications: 1) basic lighting, lighting activated through wireless means, and battery backup for both lighting activation means; 2) a wireless router, transmitter and repeater; 3) an audio monitoring device; and 4) a cordless phone signal repeater. These applications are associated with a respective central electrical/electronics assembly and housing component that is interconnected to its associated labeled interconnection point (as illustrated, 1G, 2B, 3R and 4Y) on the stand.

Each component (HC) has three external interfaces: 1) the bottom base stand electrical interface; 2) the side interface connection modules for connections through the central shaft component apertures to base components (either residing in or are a part of such base); and 3) the top interface for interconnections (and applicable USB cross-connections) to and between the lighting fixture electrical/electronics assembly(ies) components.

With reference to FIG. 60, the side interface components may vary between certain components. Housing Component (HC) side interface components consist of connection modules for the following: a connection for the second power switch source—the wireless receiver for wireless switch activation (P2—in an always-on state); a battery backup connection for the standard switch (B1—optional); a battery backup connection for the second power switch connection component (B2—optional); and a USB connection for an electronics/microprocessor device (in this case, the wireless receiver for wireless switch activation may be connected to the USB port as a means to extend remote light activation beyond the range of a home wireless network, if such network does not have a remote access means. There is no standard switch connection (P1) on the side interface of HC1, because the standard on/off switch resides in the upper portion of the table lamp. HC2 side interface components consist of connection modules for the following: a power connection (P1) for a user interface that is connected to the wireless router, transmitter and receiver (located in the top portion of the lighting fixture) via a USB connection (U1); a power connection for a second component that may be residing in, or may be a part of, the lamp base; a USB port connection for the previously stated network interface (U1); and another USB port for another base component device or another housing component (U2). HC3 side interface components consist of connection modules for the following: a power connection for the audio monitoring device equipment concealed inside the lamp base (P1); a power connection for a second component that may be residing in, or may be a part of, the lamp base (P2); an audio connection feed for the purpose of connecting audio signals between components that may be located in the central and top portions of the lighting fixture (A), in this example, connecting the audio monitoring device in the lamp base to a small microphone located in the upper portion of the table lamp; and a video connection feed for the purpose of connecting video signals between components that may be located in the central and top portions of the lighting fixture (V); and a USB port for a base component device (U). HC4 side interface components consist of connection modules for the following: a power connection for a component that may be residing in, or may be a part of, the lamp base (P1); a power connection for a second component that may be residing in, or may be a part of, the lamp base (P2); a USB port for a base component device (U1); and another USB port for another base component device or another housing component (U2).

With further reference to the HC side interface components, each grouping of such interface components varies in height amongst each uniquely numbered HC in a descending order. The purpose for the differing height alignment is to utilize lamp central shaft housing space efficiently, given the amount of potential connections that may be housed in the central shaft area. The Figures depict the same height descending relationship between the HC components and their respective alignments on the central shaft. In order to support a user-friendly design, a color scheme is utilized for each HC grouping, and related interconnection throughout the lighting fixtures associated components. The color schemes for such components, assembly marks, and connections are green (HC1), blue (HC2), red (HC3), and yellow (HC4). Connections may also utilize uniform markings and patterns to illustrate like interface applications.

With continued reference to these Figures, the top interface components (FIG. 56) also may vary between certain components but map to each respectively numbered HC side interface connection, with the exception of HC1 P1 (as previously explained). Given that the preceding paragraph explained each connection module designation and function, this narrative for the top interface components will cover such component s applicable to the application example. With respect to the pertinent HC1 top interface components, the USB port (U) of HC1 may be connected to the wireless router which is residing in the top portion of the lighting fixture. The purpose for such connection is to activate switch lighting through a remote connection via the router (which would also be connected to a home network interface for outside/Internet access). The HC2 connections are P1 for the wireless router, transmitter and receiver; and U1 for connecting the user interface to the wireless router, transmitter and receiver. The HC3 connections are P2 for powering the microphone located in the top portion of the lamp, and A for connecting the microphone to its base component equipment. Finally, the pertinent HC4 connections are P1 for powering the cordless phone signal repeater.

It is conventionally understood that lamps and other electrical and electronic devices have on/off switches. Such switches are conventionally toggles, sliders or buttons, and these should be construed as included herein. However, it is to be understood that the terms “on/off”, “on/off switch”, “starter”, “activation means” and other equivalent words should also be taken to include a switch or logic programmed switch that may be ambient sensor controlled, motion sensor controlled, timer controlled, remote timer controlled, remote unit controlled, random program generated controlled, device controller controlled, timer program controlled, manually controlled, local area network server controlled or remote or web server controlled, security system controlled or accounting for a hierarchical program to account for combinations of the following. It is also to be appreciated that the settings associated with the interfaces described herein and especially, the following paragraphs, may be in a variety of embodiments that may range from manual DIP switch means to programmable or logical interface circuit software initiated means.

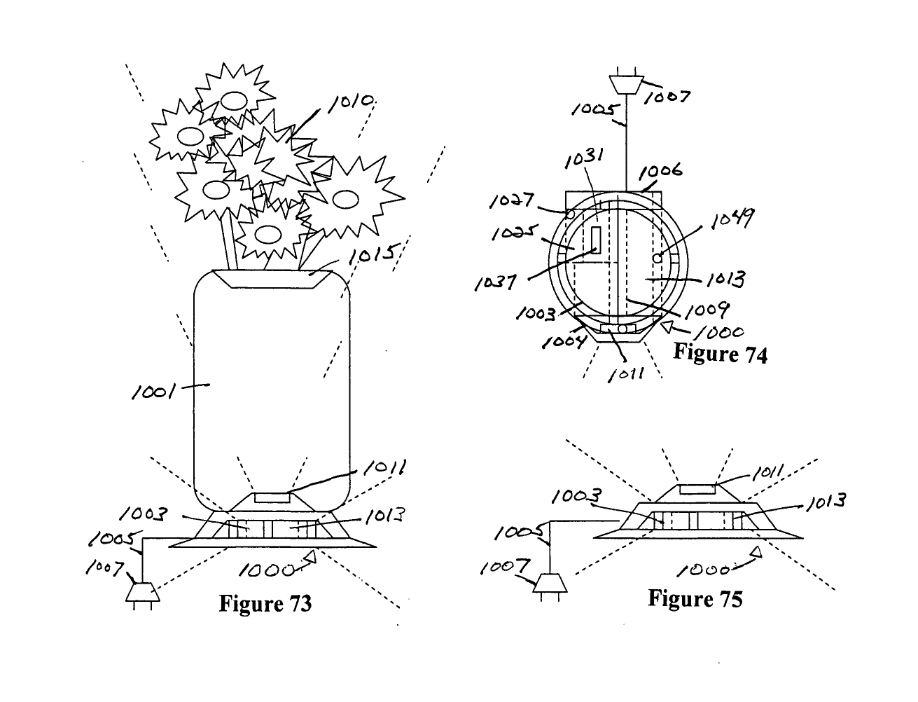

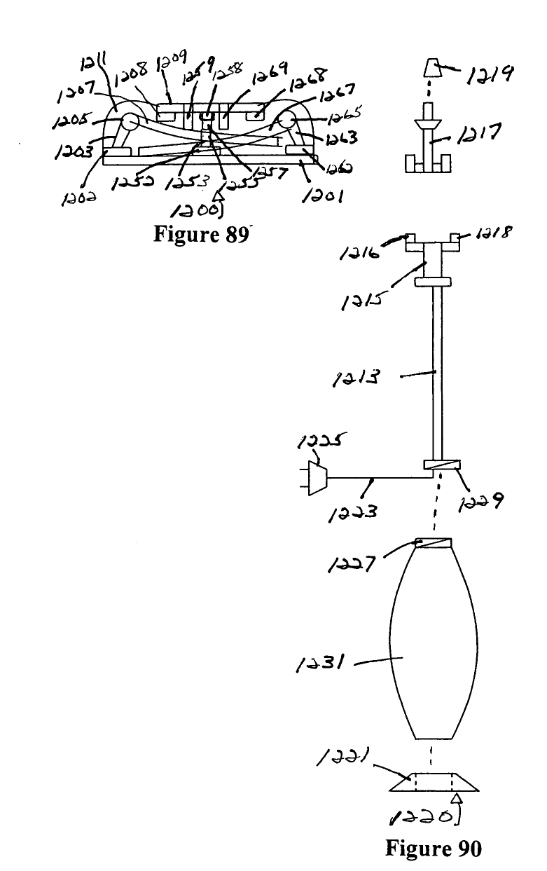

With further reference to the figures for purposes of illustration, the present invention is in, but not limited to, the following additional enclosure forms, components, systems and applications: urns and pedestals (FIGS. 64, 65 and 66); flower vase and vase enclosure systems (FIGS. 67 through 72); pedestal systems (FIGS. 73 through 85); urns with multi-utility means and components (FIGS. 86 through 112); collapsible lamps (FIGS. 89 through 96).

The urns illustrated in FIGS. 64, 65 and 66 may include, but are not limited to, one or more motion detector(s) which may be in modular form, where the scanning portion of such detector is located through an aperture of these urns (FIGS. 64 and 66) wherein the detector may face towards a front door and associated area as depicted in the FIGS. 64 and 66. One of the purposes for such detector is illustrated in the following application. Upon the opening of the entry way door, motion is detected and this action may cause certain present invention modular device activations to take place. In the urn, there may be a wired connection to another module, inner component or external device or a wireless transmitter and/or antenna(e) where the antenna is located atop the urn as in FIG. 64, or a device activation controller and wireless transceiver and antenna(e). With respect to the wireless transmitter, such transmitter would receive an electronic signal through an electrical connector with at least one terminating point that is connected to the motion detector which would originate such signal upon the detection of the opening of the door. Upon receipt of such signal, the transmitter component would send a signal to one or more receivers that may be connected to one or more processors on a controller or to one or more processors connected to, or on, one or more switch(es) that are on or connected to (a) light fixture(s), air purifier(s), or a variety of appliances or devices. In the application associated with a device activation controller, such controller may have one or more processors with software programmed with certain parameters. Such parameters may be or include modes such as, but not limited to, timer modes, security modes, dwelling safety modes, where such modes may comprise, for example, in the context of a timer mode, a time of day; or conditional parameter/statements (such as, if, then statements, which may utilize input data from other processors and/or sensors as well as device addresses.

Each entry way urn could alternatively have, but is not limited to, a line of sight transmitter and receiver that is aimed at each respective unit which is near the door. In this application (FIG. 66), upon the opening of the entry way door, the line of sight connection is broken and this action may cause certain device(s) or module activations to take place. In at least one of the urns and urn top component, there may be a wired connection to another module, inner component or external device or wireless transmitter and antenna(e) or a device activation controller and wireless transmitter. With respect to the wireless transmitter, such transmitter would receive an electronic signal from the line of sight receptor that would originate such signal upon the connection break caused from the entry way door being opened. Upon receipt of such signal, the transmitter component would send a signal and the subsequent activity may follow the application stated in the preceding paragraph. Other forms of embodiments comprising motion detectors and/or line of sight components may be, but is not limited to, figurines or sculptures that may have openings, housings or be comprised of interconnecting components to accommodate the modular components described herein.

Another invention embodiment associated with this application, and illustrated in FIG. 65, is a pedestal with an urn. The pedestal may comprise, but is not limited to, one or more motion detector(s), other modular components, wired and/or wireless communications equipment. As depicted in FIG. 65, the pedestal is on top of a foyer table piece with at least one of its motion detectors facing toward the entry way door and associated area. Upon the opening of the entry way door, motion is detected and this action may cause certain device(s) activations to take place and may cause a series of actions such as those stated in the paragraph associated with the application with urns of the preceding Figure. This pedestal may be in the form and design, but is not limited to such form and design, of an urn or a vase pedestal or a plate or bowl pedestal (with illuminating or non-illuminating functions).

Another invention system embodiment that may utilize the modularity and integration characteristics described herein is a chemical and chemical dispenser component such as, but not limited to, an electric or battery-powered air freshener component and/or module (FIGS. 67 through 85). Said module may be connected within or to the pedestal and other pedestal module components to comprise new embodiments of the present invention systems, such as, but not limited to, a multi-utility flower vase pedestal (FIGS. 73 through 85). This system may utilize, among a variety of other modules, the motion detector component and connector functionality along with a system mode or timer module and connector. One application associated with one form of this embodiment is a continuation of the example related to the entry way door being opened. In addition to lights being turned on (given that certain parameters from a variety of parameters are met, which will be described in further detail herein), upon the opening of the front door, a system mode or timer module may be activated as a result of an electric signal connection originating from the motion detector module and through an electrical circuit termination between the motion detector module and the timer module. The activation of such timer module may cause the activation of a timer and a circuit connection from such timer to an air freshener dispenser heating unit, where such heating unit may be activated by an electric current originating from such timer module and traveling over a circuit and circuit connecting interface between the timer module and the electric air freshener module. The activation and operation of the air freshener heating unit would cause the emission of an aromatic scent from an essential oil residing in a container or cartridge (which is also modular, interchangeable and interconnecting with the air freshener electrical and heating housing component) and emanating out of such container through a vapor permeable plastic composite conduit such as, but not limited to, a wick that resides along the bottom portion of and protrudes upwardly out of such container through a top portion of such air freshener module. The heating unit may be on for a designated period of time, governed by the timer module, at a designated diffusion setting, which may be set manually (by accessing the underside of the pedestal or through a top portion aperture of the pedestal) or through a software or firmware generated means. Other invention embodiments may account for a controller processor and air freshener connector that may comprise circuit leads that account for diffuser settings whereby such diffusion level may be activated or changed through such processor controller. Such processor controller may also change a different scent emanation by integrating with components capable of such functionality.

The relevance of performing the preceding functions through modular components associated with a pedestal may have a variety of significances when such pedestal may be associated with supporting a vase that contains silk or some form of artificial flowers or fresh flowers. For example, a vase may contain silk roses, and the pedestal associated with such vase may have an aromatic dispenser emanating a rose scent, in addition to other modules and associated functions. These functions, when performed through an integrated modular means as described in the previous example, provide even greater utility and benefits to the user, such as, at minimum, extending the life of the air freshener essential oil.

FIGS. 78 through 85 illustrate the application stated in the preceding paragraph, with the flower vase pedestal modules and components in mostly block form: motion detector; system mode or timer component; communications component; electrical housing; and air freshener.

Said pedestal is comprised of the following components: an exterior housing with a variety of apertures; an interior modular frame with slots for a variety of modules and module release buttons (one is depicted in FIG. 78); an electrical housing with a back frame and a center frame.

The exterior housing may be in a variety of shapes and designs, such as but not limited to, various forms ranging from a contemporary form which is depicted in FIG. 73 to a more ornate and intricately detailed form whether it may be Oriental with associated carvings or a part of a ceramic figurine. Such housing comprises at least one horizontal planar surface to support a flower vase. It may also be composed of a variety of materials such as, but not limited to, inexpensive moldable plastic composites, pottery, clay and/or more expensive porcelains or woods with a variety of finishes and possible inlays (such as precious minerals or woods).

The exterior apertures support modular functionality, housing, venting and exterior design. Apertures on the front facing and side portions may support motion detector motion sensor functionality, wireless module communications, module ventilation and design. The back side consists of one aperture area to support the electrical housing back frame and electrical cord connections. Top apertures may be located in four areas: the main planar surface area (for certain pedestals); the top front; the top sides; and the top back. The main planar surface may comprise apertures for the module release buttons (which will be covered further in this narrative) and the timer module input and output means. The top front apertures may be for an air freshener diffuser component and aeration, ambient sensor functionality and module ventilation. The top side apertures may be for ambient sensor functionality and module ventilation. Certain pedestals may also have top side apertures for an air freshener diffuser component and aeration. Certain pedestals may have a top rear side or corner component for wireless communications antennae (as needed, pending on the wireless application). The top back portion apertures may be for module ventilation. An optional aperture cover component for covering top component non-aeration apertures that are associated with modules that the user may plan on purchasing in a subsequent period may also be available for the pedestal. The underside of the exterior housing component is primarily hollow with interconnecting components such as, but not limited to, inserts, grooves and clips to accommodate the various invention module embodiments associated with the present invention.

The interior modular frame is comprised of an outer frame component with slots to accommodate modular inner chamber frames and interconnecting components such as inserts and clips to secure such frame to the underside of the exterior housing component. The outer frame component consists of a front and side portions. Preferably, there is no back or rear portion, because such open area may be used to accommodate an electrical housing back frame. The modular inner chamber frames may be comprised of cross braces with interconnecting components such as slots for connecting to the outer frame and modules and also projected movable clipped interconnecting components for securing and releasing module components.

There are a variety of embodiments and interconnecting means for comprising and supporting the securing and releasing of modules to the variety of present invention enclosures, pedestals and bases.

An illustration of one embodiment, out of a variety of many embodiments, for a movable interconnecting component is depicted in the air freshener illustration, FIG. 80. FIG. 80 depicts a side view of a module release button and its associated movable components. Release button has a top portion that is primarily flush with the pedestal top main planar surface with recessed sides that fit within a wider aperture located on the underside of the associated exterior housing area. Such button has a bottom portion that resides slightly off the center of the top portion of a hinged clipped interconnecting component (the button bottom portion is on the opposite side of the hinged means). The bottom side of the hinged component that is on the opposite side of the bottom clip portion has a spring pushing against it. Such spring is in a recessed holder that comprises an upper enclosure that supports the cross hinge that connects through the clipped interconnecting component. Such holder is part of the inner modular frame. The operation of the components described in this paragraph will also be covered in the air freshener module narrative.

These interior modular frames and their associated components such as the module slots and module release buttons may be comprised of inexpensive durable and moldable plastic.

The electrical housing may be comprised of two primary components: a back frame and a center frame as depicted in FIG. 78. The frames provide a means and infrastructure configuration for electrical current and data to transit through the present invention modules. Such frames have electrical interconnecting means and settings (such as, but not limited to, dip switch settings) to support a variety of inter and intra module electrical connections.

The back frame component may be comprised of module electrical connector (primarily female plug receptors) components and a central electrical housing component with electrical connector feeds to the back frame module electrical connectors, the center frame main electrical connector, and the main electrical cord or electrical cord connector. The back frame may comprise at least one setting (such as a dip switch or on/off setting) for supporting (an) electrical module connection(s) in an on or off state. One of the purposes for such setting is related to the operation of an electric air freshener module (which will be explained in the air freshener portion of the narrative). The central electrical housing component comprises the electrical connector feeds to the electrical components previously cited in this paragraph. Said back frame may comprise a low cost durable plastic and/or rubber for the frame/housing that supports the electrical connector components, and electrical conducting materials such as copper for such electrical connectors.

The center frame is comprised of most of the components and materials of said back frame with the exception of the receptacle/housing and connectors for the main electrical cord. In addition, said center frame may comprise at least one aperture for supporting a module-to-module electrical and/or data connection. An example of the purpose for such aperture may be to support an electrical timer module power connection directly from such module to an electric air freshener module.

Both frames may connect to the inner portion of the exterior housing and the interior modular frame through a variety of interconnecting components such as but not limited to, inserts, clips, screws and grooves. The preceding interconnecting components may also be adhered to the respective frame connections by glue or other bonding means.

The motion detector module may be comprised of the following components: motion sensor; main circuitry; module interfaces; an electrical housing interface; circuitry settings; and an exterior housing. The motion sensor is comprised of sensing circuitry, conducting and connecting components and materials. The sensor connects to the main circuitry component. The main circuitry component is comprised of circuitry and circuitry connectors to circuitry settings, module interfaces and the electrical housing interface and associated circuitry, conducting and connecting materials. The module interfaces may be comprised of male and/or female electrical connectors, and associated receptacles and housings. The interfaces are comprised of currently available conducting, resisting and connecting circuitry materials such as, but not limited to, copper, and plastic and rubber composites. The electrical housing interface is comprised of electrical conducting and resisting materials, such as, but not limited to, copper and consists of a male plug and resistor for interfacing to the electrical housing. The motion detector circuitry settings are primarily for setting on and off states for the respective detector module interfaces. These settings may be comprised of dip switches with a plastic outer housing and electrically conducting or resistant connectors. The module exterior housing may be comprised of, but not limited to, a moldable plastic material or hard synthetic rubber composition. The exterior housing comprises interconnecting components such as, but not limited to, clips for holding the module components, especially the circuitry and connecting enclosures in place and secured from undesired external exposure. As appropriate, some of the exterior housing fastenings may be adhered to other component interconnectors by a bonding means or compound such as, but not limited to, glue.

The operation of the motion detectors may be illustrated in the example as now described. Upon receiving current traveling from the wall socket to the male plug of the pedestal electric cord, where such cord may terminate into the back frame central electrical housing component, and such current travels through the back frame electrical connectors and the center frame electrical connectors and may travel from frame into the detector electrical housing interface, where such current travels through the detector circuitry, the detector is in an active state. Upon the opening of a front door, which is located in proximity to the pedestal which comprises said motion detector, the sensor unit, may originate an open circuit connection to the main circuitry component, such connection travels out towards the module interfaces and may reach such interfaces, pending on the circuitry settings (for continuing through or breaking such circuit connection).

An example where a connection may be desired to be broken may be associated with a module configuration that includes a timer module and a wireless (such as RF) transmitter module, where both modules are connected to the detector module. In such configuration, it may be advantageous to have the circuit connection described herein travel solely to the timer, where said timer may control the function(s) associated with the wireless transmitter. In continuing with this example, which accounts for the previously noted configuration, the circuit connection may travel solely to the module interface that connects said detector to the timer module.

The motion detector module may also comprise other circuitry, at least one processor and additional functionality such as, but not limited to, recognizing when a certain module or external device such as a lamp may be in an on state and may contain a program associated with such condition and the operation logic for such condition. Given that the present invention accounts for this module in a variety of enclosures and is interconnected, integrated and/or associated with a variety of modules, it supports additional circuitry and processor designs to support a variety of configurations and functions.

The timer module may comprise the following components: control/mode program and circuitry; module interfaces; electrical housing interface; input and output means; circuitry settings; and an exterior housing. The timer module is comprised of the same circuitry and connecting materials that are comprised in the motion detector module. In addition, the input and output means may be comprised of a variety of components and materials. One embodiment of means is comprised of a planar interface that has a LED display and at least one input button and at least one program sequence or step button. Such means may be comprised of a translucent and durable hard plastic display component and other durable plastic and/or rubber materials. The timer program resides on a processor with input and output components that are connected to the input and output means and the module circuitry. The circuitry settings are comprised of the same materials and components of such settings that are associated with the motion detector. The module exterior housing may be comprised of, but not limited to, a moldable plastic material or hard synthetic rubber composition. The exterior housing comprises interconnecting components such as, but not limited to, clips for holding the module components, especially the circuitry and connecting enclosures in place and secured from undesired external exposure. As appropriate, some of the exterior housing fastenings may be adhered to other component interconnectors by a bonding means or compound such as, but not limited to, glue, epoxy or other binding paste, liquid or jelly.

The timer module program may support a prompt-based user input function of programs and sub-programs for each module device that is interconnected (either within or external to the pedestal) to the timer. The present invention accounts for a Set program and an Interval program.

An example of the operation of such program consists of the following for setting the operation or activation of an air freshener module which may be connected to said timer module as depicted in FIG. 78. The display of input and output means may display the time of day, such as 5:30 P above a step or sequence button that may be located on the bottom left side of the display. On the right side of the display, the characters IN may be displayed above the input button that may be located on the bottom right side of the display. Upon pressing the input button, the left side displays, DEVICE 1. Upon pressing the input button again, the left side displays, SET 1 (which is for the first time setting for device). The next input button depression displays, TIME. Upon the depression of the input button, the word, START, is displayed. The depression of the input button causes the word, HOUR, to display. The next character displayed is the number, 1. The user may either depress the input button to set the start hour at 1 or depress the step button to scroll through the number characters to the desired start hour. If the user desires to set the air freshener to turn on at 6:30 PM, then the user scrolls to 6 and depresses the input button. The next set of characters displayed are, MINUTE. Upon the depression of the input and step buttons in the manner described in this paragraph, the user sets the start time for 6:30 PM and the next display sequence is STOP. Upon the final input of the stop time, the next display item is, DATE. If the user desires to not set a date, the user may depress the step button for the display of, SET 2. If the user desires no other designated setting time for the air freshener, the step button may be depressed for the display of, RANDOM. If this function is not desired, the depression of the step button displays the word, INTERVAL. The purpose for the INTERVAL function is to set the duration for powering the specific device or module (DEVICE 1) that is connected to the timer module. The user, following the preceding logic functions stated in this paragraph, may set the power interval for one hour and fifteen minutes, by depressing the input button upon the display of the word, INTERVAL, then depressing the input button upon the display of, HOUR, then depressing the input button upon the display of, 1, then depressing the input button upon the display of, MINUTE, and finally keeping the step button depressed until the number 15 is shown on the display, the user lifts his/her finger from the step button and depresses the input button. The display then shows the characters 1H 15M and the user depresses the input button to set the air freshener to operate for one hour and fifteen minutes upon the activation of the motion detector module in the pedestal.

The communications module may be comprised of the following components: main circuitry; module interfaces; an electrical housing interface; circuitry settings; radio frequency (RF) settings and transceiver; and an exterior housing. The transceiver component is connected to an antenna that may reside within the module housing or reside outside of such housing and protrudes upward from a rear corner aperture of the pedestal. Such antenna may be no more than three inches. The communications module is comprised of the same circuitry, interface and connecting materials that are comprised in the motion detector and timer modules. The circuitry settings are comprised of the same materials and components of such settings that are associated with the motion detector and timer modules. The RF settings and transceiver component is comprised of similar materials utilized for the previously cited modules' circuitry and setting components. The module exterior housing may be comprised of, but not limited to, a moldable plastic material or hard synthetic rubber composition. The exterior housing comprises interconnecting components such as, but not limited to, clips for holding the module components, especially the circuitry and connecting enclosures in place and secured from undesired external exposure. As appropriate, some of the exterior housing fastenings may be adhered to other component interconnectors by a bonding means or compound such as, but not limited to, glue, hot glue, epoxy, heat weld, etc.

The communications module main circuitry connects to the module interfaces, the module electrical housing interface, circuitry settings and the RF settings and transceiver. The module interfaces associated with such circuitry in this narrative sample setting and configuration are connected to the timer module and the motion detector module. An open circuit connection may be associated with only one module, the timer. The module electrical housing interface is connected to the back frame electrical connector receptacle. The circuitry settings are set for open circuit connections (since the motion detector setting associated with the interface for module is closed, no contact will be transferred from module to module). The RF settings may be comprised of dip switch settings (among other forms of settings) for establishing a RF coded signal (from a combination of at least 64 codes) that is operable in the respective area where such signal is received by the associated RF receiver (such RF receiver may also have a RF setting component in order to calibrate the appropriate signal transmitter-receiver match) that may be associated with the operation of an electrically powered fixture such as a lamp. Such RF signal and equipment conforms to Part 15 of the FCC Rules. The transceiver is connected to the main circuitry, the associated RF settings and the antenna. Said communications module may be in a variety of embodiments to support a variety of communications protocols. Such protocols may be, but are not limited to, ZigBee™ (which will be described further in the narrative), Wi Fi, Bluetooth, powerline, X10, and Ethernet compatible embodiments.

The operation of the communications module that is associated with the present invention integrated module configuration described herein is based on the electric power source connection that transits into the module electrical housing, through the main circuitry and to the transmitter component; and a circuit connection from the timer module which is originated from the motion detector module.

The air freshener module is comprised of the following components: main circuitry; module interfaces; an electrical housing and interface; circuitry settings; heating unit and transfer plates; chemical agent cartridge or disc; vaporizer conduit; and an exterior housing for the electrical, circuitry and heating components. The air freshener module is comprised of the same circuitry, interface and connecting materials that make up the respective like components in the other present invention modules. The circuitry settings are also comprised of the same materials and components associated with such settings that reside in the other present invention modules. The heating unit and transfer plates are comprised of components for supporting a small heating unit means such as, but not limited to, a coil resistance heater or a metal oxide resistance heater as well as electrically conductive material such as copper for such transfer plates. The chemical agent cartridge and associated vaporizer conduit may be comprised of a translucent hard plastic material for said cartridge for displaying (in this illustrated invention embodiment) a liquid form agent and a vapor permeable plastic component for said conduit which may be, but not limited to, a wick. The module exterior housing may be comprised of, but not limited to, a moldable plastic material or hard synthetic rubber composition. The exterior housing for the electrical, circuitry and heating components comprises interconnecting components such as, but not limited to, clips for holding the module components, especially the circuitry and connecting enclosures in place and secured from undesired external exposure. As appropriate, some of the exterior housing fastenings may be adhered to other component interconnectors by a bonding means or compound such as, but not limited to, glues.

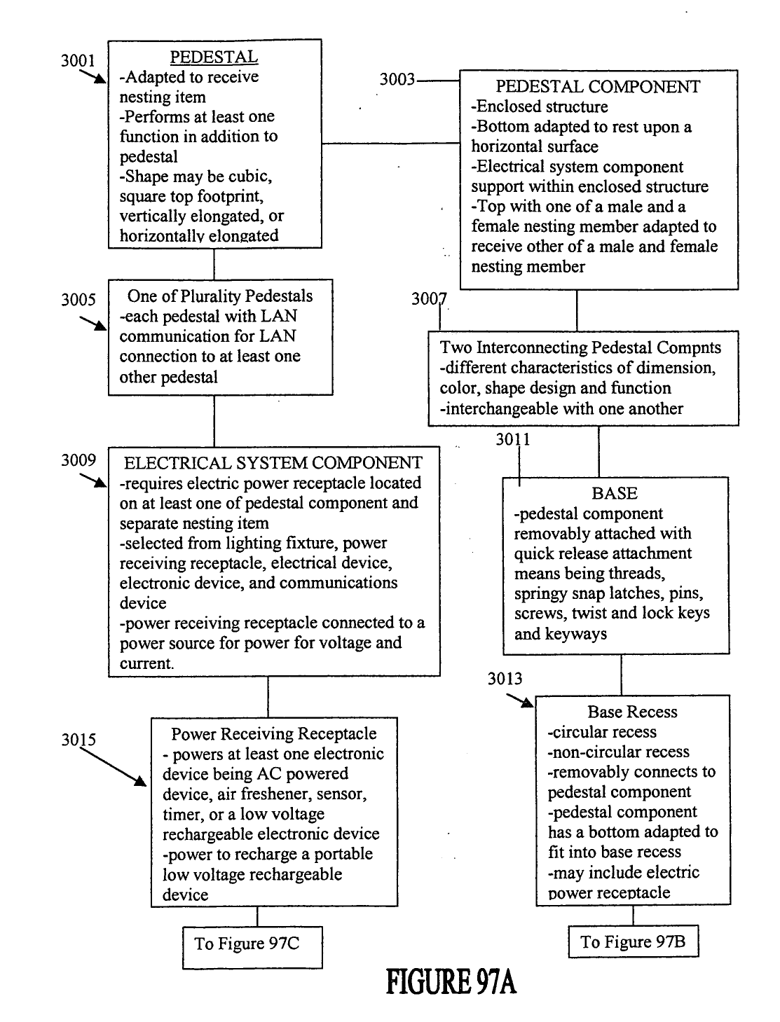

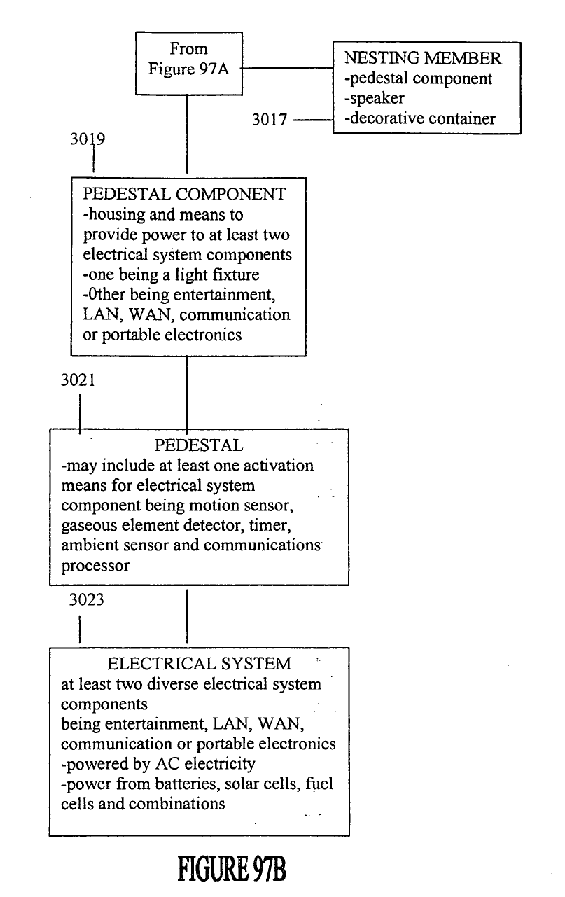

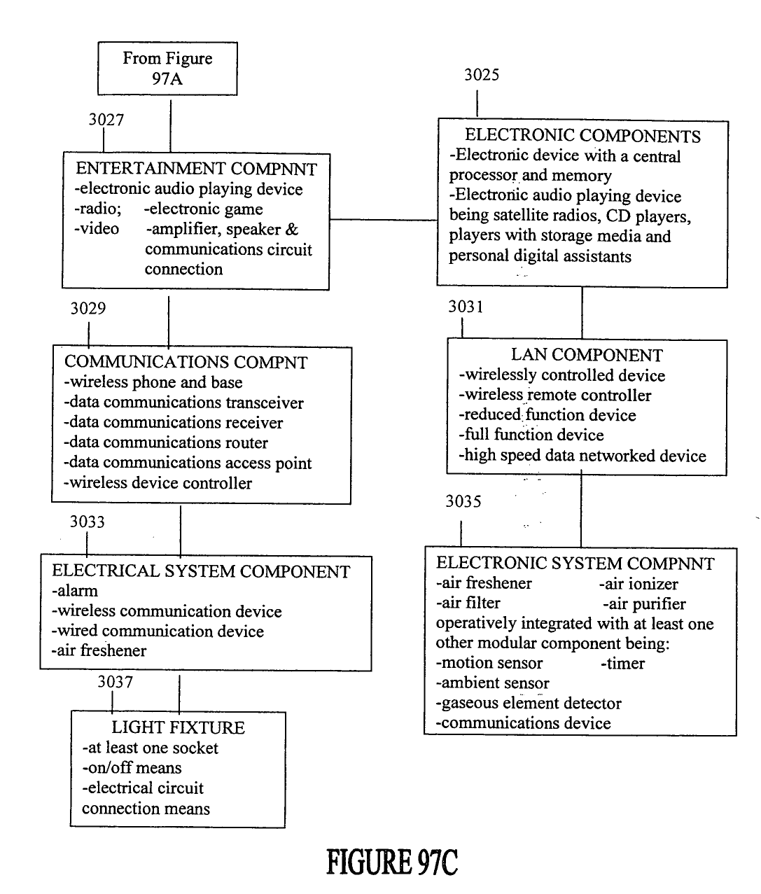

The air freshener module main circuitry connects to the module interfaces, the module electrical housing interface, circuitry settings; and the heating unit transfer plates. The module interfaces associated with such circuitry in this narrative sample configuration connect to the timer module. Such circuitry is secured in place through the fastening and support means of the exterior housing assembly. An open circuit connection is associated with such module. The module electrical housing interface is connected to the back frame electrical connector receptacle. Such back frame electrical connection may have an off switch setting that is associated with module for this sample configuration, because the power source for such module is generated from the timer module. As previously noted for this configuration, this module to module connection is supported through an aperture in the electrical housing center frame. The circuitry settings are set for open circuit connections. The heating unit is connected to the transfer plates. The heat transfer plates are connected to the main circuitry, the electrical housing interface and the heating unit. The chemical agent cartridge may be connected to the module exterior housing through a variety of interconnecting means that support attachment to and detachment from such housing. Such means may be male protruding edge components and female grooved slots. Additionally, the cartridge may also be held in place through the movable interconnecting means supported by module release buttons and associated components. The vaporizer conduit associated with this invention embodiment previously described in this narrative may reside along the bottom portion of and protrude upwardly through and out of a top aperture of the cartridge container. Such conduit also passes through an aperture in the exterior housing where such housing area performs the following functions: supports an inner portion heat transfer component that may consist of parallel plates that, though concealed in the housing, surround a portion of the vaporizer conduit to facilitate evaporation; and also supports the venting and dispersion of the chemical agent through its structural form. The exterior housing, in addition to providing the structural support and connecting means for its contained components and the dispersion of the chemical agent or scent, also has a portion that connects to and may also protrude through a top exterior housing aperture or aroma emission orifice of said pedestal as depicted in FIGS. 97 through 99, 104, 105, and 109.

The operation of the air freshener module that is associated with the present invention integrated module configuration described herein is based on a power source connection that passes through the timer module and module interface that is originated from the back frame electrical housing connection associated with said timer module that transits through module circuitry out to the module and interface upon the activation of an open circuit which may be caused by three conditions—the activation of a time and/or date set range from said timer program, the activation of a motion detector, or the receipt of a communications signal with an associated command set to activate said air freshener module.

Upon the activation of a pre-programmed time start set program, the timer processor may open a circuit current for the circuit lead(s) that connect(s) to the module to module interface. Such electrical current may transit from such module to module interface to the module circuitry and through such circuitry to the heat transfer plates. The heat transfer plates serve a dual purpose of conducting electricity and heat when the latter element is caused by the activation of the heating unit from the electric current that transits the heating transfer plates and terminates into such heating unit. The heating unit emanates heat in the direction of the heating transfer plates that may reside, though concealed in the module exterior housing, alongside the chemical agent container or disc and, as previously noted, the vaporizer conduit that protrudes from said agent container. Even though the heating unit shuts off upon the loss of power due to a pre-programmed stop time, the scent emanates for a longer period from such stop time and the essential oil or other form of chemical agent lasts for a longer period (in contrast to prior art systems that do not comprise any on/off, timer or other integrated activation means such as the means described herein).

As noted, the air freshener module may also be activated by the detection of motion from a sensor of said motion detector module. In this scenario, the electrical connection that originates from said motion detector module, transits through the module to the module interface and connects to timer module circuitry, activates the circuit lead that activates the timer processor to activate the interval program and open the circuit leads associated with the module interfaces that are associated with the devices and/or modules associated with such interval program. The electric current traveling over such circuit leads and transiting to the module to module interfaces triggers the operation of the air freshener module in the manner described in the preceding paragraph.

The air freshener module in the present invention pedestal system is one embodiment which may be part of, but not limited to, a module enclosure, housing or networked device. This module embodiment may be in other forms as a standalone or networked (with other air fresheners, modules, sensors or other components) unit. Being networked, the module may be linked to processors and software and/or sensors to function at different emanation levels with different scents (for example, with a multi-cartridge oil and wick module, cleanser components, or a multi-scent disc module component). For example, an ambient light sensor may interconnect to said air freshener module and a sunrise may activate a program to emanate a coffee scent. Another example may be a module comprising or being connected or networked to a device comprising a clock, timer or timer parameter where such module may release a rose scent in the morning and a lavender scent in the evening. Being networked or integrated with other components, the air freshener module may be adapted for a variety of invention embodiments. Other invention embodiments may range from a decorative enclosure that may function as a night light and adapted for an air freshener module, to a jack-o-lantem enclosure with a flickering, dimmer and/or constant illumination component that may have an air freshener component that emanates a pumpkin scent or autumn scent, to illuminated (or non-illuminated) seasonal or holiday themed containers, vases, urns or like enclosures that may emanate a pine scent or pot-pouri scent where such scents may emanate from an air freshener with a timer or networked component that may cause the activation of such freshener. Another embodiment may comprise a means for providing an alert function when, for example, but not limited to such example, an essential oil quantity, mixture or level in a vial, cartridge, or chamber may be close to a near empty level. Such alert function may be activated when, for example, a certain contact is not immersed in the oil component or a certain sensor detects a different chemical composition, and such contact or sensor causes a circuit connection for an alerting function to trigger the operation of an illumination, audio (such as causing a chirping sound), and/or communications component(s) (pending on the application and supporting system, an email communication may occur for the purpose of adding a certain scent cartridge to a PDA Shopping List program).

The air freshener module is an embodiment of a chemical and chemical dispenser module component that may be in a variety of present invention embodiments, such as the air freshener components and enclosures described herein, as well as a present invention embodiment comprised of an insect repellant module that may be integrated or added to a fixed or portable outdoor lighting component. Such dispenser modules may consist of a heating component or a spray component for diffusing the chemical agent. The active chemical agent, pending on the application, may, therefore, be functioning as any of the following: a fragrance; air freshener; deodorizer; odor eliminator; insecticide; insect repellant; herbal substance; medicinal substance; disinfectant; sanitizer; mood enhancer; aroma therapy composition; and/or a combination or like substance. It may be in liquid form, such as a volatile essential oil for an air freshener agent, which may be synthetically formed and/or naturally derived. An air freshener agent for the embodiments described herein may also be in gel or solid form.

The present invention embodiments for providing the means to integrate an air freshener, motion detector, timer (or other mode program), and even communications component in a space-saving and electrical outlet-saving decorative enclosure such as, but not limited to, those described herein, offer a number of benefits to the end user. The convenience of having certain lights turn on along with having a pleasant, relaxing fragrance emanating from a decorative display in a non-cluttered entry way, upon the opening of a front door (especially an apartment front door, where space may be at a premium) enhances the quality and safety for the end user (without the concerns of forgetting to extinguish a burning candle or having to navigate through a dimly lit apartment with bundles, a bag and a brief case).

The pedestals shown in the above Figures, like other invention enclosures, pedestals and bases described herein may have a number of embodiments to account for various module configurations as well as accommodating existing standalone electrical (or electrical socket) fixtures or products (such as, but not limited to, night lights, bug repellents and air fresheners). For example, FIG. 72 also illustrates the pedestal with an electrical plug socket (such pedestal may have more than one plug socket) and decorative modular and interchangeable housing on its front portion (which also may have such configuration on other side or circumference portions), to accommodate, among other electrical socket fixtures or products, an air freshener or air freshener and night light combination. Such electrical socket may be connected to an electrical connector which may be connected to a cord or a device controller component or a timer module or a networked embodiment of said component or module. Such decorative modular and interchangeable housing may be available in a variety of designs, patterns and colors to coordinate with vase, urn, or other vessel designs, forms, patterns or colors. Such pedestal may also have a circuit breaker and reset function to account for electrical loading and UL requirements.

Another invention embodiment of a pedestal having at least one electrical plug with the functionality and connections described in the preceding paragraph may be a base adapted for a running water/rock/garden landscape (some of these systems have mist/fog features). Such base may have a motion detector (or other modular means for providing activation) and circuitry means to activate the preceding system embodiment in conjunction with optional air freshener, nature sound, and speaker modules.

The flower vase and vase enclosure systems of FIGS. 67 through 72 are present invention embodiments for supporting electrical modules and/or components. They may be comprised of the following: apertures for electrical connections, venting to dissipate component heat, a vase ring, an ambient light sensor, a flower illumination portion, night light, motion detector, and scent diffusion; a module and electrical housing frame; a motion detector module; a timer module; an air freshener module; and protruding cavities. They may be comprised of a variety of shapes and materials that are associated with such type of vessel such as, but not limited to, plastic composites, pottery, clay, porcelain, or wood with a variety of finishes, inlays and designs.

Said vase and/or vase enclosures may comprise at least one aperture for electrical and external component connections. Such aperture, at minimum, supports the main electrical connection which may be a modular plug connection and is sufficiently sized to support other wired connectors to and/or from other devices or modules. Such aperture is, preferably, located near or at the bottom side of such vessel in the back, for those vessels that may have a discernible front and rear design, of such vase. The apertures for releasing heat, which may be emanated from electrically powered modular components such as, but not limited to, those described herein, may be located, in various forms, on the rear (having a mid or upper portion) as well as near the top corners (as slits) on these vases. The vase ring apertures will be covered in the next paragraph which explains the vase ring component. The ambient light sensor aperture may be preferably located anywhere on or near the top portion of the vase in such a manner that supports the design theme of such vase. An aperture for a lighting component that may swivel and face upward toward the flower or planting arrangement may also be located on such vase. An aperture or set of apertures (such as a pattern of perforations that may illuminate a form or forms) may be located on a suitable portion of the vase where such apertures may provide a night light illumination. Another aperture may be located near a lower center portion of the vase for providing a sufficient opening for the sensor component of a motion sensor. Another aperture, which may be part of a protruding portion of the vase, may be utilized to support the dispensing upper portion of an electric air freshener.

The vase enclosure ring is a detachable and interchangeable invention embodiment for supporting a variety of design and component support functions. Given its variety of utilities, it may be available in a variety of forms with or without accessory components. For the purposes of the invention embodiment configuration associated with said system, the vase enclosure ring may function as a top portion inner vase enclosure, an aperture portion for an electric air freshener, and a top portion module enclosure for a module and electrical housing frame which resides inside said vase enclosure. Such functions support the multi-utility characteristics of the present invention embodiment while supporting the functional and aesthetic design of a flower vase.

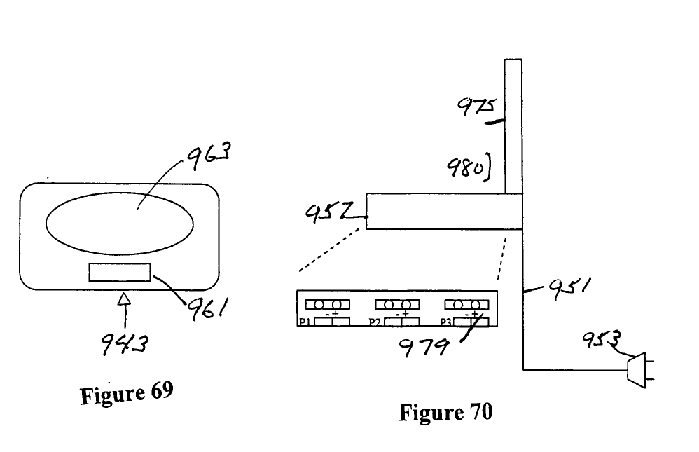

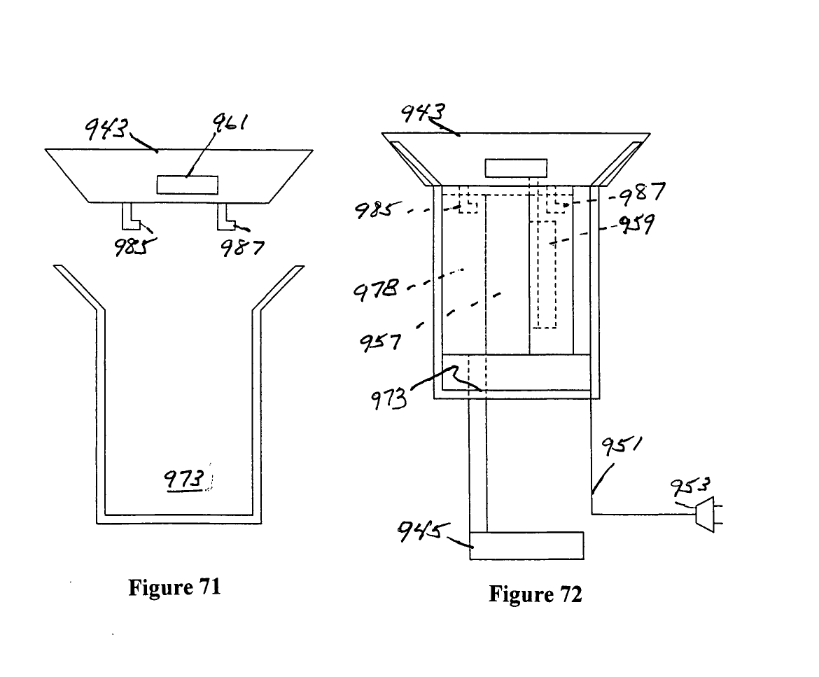

FIGS. 69 and 71 depict top and side views of a vase enclosure ring which reflects interconnecting components for connecting to the top portion of the vase and a center open portion with a rear portion center edge that is closer to the top rear edge of the vase in comparison to a front portion center edge that is recessed-further from the top front edge of the vase. The purpose for such difference is to sufficiently cover and provide ventilation for the various modules that may reside in the front portion of the flower vase. Said ring may be comprised of the same materials, finishes and patterns that are associated with said vase or vase enclosure.

FIGS. 70 and 72 also depict the module and electrical housing frame which supports the modules, power source and respective connections between such modules and the modules and power source. It may be comprised of metallic and/or hard plastic composites for the frame support and housing components and electrically conducting materials such as, but not limited to, copper for the connectors. The frame is comprised of a bottom frame power and module receptacle, a side frame electrical component, and a main brace frame.

The bottom frame power and module receptacle comprises a main electrical interface and housing component, electrical feeds and electrical connectors. The main electrical interface and housing component may be in a variety of forms such as, but not limited to, a modular plug receptacle, interface and housing component or a directly connected interface and housing component. The modular plug receptacle may be a female receptacle for an electrical cord that may run through the bottom side vase aperture and terminate into such receptacle component. The directly connected interface and housing component may be a hard-wired connection for such electrical cord that may run through the vase bottom side aperture. The main electrical interface is connected to three electrical connector feeds: the external power connection feed or the previously noted receptacle; the module connector feeds; and the side frame electrical component. The housing is for supporting and covering the interfaces and connectors, as appropriate, with the suitable connecting and bonding means and materials that have been previously noted in this narrative. The bottom frame module receptacle component may comprise female electrical connectors and a power switch for each respective module connection. The purpose for such power switch is to support the same power options associated with the modules that was described in the pedestal narratives above. When a user may desire to have other modules such as, but not limited to, an air freshener module be operable based on parameters that may be controlled by a timer module, the user may set the bottom frame module receptacle switch setting that is associated with such air freshener module to an off power setting.

The side frame electrical component is the electrical power and circuit interface connection for modules that may reside in the upper portion of an enclosure. This component is a modular component and may be available in a number of designs in order to support a variety of utilities. In one multi-utility invention embodiment, it may be a housing component with a similar construct to a housing component such as HC2 (described in conjunction with FIGS. 57 through 61 above, identified as HC 2), which is a component that may comprise two power feeds or sources, a processor and a USB connector. In its primary form, it may function as an electrical connector. Even though the vase enclosure system configuration described herein does not account for any upper enclosure modules, such side frame may be utilized for future functionality such as supporting a vase enclosure ring that may comprise a floral illumination component.

The main brace frame supports the bottom frame power and module receptacle, the side frame electrical component and the placement support of frame inside said vase enclosure. The bottom and side frames may be secured to the main brace frame by a variety of interconnecting means, such as nut and bolt assemblies. The top portion of the main brace frame extends in an outward fashion on all sides and/or circumference(s) for the purpose of residing on a recessed inner lip of the vase that supports such main brace. The top portion of the main brace frame may be available in a variety of shapes to accommodate the vase and vase enclosure design. The main brace frame may be comprised of a durable plastic and/or metallic composite(s).

The motion detector, timer, and air freshener modules comprise the same components and materials that have been described in the narrative associated with the pedestal. The modules' exterior housings differ for accommodating components in an upright standing position to support the vase standing form in contrast to being in a side position for accommodating module fitting under the pedestal planar surface. In addition, the shapes of the air freshener chemical agent cartridge and vaporizer conduit also differ by being in an upright position (the vaporizer conduit is in a straight upright fashion) to support the vase and vase enclosure standing form.

There are many benefits that are associated with the preceding present invention multi-utility vase enclosure and like present invention enclosure systems. For example, at minimum, this system may be very helpful to apartment unit residents where, such apartment may have limited space and such space or occupancy requirements may not support the positioning or placement of a motion detector on a wall or ceiling mount.

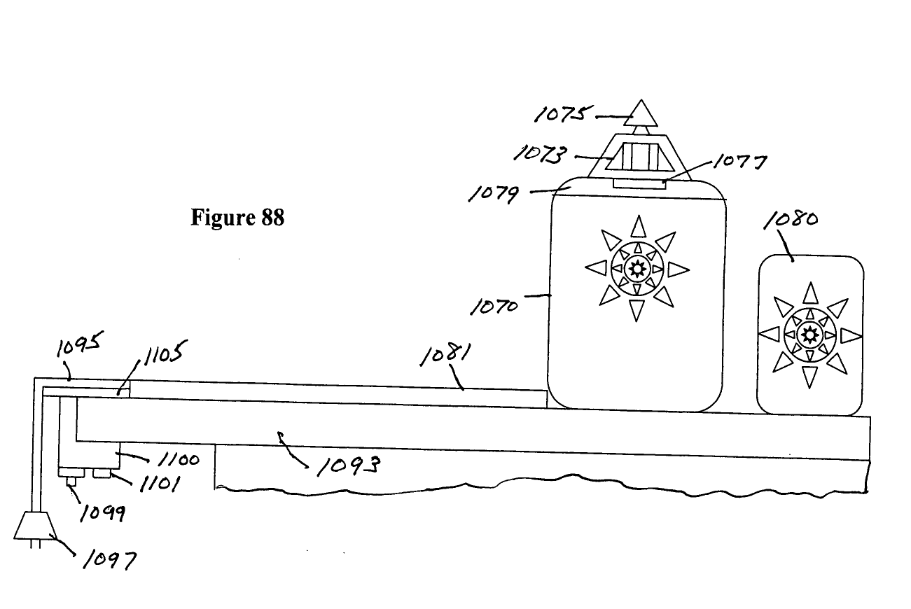

Another invention embodiment enclosure that supports multiple utilities in separate and/or integrated means is an urn system as shown in FIGS. 86, 87 and 88) which supports, but is not limited to supporting, the means and functionality of the urn of FIG. 88, and an additional means for providing multiple electrical outlets at its base, preferably in various concealed forms and functions, with a circuit breaker and reset function. Said urn may have accessory components such as a countertop and/or shelving brace support or fastening means and an electrical guide track or duct (FIGS. 87 and 88).

The urn may provide many benefits in compact rooms with scarce electrical outlets where a user desires to use electrical appliances such as in a bathroom. One sample embodiment of the urn for a bathroom application may comprise an integrated module system of a motion detector, air freshener, timer, night light, radio frequency (RF) transmitter (for activating a bathroom light) and electrical outlets with a circuit breaker. Pending on the counter or bathroom shelving layout, the urn may have a supporting brace or fastening means that may adapt to either a counter or shelving. One of the primary purposes for such fastening means is to anchor the urn when appliances such as a blow dryer or electric curler may be used where such use may cause a pulling (and potential dropping) of the urn off the counter space.

FIG. 88 illustrates an urn on a countertop. The urn may be available in a variety of shapes, such as, but not limited to, circular, spherical, octagonal, rectangular, and/or square. It may have a center portion that may be lifted, turned slightly and rested on a set of lower portion inner column frames. The lifting and resting of center portion results in exposing lower portion electrical outlets that are positioned sufficiently above (to avoid water contact) and parallel to the counter surface and such outlets are recessed between a column frame. Each electrical outlet may have a power status light and a reset button.

The urn contains a module and electrical housing frame to support the modules described herein. Such frame may function as and comprise the same components associated with the module and electrical housing frame.

The urn and its associated modules may be comprised of the same materials as the other like present invention embodiments described herein. It also may comprise the like apertures of the flower vase to support, but not limited to, the following: electrical connections; venting component heat; an ambient light sensor; a night light; motion detector; and scent evaporation.

As previously noted herein, the present invention also accounts for another invention embodiment of utilizing a multiple electrical outlet component as described for the urn as an optional configuration for the present invention multi-utility pedestal system.

Another invention embodiment which may support yet other invention embodiments is the means to network devices amongst enclosures and/or modules through various data interface and/or electrical circuit connections (wired and/or wireless). For example, the present invention also accounts for lighting fixtures, such as, but not limited to, a table lamp that may have a data interface (such as, but not limited to, a USB) connector, processor connector or electrical circuitry connector in one or more of its modules where said configuration is utilized for supporting networked components or devices associated with such interfaces. An example of such a module is a present invention electrical/electronics assembly housing component. (FIGS. 57 through 61). Even though this component is depicted herein in primarily lighting products, this invention embodiment supports a characteristic of utilizing interchangeable components to add value to a variety of fixtures, enclosures, appliances, dispensers and other embodiments described, but not limited to solely those described, herein. Such interface connector and/or processor component may be connected to a present invention wireless receiver module and/or a present invention motion detector module, where such module comprises components that may originate a circuit connection to an external device or external module such as the present invention air freshener module (which may be housed in a present invention pedestal or a present invention flower vase that comprises components and connectors described herein). As noted in FIGS. 80 through 86, given that, for example, Housing Component 2 (HC 2) may comprise a multi-device timer processor and program, the operation of the preceding air freshener module may be controlled by a HC 2 in a present invention table lamp embodiment.

The preceding table lamp/data interface/flower vase/air freshener illustration may apply to a variety of other analog invention embodiments, such as, but not limited to, a present invention table lamp with an invention Wi Fi bridge module embodiment that may function as a Wi Fi access point for one or more device terminations and/or a Wi Fi repeater. Such Wi Fi component may have antenna(e) in the upper portion of the lamp, where said antenna is sufficiently away from the lighting component and circuitry components that may be in the upper, mid or base portion of the lamp that may connect through one or more Housing Components (similar to the one stated in the preceding paragraph). Such Housing Component may connect to the base of the lamp and may have connections at its top, side and bottom portions. The lamp base connection may interface with other base connections for internal and external devices. Such external devices may be a digital picture frame and/or LCD component that may display content, such as, but not limited to digital pictures, received via the Wi Fi communication network. The lamp may also have invention embodiment broadband interface module components for receiving and communicating digital content. Such invention Wi Fi or wired broadband interface module may also be interconnected in the manner previously described to an external device such as a Voice Over Internet Protocol (VoIP) phone or a VoIP analog telephone adapter (ATA). Such ATA may also reside in the upper, mid or lower portion of the present invention table lamp. The preceding example provides a means for enabling a user to have a VoIP call while having a phone, for example, on an end table in proximity to a lamp on the same end table without the clutter of the technology equipment that is utilized for such a call on or near the same end table.

One of the many advantages of the embodiments cited in the preceding paragraphs is economy of monetary investment and space. For example, instead of buying a standalone digital picture frame with software and wireless components, the user may buy the frame, software and a connection (USB or Ethernet) and utilize the wireless capabilities of the present invention embodiment of a Wi Fi module for a lamp. Such Wi Fi module may provide the means to interconnect with other devices and thus the end user does not have to buy a wireless communications component solely for the digital picture frame. The appearance of simplicity of a digital picture frame (without the wireless component) alongside a table lamp on an end table is also appealing.

The key means of one invention embodiment to support multi-utility functions and components in a lighting fixture such as, but not limited to, a table lamp, is, again, illustrated in FIGS. 56 through 63. FIG. 56 is a top view of the following multi-utility lighting fixture components: a motion detector module; a central shaft guide; central shaft electrical/electronics housing component designation guides; a base stand; electrical/electronics housing component; and a power panel. For the purpose of facilitating the review of the illustration described herein, a legend associated with the housing components, such as HC2 is in FIG. 59.

The motion detector module may be connected to a base stand power source such as one that may be utilized for housing component's (HC) second power connection or HC 2 P2. Such module may also have an interface, such as, but not limited to a circuit or USB connection which may connect to HC 2's second USB port connection or HC 2 U2. The purpose for such a connection is to activate a multi-device timer processor which resides in HC 2 when motion is detected. Such timer may be connected to other devices within and outside of the lamp where such timer may control the operation of such devices.

The central shaft may be a modular component that: may house at least one housing component; may comprise male (base stand interconnecting component) and female interconnectors (interconnecting aperture) to the base stand and the upper lamp portion; may comprise apertures for housing component and module port and/or wired connections; and may include electrical/electronics housing enclosure guides.

The electrical/electronics housing component guides support the positioning of each housing component and are located inside the central shaft, above and below the central shaft housing component apertures.

The base stand may be in a variety of forms and embodiments and comprise electrical and data connection ports and feeds for the lamp components and respective power sources (AC for the lighting component and DC for the devices/modules), apertures for module devices such as motion detector, and interconnections for a central shaft and user interface.

The electrical/electronics housing component may be in a variety of embodiments based on the desired functions associated with such component and the multi-utility lighting fixture. This component comprises the means to be interconnected, inter-fastened or guided to, but not limited to, the lamp central shaft component, the lamp base stand, other housing components within the central shaft or in the upper portion of the lighting fixture, devices/modules within the lamp base enclosure or external to the lamp, and the user interface.

The primary lighting power source for the configuration illustrated in FIG. 56 is the first housing component HC 1. HC 1 may be in a variety of embodiments. The embodiment accounted for in FIGS. 56 and 63 comprises four power connections for primary lighting and devices. A sample configuration associated with such power source may be a lighting fixture with a Wi Fi bridge and a remote control (RF) receiver for wireless remote control lighting. With reference to the illustration legend, the HC 1 ports utilized for the configuration described herein are: P1, P3 and P4. P1 is the power connection for the lighting component. P3 may be the power connection for the remote control receiver. P4 may be the power connection for the Wi Fi bridge. As with all modules and/or devices associated with the aforesaid housing component and the present invention lighting fixture, such modules and devices may reside in other portions of the lighting fixture. For example the Wi Fi bridge and the remote control receiver, which may utilize RF or infrared signals, may reside in the upper portion of the table lamp. Though it is not depicted in this configuration, P2 may be a power connection for an illuminating base enclosure that may be turned on and off separately from the main lighting switch.

The external AC and DC power source for such connection may originate from an AC and DC power cord (FIG. 63) that terminates into the AC and DC ports of the power panel depicted in said FIG. 63. Such component ports have power feeds in the base that connect to HC 1 through male and/or female interconnectors and receptacles.

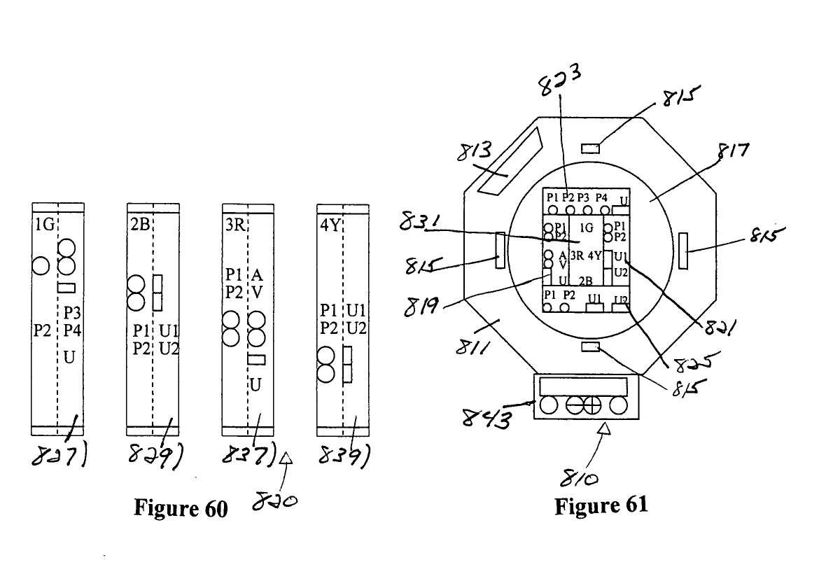

The user interface (FIG. 61) is a detachable programming and/or inquiry interface tool that may connect to the administration ports of said housing components (depicted in top view of FIG. 61) and other present invention modules, such as a multi-device timer module (which may be available with an integrated interface as described in the pedestal system narrative or a modular interface).

Said user interface may be in a variety of embodiments. The embodiment described herein is designed to utilize a menu prompt program. Said interface, as depicted in FIG. 61, may comprise a LED display, two input buttons located below and on the left and right sides of such display, and two scroll buttons. It is designed to interact with a variety of programs, such as the timer module program described herein, and may integrate with a keypad adjunct module. It is comprised of the same materials and components as those associated and described with the timer module user interface.

The power panel of FIGS. 56 and 63 may also be in a variety of embodiments. The illustration and configuration described herein accounts for ports for four power cords. Such cords are a unique AC and DC power cord (FIG. 63) and three DC power cords. Though it may not likely be necessary to load or require such amount of power into a multi-utility light fixture, (especially in a residence that typically utilizes a 15 to 20 amp circuit), the power panel configuration is illustrated to account for such a possible loading, subject to UL approval.

Another power panel embodiment may comprise, but is not limited to, a primary power interface that may consist of one AC port and one DC port that may have electrical circuit feeds to the base housing component interconnections. Such a configuration may account for a circuit breaker and reset button that may reside on said base. Another power panel embodiment may comprise one primary power interface and connect to an AC and DC juncture and converter residing in the lighting fixture or multi-utility fixture/enclosure (this is not a preferred embodiment due to limited lighting fixture space utilization, but it still may be useful for certain configurations). Yet, another power panel embodiment for the present invention systems, but not limited to said systems, described herein may account for a primary power interface and a battery back-up power interface.

The preceding components described and illustrated in FIGS. 56 through 63 may be comprised of primarily electrically conducting (such as, but not limited to, copper), hard plastic and rubber composites, processor-related, and/or metallic or ceramic materials as suitable for performing the utilities associated with such components.

The modular component characteristics described in the preceding paragraphs may be streamlined significantly to account for another invention embodiment that may be a lighting fixture comprising one or more modular components. For example, a lighting fixture may be comprised of few interconnecting lighting components and one modular non-lighting component. This characteristic may be viewed as a present invention predecessor embodiment to a lighting fixture that comprises a more sophisticated housing component such as a housing component 2 or HC 2. One of the purposes for the design of such lighting fixture is to reflect a phased manufacturing staged product to minimize lighting fixture design retooling. In this regard, said present invention embodiment may account for a Wi Fi bridge upper portion housing component which may also house the lighting fixture upper components and a wireless remote receiver; a Wi Fi bridge modular component; a DC power component which may be alongside the lighting electrical component; a DC power base interconnecting component; a lamp base AC power port; a lamp base DC power port; an AC and DC power cord (FIG. 87) which comprises an AC cord base connector and a DC cord base connector, an AC plug-in power cord, a DC plug-in power cord, a power cord portion with an AC and DC electrical housing with AC and DC cord ports; a lamp base and shaft; and an upper lighting portion.

Another set of present invention lighting fixture embodiments with key modularity and interchangeable characteristics that account for not only manufacturing, but also shipping economies, is a collapsible lamp system that comprises predominantly collapsible components (FIGS. 89 through 96). Specifically, this type of invention embodiment is a knock-down lamp product that provides the consumer a valuable offering (very economical and may come in a lot of varieties) and the retailer, shipper and manufacturer a very low-cost product. The benefits are derived by the purpose of the following utilities of such product which is to accomplish the following: 1) deliver an aesthetically pleasing product that may come in a variety of shapes, faux-materials, faux-textures, patterns and even prints (that are on malleable plastics and unique for lamp lower portions); 2) deliver a product with a minimal amount of parts to mitigate loss of parts; and 3) deliver a product that takes up a minimum amount of package and, thus, container space.

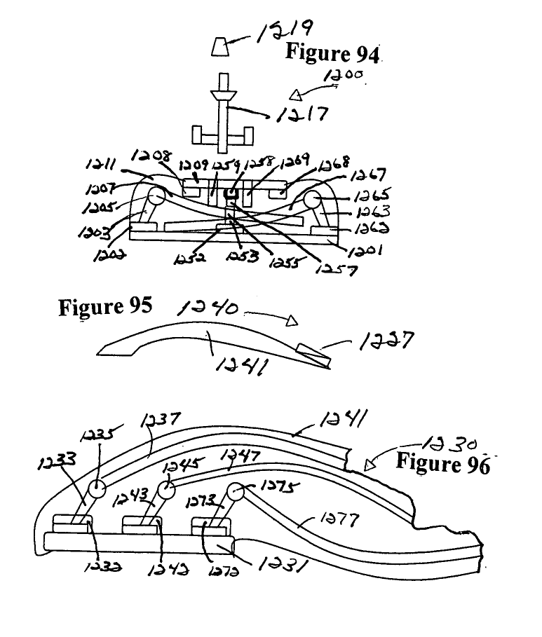

This product may be in a number of embodiments relative to shape, components and utility functions such as lighting and non-lighting functions. One basic embodiment may be comprised of the following components: 1) a one-piece collapsible lamp shade with harp brace portions (FIGS. 89, 91 and 94); 2) a finial component and upper harp brace (FIGS. 90 and 94); 3) a lower harp brace ring (an optional component); 4) a main lighting component (FIG. 90); 5) a one-piece collapsible lamp lower component (FIGS. 90, 91, and 95); and 6) a lamp base outer stem (FIGS. 90 and 91). Another embodiment may be comprised of the following components: 1) a one-piece collapsible lamp shade and harp (that includes a lower harp brace ring component that is hinged at the tip of one of the harp tubes—not depicted in the Figures); 2) a finial component and upper harp brace; 3) a main lighting component; 4) a one-piece collapsible lamp base; and 5) a lamp base outer stem. This product may also have accessories such as a decorative and functional ring that may serve as a snug fitting between the bottom base portion and an insertion portion of the lamp base ring.

The collapsible lamp shade and base components may be comprised of cloth, stitching, and malleable plastic/vinyl materials. The present invention tubing and insert components which are utilized for knock-down and structural support functions may be comprised of flexible, taut and durable metallic and/or plastic composite materials. The present invention frame components may be comprised of durable metallic and/or plastic composite materials. The tubing and frame structures may be of a variety of shapes such as circular, spherical, octagonal, rectangular and/or square to support the respective lamp shade and/or lamp base shapes.

The one-piece collapsible lamp shade and harp (FIGS. 89, 91, 93 and 94) is comprised of at least two horizontal frame components for supporting the lamp shade frame structure, tube or rib inserts, tubes or ribs and/or top finial frame and pivotable upper harp brace portions. As depicted in FIGS. 89, 93, and 94, such frame components for the configuration described herein are top and bottom ring braces. The lamp shade with an outer portion wraps inward around the top and bottom rings, covering such ring braces and associated tubing or ribs, while exposing the tubing inserts and upper component finial and harp frame. Such shade may be fastened to the ring braces and secured around the tubing frame by means of, or similar, to stitching.

The bottom brace component comprises fixed or secured tube inserts where each insert may comprise a bonding or fastening means for securing a short lower tube or rib portion that supports the directional form of the lower lamp shade portion and comprises a hinged or pivot means for securing and supporting both the knock-down and structural functions that are associated with each respective tube.

The top ring brace component is comprised of two support embodiments: a tube insert embodiment; and a finial and upper harp frame. The tube insert embodiment comprises female inserts that are fixed to such ring frame that face in a direction that supports the form of the lamp shade. Such insert is to support and secure its respective tube or rib end when such tube/rib is fastened and/or placed into such insert in a taut fashion. The finial and upper harp frame component is comprised of two types of supports: a finial support and an upper harp support. The finial support may be a horizontal component with an inner centrally located horizontal frame such as, but not limited to, a ring (as depicted in this configuration), where such ring is supported by at least three brace legs where each brace leg is of equal length and has one endpoint that may terminate into the ring at a circumference point that reflects an approximately equal distance from the other brace leg and has the other endpoint terminating into the top ring component. The upper harp support consists of three separate fixed harp tubes where each tube has a swing component on one of its ends and such swing component is secured around a separate finial support brace leg at the portion of such leg that is near the inner ring or hub. The swing or pivotable component as described herein provides the means for flattening the harp portion of the lamp and mitigating the need for separate harp components.

The present invention finial component and harp brace provide the means for securing the harp brace structure in place while also securing the lamp shade to the harp brace structure. This component has a vertical central piece that supports two portions: a harp brace and a finial component.

The harp brace is comprised of three legs or cross supports that extend out from the central piece in a horizontal fashion. Each leg has a ring or harp brace portion receiving guide at its outward end. Such receiving guide has a sufficient diameter for receiving a respective harp tube or brace portion and is sufficiently spaced and aligned from the vertical central piece or hub for supporting each harp tube and the resulting harp brace structure.

The component vertical central piece finial component has a narrow width for supporting the placement of its top portion through the inner ring of the top ring of component. Such component central piece may have a small plate or disc with a diameter that is larger than the inner open diameter of the component inner ring that supports the central piece to only go so far through the ring while also being of a strong enough material (such as, but not limited to, metal) to support the lamp shade when the harp brace structure is secured and placed on the lighting component or the lower harp brace ring which resides on the lighting component. Upon the placement of the component central piece through the lampshade top inner ring component, the finial may be secured to the top of such central piece.

The present invention lower harp brace ring may be utilized when the lighting component has a top portion and socket enclosure design that does not comprise three harp tube inserts. The lower harp brace ring is comprised of two components: the ring component and the harp brace component. The ring component is designed for placement on top of the bulb socket enclosure of the present invention main lighting component. It is comprised of electrically resistant material and has an inner opening and form that supports the placement of the electrically conducting and grooved portion of the light bulb through such opening. The securing of the light bulb to its socket secures the lower harp brace ring. The harp brace component is comprised of three legs that horizontally extend out from such ring. Each leg is of suitable length to support a fixed and secured harp tube insert at its end is appropriately aligned to secure such harp tube to the ring.

The main lighting component is comprised of a socket component with electrical switch and housing (upper portion), an upper lamp base support means, a center shaft, an inner base stem, and a power cord. The upper portion has a lamp base support means (located at its bottom portion) for securing the top portion of the lamp base on to the center shaft and main component. Such support means may be in a variety of embodiments such as, but not limited to, a decorative ring with an inner hollow portion with inner grooved edges for receiving a top lamp base fastening ring portion with outer edge grooves to fasten on to such support means. The center houses the power cord which is connected from the socket component through the shaft to and through an inner bottom base support stem. Such inner bottom base support stem may have an indented curved portion on its bottom outer side and a circular side with grooves to support the turning, screwing or attachment and detachment of a lamp base outer stem on to the bottom sides of the inner bottom base support stem. The lamp base outer stem may have a mostly flat portion that is flush against a table surface and may have a curved aperture at its bottom portion to provide the means for the electrical cord to snake from the inner bottom base support stem through the lamp base outer stem bottom curved aperture. It may also have another embodiment, pending on the lamp design, with base legs. For the latter design, the cord may simply be underneath the raised hollow portion of the lamp base outer stem. If the lamp base outer stem has a flat underside portion, the user, prior to turning or securing the outer base stem onto the inner stem, the user may align the outer stem with the inner stem. The bottoms of the outer stem and the inner stem may have a mark for the purpose of aligning the two components properly. The purpose for such alignment is to allow for the electrical cord portion to align onto the bottom curved aperture of the lamp base outer stem. The bottom curved aperture may be comprised of a non-metallic portion to comply with electrical and UL codes.

One of the purposes for the present invention outer base stem is to provide for the attachment and detachment of the lamp base. This may be accomplished through other means, in other embodiments, as described herein.

The one-piece collapsible lamp lower portion may be comprised of the following components: at least two horizontal frame components for supporting the lamp lower portion structure; the lamp lower portion enclosure or covering; tube or rib inserts; tubes or ribs; and at least one base fastening ring.

The lamp lower portion frame components for the configuration described herein are top and bottom ring braces. Said component also comprises the lamp lower portion enclosure with an outer portion that wraps inward around the top and bottom ring braces, covering such braces and associated tubing or ribbing, yet having its top portion tucked underneath the upper top lamp lower portion fastening brace which resides above the top lower portion frame or brace component. Such lamp lower portion enclosure may be fastened to the braces and secured around the tubing frame by means of, or similar to, stitching.

The bottom brace component for the present invention configuration comprises fixed or secured tube or rib inserts where each insert may comprise a fastening means for securing tubing or ribbing in a different manner from the bottom brace component lamp shade tubing assembly. The distinction is based on supporting a collapsible form in a side to side fashion versus the lamp shade collapsible form which is in a top to bottom or bottom to top configuration. The purpose for such side to side form is to support collapsible tubing or ribbing that is comprised of one primary tubing or ribbing component in multiple quantities (such as six tubes for this configuration) in an enclosure that has two relatively narrow horizontal outer rings or openings. Though there may be a number of embodiments around such configuration, the narrative will account for this configuration for the purpose of illustrating a common lamp lower portion design that presents more of a challenge for a collapsible lamp lower portion utility. For supporting the configuration form described herein, each insert is a receiving ring that covers a larger thin chamber for holding in place a thin flat circular component that is on the end of each short lower tube portion. Such tube or rib insert ring and chamber is secured to the lamp base bottom ring brace. The chamber portion allows the lower tube or rib portion and the associated hinged primary tube or rib portion to be turned or pivoted in the desired direction for either a knock-down or upright function, because such chamber portion coupled with the thin tube or rib end provides sufficient means to support the turning or pivoting of the tube or rib component.

The top ring brace component is comprised of two support embodiments: a tube or rib insert embodiment; and a top fastening ring. The tube or rib insert embodiment comprises female inserts that are fixed to such ring frame that face in a direction that supports the form of the lamp lower portion enclosure. Such insert is to support and secure its respective tube or rib end when such tube or rib is fastened and/or placed into such insert in a taut fashion. The top fastening ring portion is secured on top of the top ring brace component and is comprised of grooved side edges for turning or fastening such lamp base to the main lighting upper shaft component.

Upon the securing of the lamp lower portion to the main lighting component, the user may align the lamp base outer stem mark to the inner stem mark and turn or fasten such outer stem on to the inner stem. This final securing results in a low cost and very attractive lighting product.

As described herein, one of the main utilities associated with the present invention multi-function adaptable enclosures is the means to support modular components in a variety of integrated or networked embodiments, wherein said integration or networked embodiments may enhance the safety and comfort of the work and/or living environment. One particular networking means for facilitating such safety and comfort that may be comprised in a number of the present invention embodiments is a wireless communications protocol called ZigBee™.

In support of providing an economical and effective means for the networking of the present invention fixtures and enclosures with reliable data communications, one of the preferred embodiments for wireless local area networked communications is the ZigBee™ protocol. ZigBee™ is the trademark of the ZigBee Alliance Corporation, having an address of Bishop Ranch 2, 2694 Bishop Drive, Suite 274, San Ramon, Calif. 94583.

ZigBee™ is an open wireless network software layer protocol based on the IEEE 802.15.4 standard and is intended to support networking of a variety of devices, from lights to wireless smoke and carbon dioxide detectors, to wireless home security, to utility metering, as well as medical devices previously filed by this inventor.

The ZigBee™ embodiment that may be associated with some of the present invention integrated components such as, but not limited to, the motion detector, timer and communications modules, supports the functionality of sending a short burst of information if a trigger event occurs, such as a detected motion. This functionality also supports a key component for widespread acceptance of the present invention, which is economy. Many of the device interfaces associated with the present invention are designed for low power consumption, simplicity, low cost, and communicating small amounts of data, such as, but not limited to, on/off or dimmer settings, coupled with air freshener emission settings or heating ranges. Such attributes match with a ZigBee™ network Reduced Function Device (RFD). For setting, command or multiple command functions requiring additional functionality, the ZigBee™ standard accommodates such functionality through a Full Function Device (FFD). The FFD may also operate as a router and an overall network coordinator. In functioning as network infrastructure components, they may support a variety of network topologies, such as star, cluster tree, and mesh. ZigBee™'s low power requirements particularly supports the integration of multi-functional modules in the present invention fixtures and enclosures.

ZigBee™, being designed for the hostile RF environments that routinely exist in mainstream commercial and industrial applications, supports the critical need for reliable communications associated with home networks, especially when such networks may include integrated environmental and security sensor embodiments, where such components may be included and networked in the present invention system.

It incorporates an IEEE 802.15.4 defined CSMA-CA (carrier-sense medium-access with collision avoidance) protocol that reduces the probability of interfering with other users. The preceding, coupled with automatic retransmission of data ensures robustness. Utilizing Direct Sequence Spread Spectrum with features including collision avoidance, receiver energy detection, link quality indication, clear channel assessment, acknowledgement, security, support for guaranteed time slots and packet freshness; ZigBee™ offers a variety of component manufacturers and users a highly reliable, standards-based solution.

ZigBee™-compliant products operate in unlicensed bands worldwide, including 2.4 GHz (global), 902 to 928 MHz (Americas), and 868 MHz (Europe). Raw data throughput rates of 250 Kbps can be achieved at 2.4 GHz (16 channels), 40 Kbps at 915 MHz (10 channels), and 20 Kbps at 868 MHz (1 channel). The transmission distance between a set of ZigBee™ devices may range from 10 to 75 m, pending on power output and environmental characteristics. The preceding range may be enhanced with repeaters. In addition, devices, as part of a variety of network topologies, may communicate through network nodes. A ZigBee™ network can support 264 nodes. Such networks may also be linked through network coordinators to support extremely large networks. The present invention embodiments described herein may be supported through such network size capacities.

ZigBee™ utilizes the four basic frame types defined in 802.15.4: data, acknowledgement (ACK), media access control (MAC) command, and beacon.

The data frame, as previously noted, may include up to 104 bytes. The frame is numbered to ensure the tracking of all packets. It also accounts for a frame-check sequence structure to ensure that packets are received without error.

Another key structure for the 802.15.4 standard is the acknowledgement (ACK) frame. It supports providing feedback from the receiver to the sender to confirm whether the packet was received without error. A ZigBee™-compliant device takes advantage of specified “quiet time” between frames to send a short packet immediately after the data-packet transmission.

The MAC command frame supports the mechanism for remote control and configuration of nodes. It may be used to configure individual clients' command frames no matter how large the network.

The beacon frame helps support long battery life by waking up client devices, which listen for their address at differing cycles and go back to sleep if they don't receive it. Beacons are important for mesh and cluster-tree networks for keeping node synchronization without requiring such nodes to consume battery energy by listening for long periods of time. ZigBee™ networks may also comprise non-beacon functionality.

Security and data integrity are key components of ZigBee™ technology. ZigBee™ components such as access control lists, packet freshness timers and 128-bit encryption based on the NIST Certified Advanced Encryption Standard help protect data transmission. It leverages the security model of the IEEE 802.15.4 MAC sublayer which accounts for the preceding through four security services: access control (maintaining a list of trusted devices within the network; data encryption; frame integrity (to protect against modification by parties without cryptographic keys; and sequential freshness to reject data frames that have been replayed.

ZigBee™ devices may, utilizing low power consumption, be battery operated with alkaline batteries. ZigBee™ chip sets are available from Ember, Motorola and Atmel. The ZigBee™ Alliance (zigbee.org), an organization that promotes and supports the ZigBee™ standard, has over ninety members.

ZigBee™ or similar reliable, coded wireless embodiments being comprised in the present invention embodiments described herein not only enhances the living area in which the user resides or works, but may also support additional utilities, such as, for example, security functions. For example, decorative present invention multi-utility enclosures such as, but not limited to, vases, urns, appliances, fixtures, bases, stands, and/or pedestals may comprise a present invention system of integrated modules such as, for example, as previously described herein, a motion detector, a controller processor and timer, an electric air freshener, and/or a ZigBee™ chip set and associated components, or other wireless communications components, whereas upon the opening of an entryway door, the motion detector may activate a motion detector circuit lead that may connect to a controller circuit lead which may activate a preset program (from a table of programs) to turn on an air freshener and/or transmit, for example, (a) ZigBee™ frame(s) to activate a certain light or set of lights. Such controller program may activated a timer circuit lead that may connect to an air freshener circuit lead and such lead may remain in an on state for a preset period of time. Such ZigBee™ transmitting function circuit connection may be shut off by the timer circuit upon the timer processor's receipt of an acknowledgement from the remote light ZigBee™ chip set that such frame was received where such acknowledgement is received by, for example, the pedestal ZigBee™ chip set module and such acknowledgement is relayed to the controller processor. Upon the conclusion of the timer interval associated with the air freshener and/or remote light(s), the controller processor may shut off the timer circuit lead electrical signal powering the air freshener, thus causing such freshener to shut off. Upon the conclusion of the timer interval associated with the transmission connection to the ZigBee™ chip set, such connection may be activated for receiving a signal from the timer.

One of the purposes for such acknowledgement relay and timer circuit disconnect is to support a remote light staying on for a certain period of time, as governed by the timer program, in the event that another family member or pet activates the motion detector where such activation may have caused the transmission of a ZigBee™ packet to activate the light switch where such activation may shut off the light before it is desired to do so. Another means for removing the latter potential problem is accounting for a present invention intelligent light processor that upon receiving a coded wireless command set (such as a ZigBee™ frame) may send such instruction to a processor that governs light operation where upon the receipt of an instruction frame command to turn on the light, compares such command with the state of the light circuit connection by having such circuit connection having a lead and associated components terminating into such processor. In the event that the light circuit connection is in an on-state, the light processor does not change the state of the light circuit. Should the light circuit connection be in an off-state, then such command set would activate the processor to activate the light circuit relay lead to turn on the light.

Another means for activating multiple functions in place of or in conjunction with a motion detector module in the preceding present invention is a personal communicator receiver module. Such module may be in a variety of embodiments such as, but not limited to, a personal wireless car key receiver, a Bluetooth receiver, an infra-red receiver, a RFID scanner, ZigBee receiver, a UWB receiver, a cellular network receiver, and/or a Wi Fi receiver. Such module may receive transmissions from a variety of personal communicator embodiments, in part or in whole, such as, but not limited to, a cell phone, a smart phone, a PDA, a pocket PC, a wireless key, a smart card, a wearable item such as a piece of jewelry, ring, watch or pendant with a wireless data communications means and power means. Such receiver module may be integrated with the other present invention modules of the present invention multi-utility enclosure and may be supported by associated enclosure apertures and framing, powering, communications, circuitry and securing means. Such receiver module may also comprise a data communications means and/or interface to the present invention controller or timer program processor. Upon the receipt of at least one data packet where such packet may identify a certain individual and may originate from, for example, that individual's personal communicator transmitter to the present invention's module receiver to the present invention's controller or timer module processor, such processor may activate a program that comprises the activation of one or more modules associated with the individual's interests, profile or transmitted command(s). Such activated modules may be within the enclosure or remote from the present invention enclosure. Such activations may range from those noted in the preceding paragraphs to room temperature settings, to present invention wall outlet plugs for activating, for example, lamps or electric air fresheners, to kitchen appliance activation to air ionizer settings and activations to networked, automated, movable shelving, closet conveyor, and/or entertainment storage carousel settings, positions and/or rotations. In addition, such personal communicator transmission may also include at least one data packet that may enable the activation of a security or medical or environmental mode program which supports another utility for such modules as described in the next paragraphs. The communications means that supports such multi-utility enclosure and external apparatus utilities may be ZigBee™, UWB, Bluetooth or other wireless data means, as well as wired means such as HomePlug or Ethernet compatible networking, or a combination of the preceding. The preferable wireless embodiment for the preceding invention embodiments is ZigBee™.

The security or alert utility for the present invention multi-utility enclosure configuration described in the preceding paragraph provides additional benefits for a variety of users. Such apparatus which enhances a living or work space area during certain periods of the day or evening as previously described, may also serve a dual purpose as a security or alert enhancement. In a security function mode, the motion detector module, upon the detection of motion, may activate a circuit connection to the controller and timer module processor, where such connection may activate a preset program (from a table of programs), which in this example mode, is a security mode program, where such program executes the controller processor to transmit, for example, a ZigBee™ network chip set address or set of addresses over a data circuit connection from such controller processor module to the ZigBee™ wireless communication module. Such ZigBee™ network address(es) may be associated with ZigBee™ communications receivers that are connected to alarm or alert data circuits or circuits that may activate an alarm, alert or processor function associated with the receipt of such signal.

Another mode embodiment associated with the present invention utilizes a mode command to generate a specific program. This mode command is especially useful for communicating necessary action from a Home Area Network communications device in the event of an emergency, where such mode function may support an optimal (and)/or backup communications means. For example, a present invention wearable alert apparatus, such as, but not limited to, a pendant, may comprise at least one button and communications processor and transmission means where such transmission originating from such pendant may comprise a series of destination addresses and content data packet, where such data packet may contain a medical mode command, where one destination or primary address may be to a main medical device controller, which upon receipt, processes and generates a series of outputs to support a desired response, and another address may be a backup address which may be to, for example, a multi-utility enclosure (such as, but not limited to, the present invention pedestal system described herein) communications module and mode/timer and controller module which may receive, process and generate another series of outputs that may utilize some or alternate devices or instructions to support such backup actions in the event that the primary source or apparatuses associated with such primary source encounter an operational problem. Such mode command application may also apply to an environmental and alert apparatus or system.

The administration and setting of (a) preset program(s) that may be associated with either security, medical, environmental, timer or other mode functions may be administered by four means: 1) a local communication means by a user through a variety of devices, such as, but not limited to, the user interface device previously described and illustrated in FIG. 61; 2) a remote means through a remote server which may receive input from a variety of sources with appropriate security and authentication logins; 3) through a mode/timer program, as described in the narrative; or 4) through an administration/keypad interface.

To further enhance the living area associated with the pedestal descriptions and illustrations, such multi-utility enclosure embodiment modular system configuration may perform additional activations through the controller and timer module and the communications module. Such embodiment of the controller and timer module program may comprise a day mode program that may be administered as a second step or sequence menu prompt, after an “ALARM” prompt, where said “ALARM” prompt accounts for said device as being part of a security system. The purpose for such day mode program is to generate certain activations upon a trigger or timer condition within a certain time range of (a) certain day(s) (and)/or twenty-four hour period. Such mode program may also comprise other parameters as noted further in the narrative. The day mode program may comprise at least one or more time ranges. Such program may apply to timer (and)/or motion detector-based (and)/or communications (such as, but not limited to, personal communicator or user access code or sensor-based transmissions) activations or to activations for any other apparatus, device, system or embodiment with a direct or indirect networked connection that may interact in either or both a transmit (and)/or receive communication with such present invention.

With respect to the previous apartment dwelling application and associated configurations, a motion detector module activation may generate an electrical signal over the circuit connection to the controller and timer circuit which may activate the controller processor to generate a program where such program may reference a security mode condition table or perform a similar function. If the controller module program is not in security mode, the next program sequence may be to reference whether a day mode condition program is activated or perform a similar function. If the day mode program is activated or such day mode condition is in an on-state, the controller program sequence may proceed to the program line or level associated with the activations for such day mode program. Such activation may be to activate, for example, an air freshener for a certain period of time. Such program generation may also be to activate a certain amount, type or location area associated with, for example, lights, appliances, (and)/or other fixtures. Such program generation means may comprise transmitting, for example, ZigBee™ data packets to a variety of addresses or devices with, for example, ZigBee™ transceivers or receivers. Such devices may be other multi-utility enclosures, other present invention embodiments described herein, or, in continuing with this example, ZigBee™ device equipped embodiments.

One of the purposes for repeating some of the preceding present invention embodiments in subsequent passages of this filing where said subsequent passages account for enhanced utilities or applications (such as, for example, security applications), is to account for the versatility of such embodiments when coupled with said added functionality while also complementing their interaction with networked or integrated present invention multi-utility components to enhance user comfort and safety. One example of such complementary use may be in supporting a family with an elderly relative residing in their home who may require certain assistance. An embodiment, such as the present invention pedestal system, may reside in a hallway corner where such hallway may connect to the elderly relative's bedroom or bathroom. During the day, the pedestal system may support functions such as an air freshener as previously described. In the evening, such pedestal system may activate the hall light and activate a speaker and processor in a fixture, such as lamp alert device, where such device, which may comprise a ZigBee™ chip set, upon the receipt and recognition of the transmission from the pedestal system (which may also comprise a ZigBee™ chip set and associated communications components), may play an alert voice message, such as “Activity, gram's hallway”. Another multi-utility enclosure may have a similar motion detector, controller, timer, and communications configuration, in another room, such as a kitchen, whereby, upon the triggering of a motion detector, subsequent module interaction may activate the play of another message in such device, such as, “Activity, kitchen”.

Another embodiment of a multi-utility enclosure/fixture is another lamp embodiment with a high-speed communications capability comprising either Wi Fi components such as, but not limited to a router, access point, repeater, and/or a high gain antenna or power line components such as, but not limited to a HomePlug™ converter and/or terminating point.

Another means for enabling a lamp to serve as a multi-utility high speed communications network hub or access point is through a wired means by utilizing, among a variety of wired mediums, a power line medium such as HomePlug™ In a sample embodiment, the lamp may serve as an access point. A device such as, but not limited to, a digital picture frame, a personal computer, and/or a printer may interface to such lamp embodiment via, for example, an Ethernet connection or termination adapter at the base of such lamp. Such adapter may be connected to a HomePlug™ transceiver that may reside within or outside said lamp.

The preceding invention multi-utility fixtures when comprised of networking means and other like networked devices described herein may also be adapted for connecting with other HAN devices and local area network devices that are and will be utilizing certain protocols compatible with particular deployment areas/configurations and other protocols that are more favorable for other configuration or dwelling area deployments (protocols such as, but not limited to, Bluetooth, UWB, and/or proprietary closed architecture mediums).

The present invention system may also comprise other embodiments to facilitate sensor, communications, as well as exception level alert functions. For example, a stove top and/or oven appliance may have an integrated timer and alert function associated with burner settings (such as, a stove right front burner may have an associated timer and alert activation if it is on a “HIGH” setting for more than 20 minutes). The alert component may comprise a ZigBee chip set and program to communicate to a variety of present invention alert devices such as a component with a ZigBee chip set, processor, program, memory, voice chip, and associated equipment which may announce an appliance warning message that the stove burner has been on for more than 20 minutes. Such component may be part of an environmental sensor and alert device in a variety of embodiments, such as, but not limited to a lighting fixture or lamp alert device system (which also may be in a variety of embodiments), such as a night stand table lamp, with (a) speaker(s) concealed, for example, under its lamp shade (FIGS. 132 and 133) and may comprise other components that may be in or on other portions of the fixture.

Said lamp alert device may comprise the following components:
an input means for alert device programming and voice message recording
a user interface means
a communications means for receiving and/or transmitting wireless (including an antenna and at least one processor) and/or wired command and/or programming and/or instruction sets
an output means for alerting, notifying and/or informing users about an emergency and/or trigger condition and associated action
a processing and memory component with at least one software program, processor and associated memory
a data circuit means for relaying the command and/or instruction set from the communications receiver processor chip to the program processor
a powering means

The input means may be comprised of a wired and/or wireless communications interface or hardwired or plug/receptacle circuit interface to the device processor, and a microphone for connection to the digital recorder. The input means may be located on either the lower, middle or upper portion of the lamp. The preferred embodiment, but not limited to such embodiment, of the input means for the present invention is a plug/receptacle interface, such as, but not limited to, a USB interface.

The preferred plug/receptacle interface may be utilized for directly connecting with a device administration component. One embodiment of said administration component is comprised of a planar user interface that may have a LED or LCD display and input means such as at least one input button and at least one input program sequence or step button, such as the administration component depicted in FIG. 85. This component may be comprised of primarily durable plastic and/or rubber materials with associated screw and adhesive fastening means. The connecting means for this component may be a plug or receptacle component.

The lamp alert device may support a prompt-based user input function of programs and sub-programs for each unique alert function and/or voice message and/or instruction communication associated with (a) certain types and locations of trigger conditions. The present invention may account for, but is not limited to, a Sequence and Command program.

An example of the operation of such program consists of the following for setting trigger parameters and recording voice instructions associated with such trigger parameters. The display of this component may display the time of day, such as 5:30 P above a step or sequence button that may be located on the bottom left side of the display. On the right side of the display, the characters IN may be displayed above the input button that may be located on the bottom right side of the display. Upon pressing the input button, the left side displays, VOICE. Upon pressing the input button again, the left side displays, SMOKE. The depression of the input button associated with SMOKE displays PRGRM 1 (which establishes the first program for broadcasting a voice message associated with receiving a coded transmission from a smoke sensor device transmitter). The next input button depression displays, GRP 1. GRP 1 represents receiving a coded transmission from a set of smoke detectors identified as GRP 1. Even though the coded transmission may account for a character set that identifies the group number and device address of the transmitting sensor device(s), GRP 1 is sufficient as a trigger value to minimize programming time and memory for this embodiment example. Upon the depression of the input button again, the word, MSSG 1, is displayed. The next depression of the input button causes the word, RECORD, to display. Hitting the input button associated with this prompt allows the user to speak into a microphone speaker residing on the lamp while the RECORD prompt on the left side of the display flashes. In this sequence, the right side of the display emits the word, STOP. Upon depressing the input button, the next display sequence is MSSG 1 and PLAY. Upon hitting the input button again, the next display sequence is MSSG 1 and EDIT. Upon hitting the left side button under the word, MSSG 1, the next display frame states MSSG 1 and SAVE. Upon hitting the input button to save the message, the next display sequence is GRP 1 and IN. If the user desires other functions to take place in association with a transmission from (a) smoke detector(s) belonging to GRP 1, the user may depress the input button and scroll through other function sequences (such as, but not limited to, enabling the recording and playing of other messages, flashing sequences of the lamp, changing color patterns of the lamp if the lamp utilizes LED technology and/or transmitting coded messages to other devices in proximity to the lamp) by depressing the associated left sequence or step and right command or input buttons. If the user desires to enable functions associated with other smoke sensors or other sensors, the user may depress the left side button and right side button as appropriate.

The voice record, storage and play components that support the preceding, as well as other present invention voice messaging embodiments described herein, in whole or in part, may comprise a variety of embodiments. For example, one embodiment may comprise the analog to digital recording and conversion, storage, digital signal processor, storage and digital to analog playing and conversion functions on a generally available single chip and/or device, such as those provided by Texas Instruments, Sanyo or Winbond Electronics. Such single chip device may reproduce telephone-quality voice. Such voice messaging embodiment may also comprise alternate chips and associated components for reproducing higher quality voice transmission.

An application for the preceding programming illustration, may be a user programming voice instructions in association with two groups of smoke detectors. In this application, a first group of detectors may reside in the basement and front side of the house. The lamp alert device may reside on a night stand beside the child's bed in his/her second floor bedroom residing in the back of the house. The voice instructions may include addressing the child's name, alerting that there's a fire, and instructing to open the window, and use a nearby escape ladder. The window and escape ladder may also have alert audio and/or visual alert means such as, but not limited to those associated with device, with addressable receiver chip sets or DIP switches, a circuit and a power source for triggering such alert means. These alert devices may be triggered by a wireless code set such as, but not limited to, a ZigBee frame that may be transmitted from other ZigBee transceivers and/or transmitter chip sets and/or repeaters residing on other devices such as, but not limited to, a lamp alert device or other sensor transmitters, such as but not limited to, those associated with (a) smoke detector(s) or carbon monoxide detector or an integrated unit comprising a smoke detector and a carbon monoxide detector adapted for the present invention system or a main device. A second group of, for example, present invention system smoke detectors may reside below the child's room or near the exit window. The voice message associated with this second group may alert and instruct the child to utilize an alternative exit.

The applications and utility of this lamp alert device, other present invention distributed voice messaging components that may be embodied in such device as well as other embodiments, and other devices that may be used in conjunction with the alert means of device and other invention embodiments are broad in context with the present invention system.

With respect to referring and concluding the narrative associated with the lamp device, the communications means associated with lamp alert device may be wireless and/or wired. The wireless means, which is the preferred embodiment of this present invention component, may utilize open protocols such as, but not limited to, ZigBee™, Bluetooth, and/or UWB or be adapted for closed proprietary protocols. The wired means may utilize power line-based means such as, but not limited to HomePlug™ or other wire-based communications mediums.

The preferred embodiment of this present invention component is utilizing a ZigBee based wireless protocol, because of its operating characteristics with other detectors, sensors, and transmitters or communicators where such characteristic are, but not limited to, utilizing low power, low cost, information transfer and acknowledged transmission receipt.

The economies gained from utilizing a ZigBee protocol for said lamp alert device may also support another present invention embodiment of a ZigBee router where such router may receive and process ZigBee packets that may control the following: lamp lighting operations, from timer activations to dimmer functions; various voice messages based on the type, location and quantity of sensor transmissions; and ZigBee full function device functions for serving as a mesh network hub for other ZigBee networked devices.

The power means for lamp alert device may be sourced through one standard AC outlet. Device components may also utilize battery power or backup (such as the ZigBee chip set and certain alert components) and/or DC components with the appropriate converter, resistor and capacitor elements.

Said lamp alert device may, again be in a variety of embodiments as an integrated system or may comprise integrated modular adjuncts which may utilize the mounting means depicted in FIGS. 132 and 133, among other forms of mountings (including standalone). These figures account for utilizing the present invention antenna and/or power apertures in the bulb enclosure, harp and finial support component and other present invention lamp infrastructure components.

The sensors, processors, memory, circuitry, electrical components, housings, fittings and bonding and securing means for the components described herein are comprised of conventional materials, designs and configurations, except for the designs associated with the present invention embodiments described herein.

It is understood, as illustrated in this filing, that any of the embodiments described herein may be combined with any other embodiment (and)/or feature presented herein. In addition, one skilled in the art understands that many of the innovations may comprise a variety, or combination, of separate components as well as customized integrated circuitry and/or software/firmware and/or processor and memory embodiments as alternative configurations and programs for providing the present invention utilities described herein. For example, a memory means for digitized voice commands may be stored on a variety of storage mediums, such as, but not limited to, random access memory chips, read only memory chips, flash memory apparatuses, optical storage media, magnetic storage media, or magneto-optical storage media.

It is also understood that the network protocols and means described herein may evolve or be modified where such modification may support other like protocol standards that may also be adapted with the present invention system and be construed as present invention embodiments when utilized, integrated or comprised with or in such present invention apparatuses, devices and/or systems. Protocols such as, but not limited to, ZigBee, Wi Fi, Bluetooth, UWB, HomePlug™ and Ethernet compatible network protocols, and respective offshoots of such protocols apply to the preceding statement related to such present invention embodiments. In addition, the Wi Fi standards associated with or supporting at least one or more of the present invention embodiments described herein are, but not limited to, the following: 802.11g; 802.11b; 802.11a; or 802.11n. Communications portions of the present invention system may also comprise Wide Area Network communications interfaces to interact with Wi Max, broadband, DSL, high-speed cable, (and)/or dial-up networks.

The following parts lists refer to the Figures shown below and as discussed above in this Detailed Description:

FIG. 1 is an illustration of one embodiment of a present invention table lamp with interchangeable modular components and FIGS. 2, 3, 4 and 5 illustrate another embodiment of a present invention table lamp with a ring component, in various stages of assembly:

### FIG. 1

1—present invention lamp
3—base
5—lower portion
7—upper portion
9—lamp shade
11—harp brace
13—threaded harp brace/finial
15—bulb
17—wire
19—plug
21—ring component

### FIG. 2

20—present invention lamp
31—base
33—base leg connector
35—base leg connector
37—base leg connector
39—central shaft component
41—electric/electronic port
43—electric/electronic port
45—electric/electronic port
47—interlocking component (spring loaded)
51—lower component
53—lower component decoration
61—lower component shaft ring
63—ring leg component
65—ring leg component
67—ring leg component
71—upper component
73—interlocking component receiving orifice
81—lamp shade
83—lamp shade decoration
91—finial

### FIG. 3

31—base
47—interlocking component (spring loaded)
51—lower component
53—lower component decoration
61—lower component shaft ring
63—ring leg connector
65—ring leg connector
67—ring leg connector
71—upper component
73—interlocking component receiving orifice
81—lamp shade
83—lamp shade decoration
91—finial

### FIG. 4

31—base
47—interlocking component (spring loaded)
51—lower component
53—lower component decoration
61—lower component shaft ring
63—ring leg connector
65—ring leg connector
67—ring leg connector
71—upper component
81—lamp shade
83—lamp shade decoration
91—finial

### FIG. 5

20—present invention lamp
31—base
51—lower component
53—lower component decoration
61—lower component shaft ring
71—upper component
81—lamp shade
83—lamp shade decoration
91—finial

FIGS. 6, 7, 8 and 9 illustrate another embodiment of a present invention table lamp without a ring component, in various stages of assembly:

### FIG. 6

130—present invention lamp
131—base
133—base leg connector
135—base leg connector
137—base leg connector
139—support member
147—interlocking component (spring loaded)
151—lower component
153—lower component design
169—upper component collar
170—interlocking component funnel
171—upper component
173—interlocking component receiving orifice
175—harp brace
177—threaded finial shaft
181—shade
191—threaded harp brace/finial

### FIG. 7

130—present invention lamp
131—base
139—support member
147—interlocking component (spring loaded)
151—lower component
153—lower component design
171—upper component
173—interlocking component receiving orifice
175—harp brace
177—threaded finial shaft
181—shade
191—threaded harp brace/finial

### FIG. 8

130—present invention lamp
131—base
147—interlocking component (spring loaded)
151—lower component
153—lower component design
171—upper component
175—harp brace
177—threaded finial shaft
181—shade
191—threaded harp brace/finial

### FIG. 9

130—present invention lamp
131—base
139—support member
151—lower component
153—lower component design
171—upper component
181—shade
191—threaded harp brace/finial

FIGS. 10, 11, 12 and 13 show another present invention table lamp in various stages of assembly:

### FIG. 10

220—present invention lamp
229—lower component male threaded bottom
231—base
233—base female threading
235—base wire port
241—wire
243—plug
251—lower component
253—lower component decoration
271—upper component
273—upper component threaded bottom
275—upper component lamp
281—lamp shade
283—lamp shade decoration
291—threaded harp brace/finial

### FIG. 11

220—present invention lamp
231—base
233—base female threading
235—base wire port
251—lower component
253—lower component decoration
271—upper component
275—upper component lamp
281—lamp shade
283—lamp shade decoration
291—threaded harp brace/finial

### FIG. 12

220—present invention lamp
231—base
233—base female threading
235—base wire port
251—lower component
253—lower component decoration
275—upper component lamp
281—lamp shade
283—lamp shade decoration
291—threaded harp brace/finial

### FIG. 13

220—present invention lamp
231—base
235—base wire port
251—lower component
253—lower component decoration
275—upper component lamp
281—lamp shade
283—lamp shade decoration
291—threaded harp brace/finial
   FIG. 14 shows a side view of a base component that may be included with present invention lamps, pedestals, decorative containers and other present invention devices:

### FIG. 14

300—modular, interchangeable base
301—base frame
303—base wire port
305—wire
307—plug
309—frame top
311—shaft-receiving cylinder
313—connection receiver
315—cylinder at top opening
317—base leg connector
318—electrical/electronics housing(s) connector
319—base leg connector

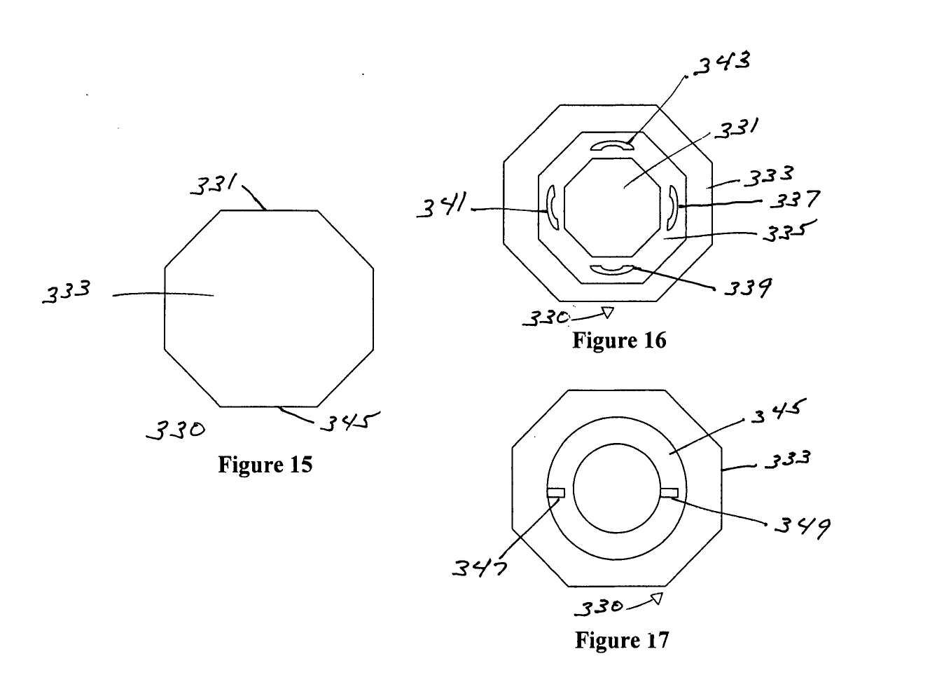

FIGS. 15, 16 and 17 show a side view, a top view and a bottom view, respectively, of one preferred lower component of present invention lamps, pedestals, decorative containers and other present invention devices for modular assembly therewith:

### FIG. 15

330—lower component for any present invention device
331—open top
333—side
345—bottom

### FIG. 16

330—lower component for any present invention device
331—open top
333—side
335—top rim
337—lower component top leg connector-receiving orifice
339—lower component top leg connector-receiving orifice
341—lower component top leg connector-receiving orifice
343—lower component top leg connector-receiving orifice

### FIG. 17

330—lower component for any present invention device
333—side
345—bottom rim
347—bottom rim leg-receiving slot for base attachment
349—bottom rim leg-receiving slot for base attachment

FIG. 18 shows a front view of one embodiment of a present invention central shaft configuration with electronic power supply and/or electronic component capabilities for modular inclusion of present invention lamps, pedestals, decorative containers and other present invention devices:

### FIG. 18

401—central shaft component
403—docking mechanism opening
405—interconnecting component (spring loaded) for base stand
407—electric/electronic component port
409—electric/electronic component port
411—electric/electronic component port
413—electric/electronic component port
415—electrical/electronic component guide
417—electrical/electronic component guide

FIG. 19 shows a front view of a present invention electrical/electronics housing component for said central shaft configuration with electronic power supply and/or electronic component capabilities for modular inclusion of present invention lamps, pedestals, decorative containers and other present invention devices:

### FIG. 19

421—central electrical/electronics assembly and housing component (basic model)
423—1G housing component designation
425—top shaft component connector
427—schematic connection for electrical/electronic component
429—base component connector

FIG. 20 shows a front view of another embodiment of a present invention top shaft configuration with electronic power supply and/or electronic component capabilities for modular inclusion of present invention lamps and other present invention devices:

### FIG. 20

431—top shaft electrical/electronics housing component
437—electrical/electronics assembly enclosure and guide
439—manual switch mechanism
441—harp receptacle
445—electrical/electronics housing component guide
447—lower portion shaft interconnecting component (spring loaded)
449—shaft insert

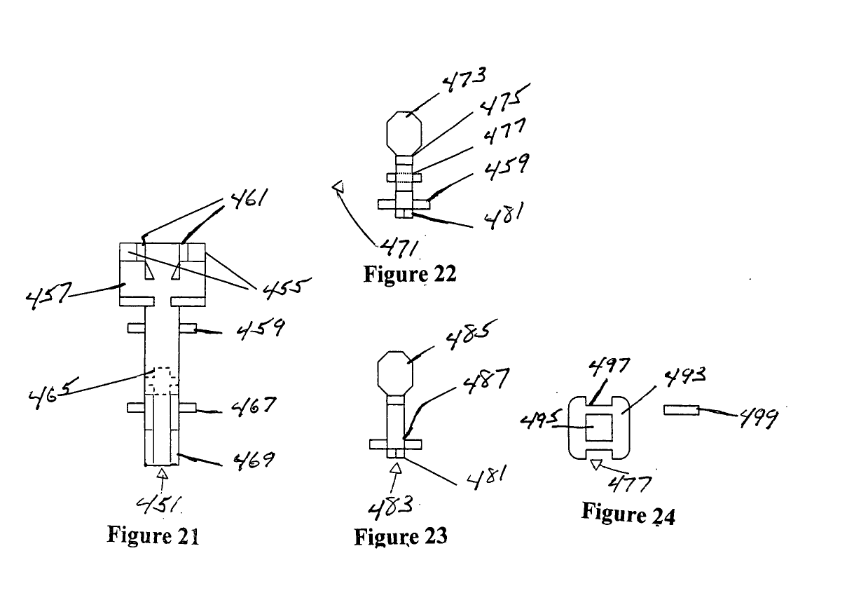

FIG. 21 shows a front view of another embodiment of a present invention top shaft configuration with electronic power supply and/or electronic component capabilities for modular inclusion of present invention lamps and other present invention devices:

### FIG. 21

451—top shaft housing component with antenna/auxiliary component receptacle
455—antenna receptacle
457—electrical/electronics assembly enclosure and guide
459—manual switch mechanism
461—harp receptacle
465—electrical/electronics housing component guide
467—lower portion shaft interconnecting component (spring loaded)
469—shaft insert

FIGS. 22, 23 and 24 show electrical/electronic assembly components for a present invention device with lighting:

### FIG. 22

459—manual switch mechanism
471—electrical/electronic assembly and enclosure frame for one bulb
473—light bulb and/or electrical/electronics component
475—light bulb socket and enclosure
477—socket and enclosure frame
481—top cross-support/attachment means/modular wiring connector

### FIG. 23

481—top cross-support/attachment means/modular wiring connector
483—electrical/electronic assembly for one bulb
485—light bulb and/or electrical/electronic component
487—shaft and manual switching mechanism

### FIG. 24

477—socket and enclosure frame (top and side view)
493—socket and enclosure frame (top view)
495—socket and enclosure frame orifice
497—socket and enclosure frame recess fitting
499—socket and enclosure frame (side view)

FIGS. 25 and 26 show a present invention modular lamp with interchangeable parts and a present invention modular vase enclosure with interchangeable parts, having the same lower component, respectively:

### FIG. 25

510—present invention lamp
511—lower component
513—lower component integrated ring
515—lower component integrated base
517—upper component
519—lower component central shaft
521—lamp shade
523—finial
525—wire
527—plug

### FIG. 26

511—lower component
514—lower component vase enclosure ring with wider inner orifice
515—lower component integrated base
520—flowers

FIGS. 27, 28, 29 and 30 show another present invention modular lamp with interchangeable parts and a present invention modular urn with interchangeable parts, having the same lower component, respectively:

### FIG. 27

530—present invention lamp
531—lower component with integrated unistructural base
533—ring
535—upper component
537—lamp shade
539—finial
541—wire
543—plug

### FIG. 28

531—lower component
538—present invention lamp
541—ring with motion sensor
543—insertable base
545—electronic modular connected shaft
547—lamp shade
549—finial
551—ring with electronics
553—transmitter/receiver

### FIG. 29

531—lower component
542—present invention container
551—ring with electronics
553—transmitter/receiver

### FIG. 30

531—lower component
542—present invention container
551—ring with electronics
553—transmitter/receiver

FIGS. 31, 32, 33, 34, 35, 36 and 37 show various stages of a present invention modular table lamp and a modular table flower pot enclosure system with interchangeable components:

### FIG. 31

560—present invention lamp
561—lower component
563—lower component decoration
567—base
569—ring
573—upper component
575—lamp shade
577—lamp shade decoration
579—threaded harp brace/finial

### FIG. 32

569—ring
571—ring top
573—ring orifice for receiving lamp upper component

### FIG. 33

561—lower component
563—lower component decoration
570—conventional flower pot and dish (inner view)
580—present invention flower pot enclosure and component system
581—decorative base/dish
583—decorative flower pot enclosure ring

### FIG. 34

561—lower component
563—lower component decoration
581—decorative base/dish
584—decorative flower pot enclosure ring
585—decorative ring top
587—decorative ring top leg connector
588—decorative ring inner portion
589—decorative ring top leg connector
590—present invention flower pot enclosure and component system

### FIG. 35

584—decorative flower pot enclosure ring
585—decorative ring top
591—orifice

### FIG. 36

570—conventional flower pot and dish
582—flowers

### FIG. 37

582—flowers
584—decorative flower pot enclosure ring
590—present invention flower pot enclosure and component system

FIGS. 38, 39 and 40 show a top view of a present invention modular table lamp in various stages of assembly where said assembly means may apply to a present invention lamp, pedestal, decorative container or other present invention device:

### FIG. 38

670—present invention modular base and shaft (top view)
671—base plate
673—base plate block
675—shaft
677—lamp lower portion with side opening and side and top portion covers
679—yoke or shaft cradle
681—slide slot
683—top portion cover/slide block
685—side portion cover

### FIG. 39

671—base plate
673—base plate block
675—shaft
677—lamp lower portion with side opening and side and top portion covers
679—yoke or shaft cradle
683—top portion cover/slide block
685—side portion cover

### FIG. 40

671—base plate
675—shaft
677—lamp lower portion with side opening and side and top portion covers
679—yoke or shaft cradle
683—top portion cover/slide block
685—side portion cover

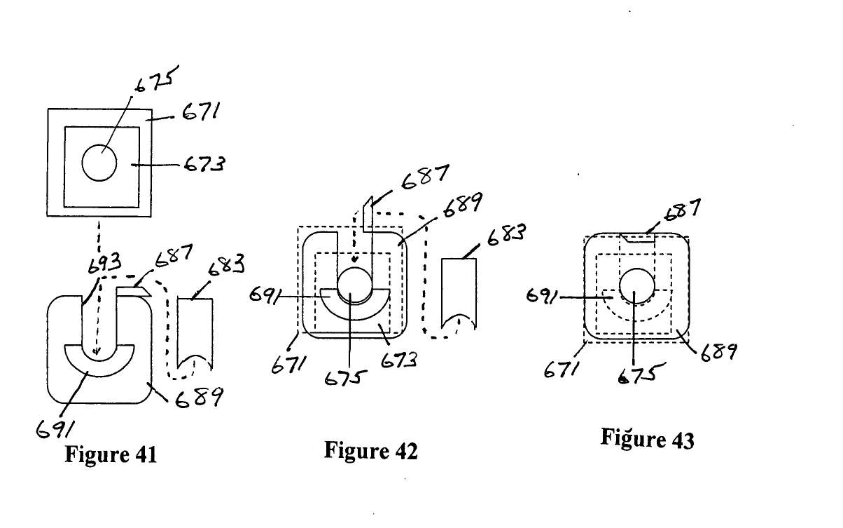

FIGS. 41, 42 and 43 show another present invention modular table lamp in various stages of assembly where said assembly means may apply to a present invention lamp, pedestal, decorative container or other present invention device:

### FIG. 41

671—base plate
673—base plate block
675—shaft
683—top portion cover/slide block
687—side portion door
689—lamp lower portion with side door/opening and top portion cover
691—yoke or shaft cradle
693—slide slot

### FIG. 42

671—base plate
673—base plate block
675—shaft
683—top portion cover/slide block
687—side portion door
689—lamp lower portion with side door/opening and top portion cover
691—yoke or shaft cradle

### FIG. 43

671—base plate
675—shaft
687—side portion door
689—lamp lower portion with side door/opening and top portion cover
691—yoke or shaft cradle

FIGS. 44, 45, 46, 47, 48 and 49 illustrate a present invention modular standing floor lamp with interchangeable components in various stages of assembly being converted to a floor lamp with a table and magazine rack:

### FIG. 44

700—present invention floor lamp
701—upper component section
703—base
705—decorative lighting enclosure
713—lamp fixture component
715—upper component section
717—upper component section
719—upper component section
721—lower component
723—modular interconnector

### FIG. 45

701—upper component section
703—base
707—support
709—light bulb
713—lamp fixture component
715—upper component section
717—upper component section
719—upper component section
721—lower component
723—modular interconnector

### FIG. 46

703—base
707—support
711—internal shaft

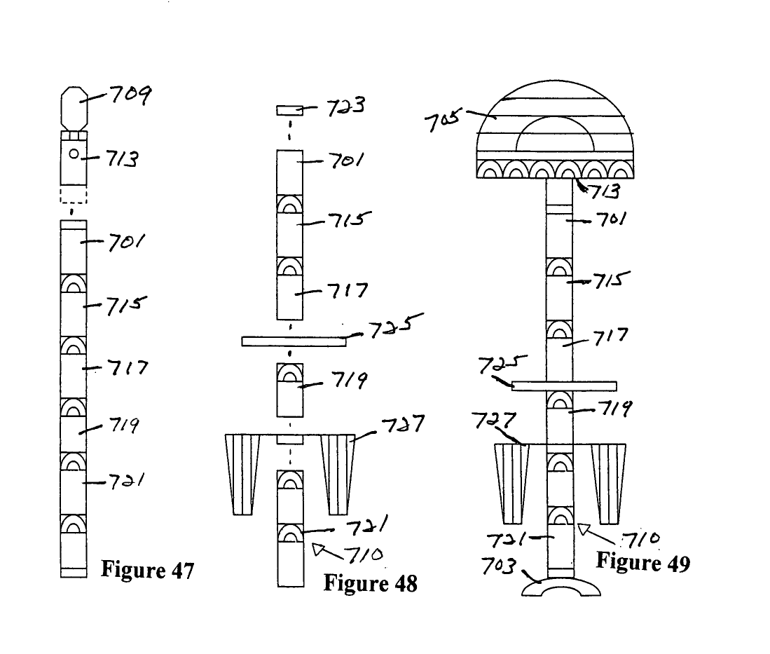

### FIG. 47

701—upper component section
709—light bulb
713—lamp fixture component
715—upper component section
717—upper component section
719—upper component section
721—lower component

### FIG. 48

701—upper component section
710—present invention floor lamp with table and magazine rack components (partial)
715—upper component section
717—upper component section
719—upper component section
721—lower component
723—modular interconnector
725—modular table top
727—modular magazine racks

### FIG. 49

701—upper component section
703—base
705—decorative lighting enclosure
710—present invention floor lamp with table and magazine rack components (partial)
713—lamp fixture component
715—upper component section
719—upper component section
721—lower component
725—modular table top
727—modular magazine racks

FIG. 50 shows one embodiment of a present invention hanging modular chandelier with interchangeable components:

### FIG. 50

730—present invention chandelier lamp
731—modular upper component
733—modular upper component
735—modular base
737—modular light fixture
739—modular light fixture
741—modular light fixture
743—support chain/wire
745—ceiling attachment means

FIGS. 51 and 52 illustrate a present invention ceiling lamp with interchangeable modular components:

### FIG. 51

750—present invention ceiling lamp
751—upper component
753—upper component decoration
755—lower component
757—base
759—base component decoration
761—lower component top male threads
763—lower component bottom male threads

### FIG. 52

750—present invention ceiling lamp
751—upper component
753—upper component decoration
755—lower component
757—base

FIGS. 53 and 54 show a present invention modular wall lamp with interchangeable parts:

### FIG. 53

760—present invention wall lamp
771—upper component
773—lower component

### FIG. 54

760—present invention wall lamp
771—upper component
773—lower component
775—light fixture support
777—light fixture support
779—light fixture support
781—upper component leg connector
783—upper component leg connector

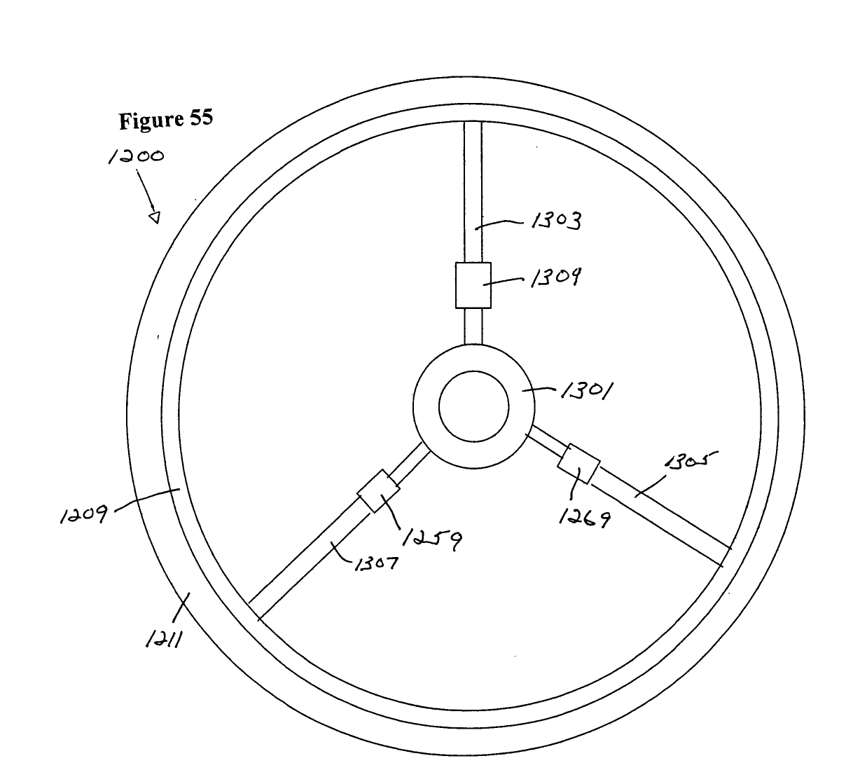

FIG. 55 shows a top view of a collapsible one-piece lamp shade and upper harp component for modular interchangeable connection with present invention lamps:

### FIG. 55

1200—present invention collapsible one-piece lamp shade and upper harp component
1209—top brace
1211—flexible material
1259—pivotal harp brace portion
1269—pivotal harp brace portion
1301—hub
1303—top brace spoke
1305—top brace spoke
1307—top brace spoke
1309—pivotal harp brace portion

FIGS. 56, 57 and 58 illustrate various aspects of a present invention multi-utility lamp fixture with multi-utility electrical and electronic assembly and housing components and FIG. 59 illustrates the legend for these figures:

### FIG. 56

810—present invention multi-utility lamp with electrical/electronic assemblies, housing components and base (top view)
811—base
813—motion detector/electrical/electronic component
815—connector receiving orifice for lamp lower portion
817—lamp shaft opening
819—top portion of electrical/electronics housing component (HC3 or 3R designation)
821—top portion of electrical/electronics housing component (HC4 or 4Y designation)
823—top portion of electrical/electronics housing component (HC 1 or 1G designation)
825—top portion of electrical/electronics housing component (HC2 or 2B designation)
831—housing component designation guides
833—power panel electrical ports and status indicators

### FIG. 57

823—top portion of electrical/electronics housing component (HC1 or 1G designation)
827—housing component 1 (HC1 or 1G designation) side view

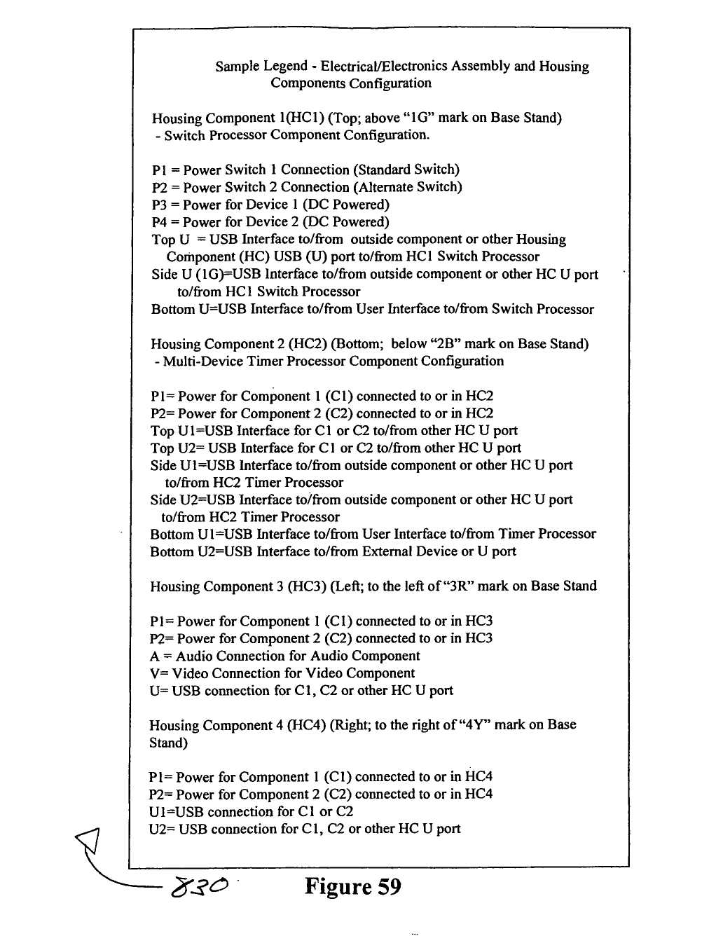

### FIG. 58

825—top portion of electrical/electronics housing component (HC2 or 2B designation)
829—housing component 2 (HC 2 or 2B designation) side view

### FIG. 59

830—legend for FIGS. 80 (partial), 81 and 82

FIGS. 60, 62, 62 and 63 show some alternative and some identical components with the support illustrations of FIGS. 57 and 58 above:

### FIG. 60

820—multi-utility multifunctional modular housing component set (side view)
827—housing component 1 (HC 1 or 1G designation) side view
829—housing component 2 (HC 2 or 2B designation) side view
837—housing component 3 (HC 3 or 3R designation) side view
839—housing component 4 (HC 4 or 4Y designation) side view

### FIG. 61

810—present invention multi-utility lamp with electrical/electronic assemblies, housing components and base (top view)
811—base
813—motion detector/electrical/electronic component
815—connector receiving orifice for lamp lower portion
817—lamp shaft opening
819—top portion of electrical/electronics housing component (HC3 or 3R designation)
821—top portion of electrical/electronics housing component (HC4 or 4Y designation)
823—top portion of electrical/electronics housing component (HC1 or 1G designation)
825—top portion of electrical/electronics housing component (HC2 or 2B designation)
831—housing component designation guides
843—modular interchangeable electrical/electronic control panel

### FIG. 62

850—central shaft component
851—docking mechanism opening
855—electrical/electronic component guide
857—electrical/electronic component port for housing component 1G
859—electrical/electronic component port for housing component 2B
861—electrical/electronic component port for housing component 3R
863—electrical/electronic component port for housing component 4Y
865—interconnecting component (spring loaded) for base stand

### FIG. 63

833—power panel electrical ports and status indicators
871—AC power cord
873—AC plug interface for power panel port
875—DC power cord
877—DC plug interface for power panel port
879—plug
881—converter
883—wire

FIGS. 64, 65 and 66 show various present invention embodiments of motion sensor and wireless communication modules having interchangeable components that may be included with present invention lamps, pedestals, decorative containers and other present invention devices:

### FIG. 64

900—present invention multi-utility, multi-adaptable enclosure and modular components in urn embodiment with top portion motion detector
901—inner electrical connector and module brace system
903—motion detector
905—antenna
907—transmitter or transceiver
909—wire
910—door cut out
911—plug

### FIG. 65

910—door cut out
915—decorative urn ring
917—motion detector module in present invention modular pedestal system
920—decorative urn with integral lower portion and base
921—present invention multi-utility enclosure and modular components in pedestal system embodiment
923—transmitter or transceiver module in present invention modular pedestal system
927—table cutout
931—wire
933—plug

### FIG. 66

910—door cut out
919—wire
925—line of sight component
929—plug
935—line of sight component
940—present invention multi-utility, multi-adaptable enclosure and modular components in urn embodiment with top portion line of sight detector
950—present invention multi-utility, multi-adaptable enclosure and modular components in urn embodiment with top portion line of sight detector

FIGS. 67 and 68 illustrate a present invention vase enclosure system with a vase enclosure ring and motion detector, timer, aromatic dispenser and oil cartridge modules:

### FIG. 67

941—lower component
943—vase enclosure ring insert for air freshener module
945—motion detector
947—flowers
949—desk cutout
959—aroma dispenser cartridge and wick
960—present invention flower vase enclosure and component system

### FIG. 68

941—lower component
943—vase enclosure ring insert for air freshener module
945—motion detector
947—flowers
951—wire
953—plug
955—internal vase
957—timer
959—aroma dispenser cartridge and wick
960—present invention flower vase enclosure and component system

FIGS. 69, 70, 71 and 72 illustrate present invention vase enclosure components and infrastructure that support motion detector, timer, aromatic dispenser, and oil cartridge modules:

### FIG. 69

943—vase enclosure ring insert for air freshener module
961—module vent and aroma emission orifice
963—floral orifice

### FIG. 70

951—wire
953—plug
957—module electrical brace portion
975—module electrical/electronics brace portion
979—module panel with connectors and on/off power settings
980—module electrical/electronic brace

### FIG. 71

943—vase enclosure ring insert for air freshener module
961—module vent and aroma emission orifice
973—frame insert
985—ring insert leg connector
987—ring insert leg connector

### FIG. 72

943—vase enclosure ring insert for air freshener module
945—motion detector
951—wire
953—plug
957—timer module
959—aroma dispenser cartridge and module
973—frame insert
975—module electrical/electronics brace portion
978—motion detector module
985—ring insert leg connector
987—ring insert leg connector

FIGS. 73, 74, 75, 76, 77 and 78 illustrate various present invention interchangeable modular component pedestal systems:

### FIG. 73

1000—present invention pedestal system
1001—present invention lower component in vase enclosure and ring embodiment
1003—motion detector module
1005—wire
1007—plug
1010—flowers
1011—aroma emission orifice
1013—air freshener module
1015—ring insert

### FIG. 74

1000—present invention pedestal system
1003—motion detector module
1004—sensor unit
1005—wire
1006—electrical housing with back and center frame
1007—plug
1009—aroma dispenser cartridge and wick
1011—aroma emission orifice
1013—air freshener module
1025—communications module
1027—antenna
1031—timer module
1037—timer input and output means
1049—module release button

### FIG. 75

1000—present invention pedestal system
1003—motion detector module
1005—wire
1007—plug
1011—aroma emission orifice
1013—air freshener module

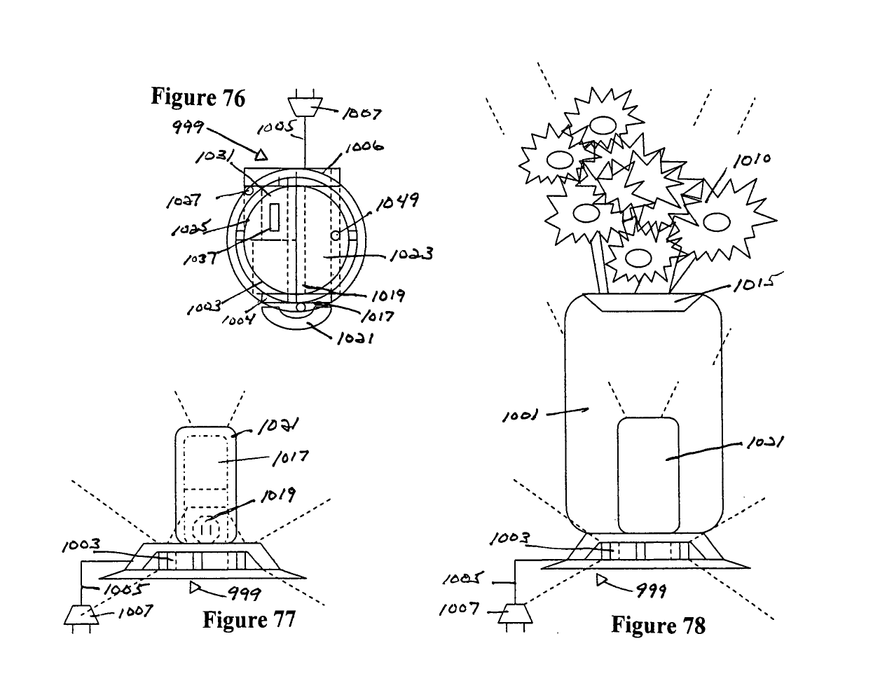

### FIG. 76

999—present invention pedestal system with integrated plug receptacle and external air freshener
1003—motion detector module
1004—sensor unit
1005—wire
1006—electrical housing with back and center frame
1007—plug
1017—plug in air freshener
1019—integrated plug receptacle
1021—modular decorative air freshener housing
1023—electrical connector module
1025—communications module
1027—antenna
1031—timer module
1037—timer input and output means
1049—module release button

### FIG. 77

999—present invention pedestal system with integrated plug receptacle and external air freshener
1003—motion detector module
1005—wire
1007—plug
1017—plug in air freshener
1019—integrated plug receptacle
1021—modular decorative air freshener housing

### FIG. 78

999—present invention pedestal system with integrated plug receptacle and external air freshener
1001—present invention lower component in vase enclosure and ring embodiment
1003—motion detector module
1005—wire
1007—plug
1010—flowers
1015—ring insert
1021—modular decorative air freshener housing

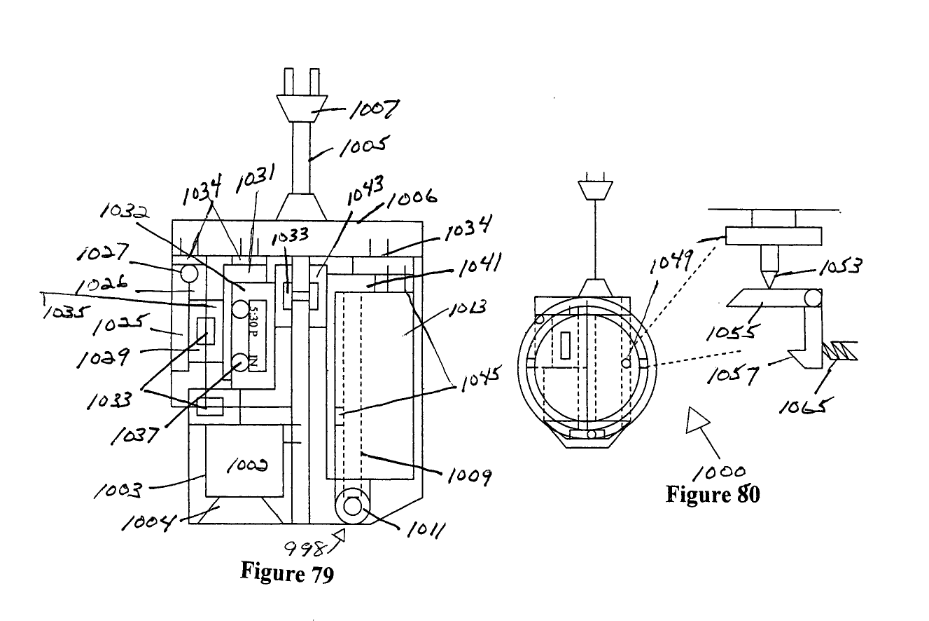

FIGS. 79, 80, 81, 82, 83, 84 and 85 show various elements of a present invention pedestal system module and infrastructure that may also apply to present invention lamps, decorative containers and other present invention devices:

### FIG. 79

998—sample present invention module configuration for present invention pedestal module system
1002—motion detector module main circuitry
1003—motion detector module
1004—sensor unit
1005—wire
1006—electrical housing with back and center frame
1007—plug
1009—aroma dispenser cartridge and wick
1011—aroma emission orifice
1013—air freshener module
1025—communications module
1026—communications module main circuitry
1027—antenna
1029—RF setting and transceiver component
1031—timer module
1032—control/mode program and circuitry
1033—module interface
1034—electrical housing interface
1035—circuitry settings
1037—timer input and output means
1041—air freshener module main circuitry
1043—air freshener module circuitry settings
1045—air freshener module heating unit and transfer plates

### FIG. 80

1000—present invention pedestal system highlighting module release button
1049—module release button
1053—button bottom tip
1055—pivot arm
1057—module release latch
1065—spring

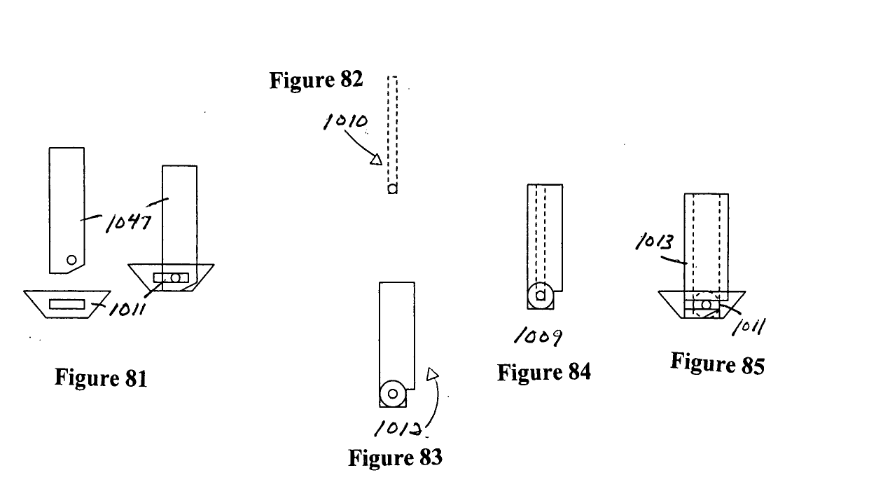

### FIG. 81

1011—aroma emission orifice
1047—housing for air freshener module heating unit and transfer plates

### FIG. 82

1010—wick

### FIG. 83

1012—aroma dispenser cartridge

### FIG. 84

1009—aroma dispenser cartridge and wick

### FIG. 85

1011—aroma dispenser orifice
1013—air freshener module

FIGS. 86, 87 and 88 illustrate various embodiments of a present invention urn with interchangeable modular components:

### FIG. 86

1070—present invention in an urn embodiment
1071—lower component 1073—motion detector
1075—antenna
1077—aromatic emission orifice and module vent
1078—decorative patterned orifice for ambient light sensor and night light module
1079—ring component

### FIG. 87

1070—present invention in an urn embodiment
1071—lower component
1073—motion detector
1075—antenna
1077—aromatic emission orifice and module vent
1078—decorative patterned orifice for ambient light sensor and night light module
1079—ring component
1081—decorative wire and brace duct
1083—outlet
1085—outlet
1087—outlet
1089—power indicator and circuit reset
1091—power indicator and circuit reset
1093—power indicator and circuit reset

### FIG. 88

1070—present invention in an urn embodiment
1071—lower component
1073—motion detector
1075—antenna
1077—aromatic emission orifice and module vent
1078—decorative patterned orifice for ambient light sensor and night light module
1079—ring component
1080—supplemental multi-utility module and module enclosure
1081—decorative wire and brace duct
1093—counter top
1095—wire
1097—plug
1099—fastener for brace and counter mount
1100—brace and counter mount
1101—fastener for counter mount
1105—brace

FIGS. 89, 90 and 91 show various stages of the present invention modular collapsible lamp with interchangeable components:

### FIG. 89

1200—present invention collapsible lamp shade
1201—bottom brace
1202—lower pivot and enclosure
1203—lower rib
1205—upper pivot
1207—upper rib
1208—rib receiving portion
1209—top brace
1211—flexible material
1252—lower pivot and enclosure
1253—lower rib
1255—upper pivot
1257—upper rib
1258—rib receiving portion
1259—pivotable harp brace portion
1262—lower pivot and enclosure
1263—lower rib
1265—upper pivot
1267—upper rib
1268—rib receiving portion
1269—pivotable harp brace portion

### FIG. 90

1213—main lighting component shaft, electrical/electronics enclosure and system securing component
1215—main lighting component upper shaft portion and electrical enclosure with lower component receiving frame
1216—harp receiving portion
1217—harp and finial brace
1218—harp receiving portion
1219—finial
1220—present invention modular collapsible lamp with interchangeable components
1221—base
1223—wire
1225—plug
1227—threaded portion to secure into upper shaft portion (1215)
1229—threaded portion to secure base
1231—lower component

### FIG. 91

1200—present invention collapsible lamp shade
1211—flexible material
1215—upper shaft portion and electrical enclosure with lower component receiving frame
1219—finial
1221—base
1223—wire
1225—plug
1231—lower component

FIGS. 92, 93, 94, 95 and 96 show structural details of the present invention modular collapsible lamp with interchangeable components:

### FIG. 92

1199—present invention collapsible lamp shade support structure without covering material
1201—bottom brace
1202—lower pivot and enclosure
1203—lower rib
1205—upper pivot
1207—upper rib
1208—rib receiving portion
1209—top brace
1252—lower pivot and enclosure
1253—lower rib
1255—upper pivot
1257—upper rib
1258—rib receiving portion
1259—pivotable harp brace portion
1262—lower pivot and enclosure
1263—lower rib
1265—upper pivot
1267—upper rib
1268—rib receiving portion
1269—pivotable harp brace portion

### FIG. 93

1218—present invention collapsible lamp lower portion structure without covering material
1227—threaded portion to secure into upper shaft portion (1215)
1231—bottom brace
1232—lower pivot and enclosure
1233—lower rib
1235—upper pivot
1237—upper rib
1238—rib receiving portion
1239—top brace
12—lower pivot and enclosure
13—lower rib
15—upper pivot
17—upper rib
18—rib receiving portion
1272—lower pivot and enclosure
1273—lower rib
1275—upper pivot
1277—upper rib
1278—rib receiving portion

### FIG. 94

1200—present invention collapsible lamp shade
1201—bottom brace
1202—lower pivot and enclosure
1203—lower rib
1205—upper pivot
1207—upper rib
1208—rib receiving portion
1209—top brace
1211—flexible material
1217—pop-in harp and finial brace
1219—finial
1252—lower pivot and enclosure
1253—lower rib
1255—upper pivot
1257—upper rib
1258—rib receiving portion
1259—pivotable harp brace portion
1262—lower pivot and enclosure
1263—lower rib
1265—upper pivot
1267—upper rib
1268—rib receiving portion
1269—pivotable harp brace portion

### FIG. 95

1227—threaded portion to secure into upper shaft portion (1215)
10—present invention lamp lower enclosure in a collapsed position
11—flexible material

### FIG. 96

1230—present invention lamp lower enclosure in a collapsed position cutout with inner support components
1231—bottom brace
1232—lower pivot and enclosure
1233—lower rib
1235—upper pivot
1237—upper rib
11—flexible material
12—lower pivot and enclosure
13—lower rib
15—upper pivot
17—upper rib
1272—lower pivot and enclosure
1273—lower rib
1275—upper pivot
1277—upper rib

FIGS. 97A, 97B and 97C show a schematic view of a present invention pedestal 3001. As shown in box 3001, the pedestal adapted to receive a nesting item atop it and adapted to perform at least one additional function in addition to pedestal. The shape of the pedestal is selected from the group consisting of cubic pedestals, square top footprint pedestals, vertically elongated pedestals and horizontally elongated pedestals.

The pedestal 3001 includes a pedestal component 3003, at least one electrical system component 3009 and is one of a plurality of pedestals 3005. With respect to box 3003, the pedestal component has an enclosed structure with a bottom adapted to rest upon a horizontal surface, and has an electrical system component support within the enclosed structure, the pedestal component having a top with one of a male and a female nesting member adapted to receive the other of a male and female nesting member attached to a separate nesting item. With respect to box 3009, the at least one electrical system component requires an electric power receptacle located on at least one of the pedestal component and the separate nesting item above. With respect to box 3015, the at least one electrical system component is selected from the group consisting of a lighting fixture, a power receiving receptacle, an electrical device, an electronic device, and a communications device. With respect to box 3015, the power receiving receptacle is connected to a power source having power for providing appropriate voltage and current to power at least one electronic device selected from the group consisting of an AC powered device, an air freshener, a sensor device, a timer, and a low voltage rechargeable electronic device. In addition, the power receiving receptacle provides sufficient voltage and current to recharge a portable low voltage rechargeable device. With respect to box 3005, the pedestal is one of a plurality of pedestals, each of the pedestals having local area network system communications capability for local area network system connection to at least one other the pedestal. [0016.03]

With respect to box 3007, there may be at least two interconnecting pedestal components, each having at least one different characteristic from the other, the different characteristic being selected from the group consisting of dimension, color, shape, design, and function, the at least two interconnecting pedestal components being interchangeable with one another.

With respect to box 3011, the pedestal may include a base and the pedestal component is removably attached to the base with quick release attachment means selected from the group consisting of threads, springy snap latches, pins, screws and twist and lock keys and keyways.

With respect to box 3013, the base may have a circular recess adapted to removably connect to the pedestal component, and the pedestal component may have a circular bottom adapted to removably fit into the circular recess. In other embodiments of the present invention pedestal, the base may have at least one non-circular recess adapted to removably connect to the pedestal component and the pedestal component may have a bottom adapted to removably fit into the at least one non-circular recess. In some embodiments of the present invention pedestal, there is at least one electric power receptacle and it may be located on the base.

With respect to box 3017, the pedestal may further include at least one pedestal component, at least one speaker, or at least one decorative container, and combinations thereof, nestable on the top of the pedestal.

With respect to box 3019, there is at least one electric power receptacle and it may be located on the pedestal component. The pedestal component may further include housing and means for an electrical circuit connection to provide power to at least two electrical system components, at least one of the electrical system components being a light fixture, and at least one of the electrical system components being selected from the group consisting of entertainment components, local area networked components, wide area networked components, communication components and portable electronic devices.

With respect to box 3021, the pedestal may also include at least one activation means of at least one of the electrical system component where the activation means is selected from the group consisting of a motion sensor, a gaseous element detector, a timer, an ambient sensor, and a communications processor.

With respect to box 3023, there may be at least two diverse electrical system components selected from the group consisting of entertainment components, local area networked components, wide area networked components, communications components and portable electronic components. The at least two electrical system components may be powered by AC electricity. In other embodiments of the present invention pedestal, the power may be from a power source selected from the group consisting of batteries, solar cells, fuel cells and combinations thereof.

With respect to box 3025, one of the electrical system components may be an electronic device having a central processor and memory. In other embodiments of the present invention pedestal, one of the electrical system components may be an electronic audio playing device selected from the group consisting of satellite radios, CD players, players with storage media, and personal digital assistants.

With respect to box 3027, one of the electrical system components may be an entertainment component being selected from the group consisting of an electronic audio playing device, a radio, an embodiment that comprises an amplifier, a speaker, and a communications circuit connection, an electronic game apparatus, and a video apparatus.

With respect to box 3029, one of the electrical system components may be a communications component being selected from the group consisting of a wireless phone and base, a data communications transceiver, a data communications receiver, a data communications router, a data communications access point, and a wireless device controller.

With respect to box 3031, one of the electrical system components may be a local area networked component being selected from the group consisting of a wirelessly controlled device, a wireless remote controller, a reduced function device, a full function device, and a high speed data networked device.

With respect to box 3033, one of the electrical system components may be selected from the group consisting of an alarm, a wireless communications device, a wired communications device, an air freshener, and an air deodorizer.

With respect to box 3035, the electrical system component may be selected from the group consisting of air fresheners, air filters, air purifiers and air ionizers. Furthermore. The electrical system component may be operatively integrated with at least one modular component being selected from the group consisting of a motion sensor, a timer, a communications device, an ambient sensor, and a gaseous element detector.

With respect to box 3037, the light fixture includes at least one socket, an on/off means and means for an electrical circuit connection.

Obviously, numerous modifications and variations of the present invention are possible in light of the above suggestions. For example, the sensors described above may be any sensors known or to be developed. As one such example, gaseous element detectors are meant to include sensors for smoke, carbon monoxide, sulfur or other environmental sensor elements. Examples of additional sensors include sensors sensitive to electromagnetic signals (e.g., cameras, motion detectors, proximity detectors, photovoltaic sensors, UV sensors, photoconductive sensors, photodiodes, phototransistors, photoemissive sensors, photoelectric sensors, electromagnetic sensors, microwave receivers, magnetic sensors, magnetoresistive sensors, position sensors, etc.), sensors sensitive to temperature (e.g., thermocouples, thermistors, radiation pyrometers, radiation thermometers, fiber optic temperature sensors, semiconductor temperature sensors, resistance temperature detectors, etc.), sensors sensitive to sound (e.g., microphones, piezoelectric materials, ultrasonic sensors, etc.), sensors sensitive to vibrations, humidity, chemicals (such as concentration of a vapor or gas) or any other type of sensing device capable of generating a detectable signal in response to a stimulus.

Most of the present invention embodiments may be manufactured of commonly available materials. The electrical, processor and communications device circuitry and electrical elements employed are commonly available and known to one skilled in the art, although not in the configuration and arrangement of the present invention.

Although the invention has been described in terms of exemplary embodiments described above and below, it is not limited thereto. Rather, the appended claims should be construed broadly, to include other variants and embodiments of the invention which may be made by those skilled in the art without departing from the scope and range of equivalents of the invention. It is therefore understood that within the scope of the appended claims, the invention may be practiced otherwise than as specifically described herein.

What is claimed is:

1. A decorative container which comprises:
(a) a base;
(b) a top component, including at least a hollow housing, said top component being removably attached to said base;
(c) at least one access opening having a location being selected from the top, side, and bottom of said decorative container where said opening may be in at least one of said base and top component;
(d) at least one electrical system component housing and at least one electrical system component requiring an electric power receptacle located on at least one of said base and said top component above, said at least one electrical system component being selected from the group consisting of a lighting fixture, a power receiving receptacle, an electrical device, an electronic device, and a communications device, said power receiving receptacle being connected to a power source having power for providing appropriate voltage and current to power at least one electronic device selected from the group consisting of an AC powered device, a wireless phone, a timer, a sensor device, and a low voltage rechargeable electronic device; and,
(e) said decorative container is one of a plurality of decorative containers, each of said decorative containers having local area network system communications capability for local area network system connection to at least one other decorative container, said decorative container is selected from the group consisting of urns, pot enclosures, vases, umbrella holders and storage containers.

2. The decorative container of claim 1 wherein said decorative container comprises said power receiving receptacle wherein said power receiving receptacle provides sufficient voltage and current to recharge a portable low voltage rechargeable device.

3. The decorative container of claim 1 wherein said top component is removably attached to said base with quick release attachment means selected from the group consisting of threads, springy snap latches, pins, screws and twist and lock keys and keyways.

4. The decorative container of claim 1 wherein said light fixture includes at least one socket, an on/off means and means for an electrical circuit connection.

5. The decorative container of claim 1 wherein said base has a circular recess adapted to removably connect to said top component, and said top component has a circular bottom adapted to removably fit into said circular recess.

6. The decorative container of claim 1 wherein said base has at least one non-circular recess adapted to removably connect to said top component and said top component has a bottom adapted to removably fit into said at least one non-circular recess.

7. The decorative container of claim 1 wherein there is at least one electric power receptacle and it is located on at least one of said base and said open top component.

8. The decorative container of claim 1 wherein at least one of said base and said top component includes housing and means for an electrical circuit connection to provide power to at least two said electrical system components, at least one of said power-consuming components being a light fixture, and at least one of said power-consuming components being selected from the group consisting of entertainment components, local area networked components, wide area networked components, communications components and portable electronic devices.

9. The decorative container of claim 8 wherein one of said electrical system components is an entertainment component being selected from the group consisting of an electronic audio playing device, a radio, an embodiment that comprises an amplifier, a speaker, and a communications circuit connection, an electronic game apparatus, and a video apparatus.

10. The decorative container of claim 8 wherein one of said electrical system components is a communications component being selected from the group consisting of an embodiment that comprises a phone, a data communications transceiver, a data communications router, a data communications access point, and a wireless remote control unit.

11. The decorative container of claim 8 wherein one of said electrical system components is an electronic device having a central processor and memory.

12. The decorative container of claim 8 wherein one of said electrical system components is an electronic audio playing device selected from the group consisting of a satellite radio, a CD player, a player with storage media, and a personal digital assistant.

13. The decorative container of claim 8 wherein one of said electrical system components is at least one local area networked component being selected from the group consisting of wirelessly controlled device, a reduced function device, a full function device, a timer, and a high speed data networked device.

14. The decorative container of claim 8 wherein there are at least two diverse electrical system components selected from the group consisting of entertainment components, local area networked components, wide area networked components, communications components and portable electronic components.

15. The decorative container of claim 1 wherein said power is from a power source selected from the group consisting of AC electricity, batteries, solar cells, fuel cells and combinations thereof.

16. The decorative container of claim 8 wherein one of said electrical system components is an alarm, an air freshener, an air ionizer, an air purifier, and an air deodorizer.

17. The decorative container of claim 1 wherein said decorative container also includes at least one activation means of at least one of said power-consuming components where said activation means is selected from the group consisting of a motion sensor, a gaseous element detector, a timer, an ambient sensor, and a communications processor.

18. The decorative container of claim 1 wherein said electrical system component is selected from the group consisting of security devices, sensors, bar code readers, radio frequency identification tag readers, and optical character recognition readers.

19. A pedestal adapted to receive a nesting item atop it and adapted to perform at least one additional function in addition to pedestal, which comprises:
(a) a pedestal component having an enclosed structure with a bottom adapted to rest upon a horizontal surface, and having an electrical system component support within said enclosed structure, said pedestal component having a top with one of a male and a female nesting member adapted to receive the other of a male and female nesting member attached to a separate nesting item;
(b) at least one electrical system component requiring an electric power receptacle located on at least one of said pedestal component and said separate nesting item above, said at least one electrical system component being selected from the group consisting of a lighting fixture, a power receiving receptacle, an electrical device, an electronic device, and a communications device, said power receiving receptacle being connected to a power source having power for providing appropriate voltage and current to power at least one electronic device selected from the group consisting of an AC powered device, an air freshener, a sensor device, a timer, and a low voltage rechargeable electronic device; and,
(c) said pedestal is one of a plurality of pedestals, each of said pedestals having local area network system communications capability for local area network system connection to at least one other said pedestal.

20. The pedestal of claim 19 wherein said pedestal is selected from the group consisting of cubic pedestals, square top footprint pedestals, vertically elongated pedestals and horizontally elongated pedestals.

21. The pedestal of claim 19 wherein said power receiving receptacle provides sufficient voltage and current to recharge a portable low voltage rechargeable device.

22. The pedestal of claim 19 wherein there is at least one electric power receptacle and it is located on at least one of said pedestal component and said separate nesting item.

23. The pedestal of claim 19 wherein said pedestal component includes housing and means for an electrical circuit connection to provide power to at least two electrical system components, at least one of said electrical system components being a light fixture, and at least one of said electrical system components being selected from the group consisting of entertainment components, local area networked components, wide area networked components, communication components and portable electronic devices.

24. The pedestal of claim 23 wherein one of said electrical system components is an entertainment component being selected from the group consisting of an electronic audio playing device, a radio, an embodiment that comprises an amplifier, a speaker, and a communications circuit connection, an electronic game apparatus, and a video apparatus.

25. The pedestal of claim 23 wherein one of said electrical system components is a communications component being selected from the group consisting of a wireless phone and base, a data communications transceiver, a data communications receiver, a data communications router, a data communications access point, and a wireless device controller.

26. The pedestal of claim 23 wherein one of said electrical system components is an electronic device having a central processor and memory.

27. The pedestal of claim 23 wherein one of said electrical system components is an electronic audio playing device selected from the group consisting of satellite radios, CD players, players with storage media, and personal digital assistants.

28. The pedestal of claim 23 wherein one of said electrical system components is a local area networked component being selected from the group consisting of a wirelessly controlled device, a wireless remote controller, a reduced function device, a full function device, and a high speed data networked device.

29. The pedestal of claim 19 wherein there are at least two diverse electrical system components selected from the group consisting of entertainment components, local area networked components, wide area networked components, communications components and portable electronic components.

30. The pedestal of claim 19 wherein said power is from a power source selected from the group consisting of batteries, solar cells, fuel cells and combinations thereof.

31. The pedestal of claim 19 wherein one of said electrical system components is selected from the group consisting of an alarm, a wireless communications device, a wired communications device, an air freshener, and an air deodorizer.

32. The pedestal of claim 19 wherein said pedestal also includes at least one activation means of at least one of said electrical system component where said activation means is selected from the group consisting of a motion sensor, a gaseous element detector, a timer, an ambient sensor, and a communications processor.

33. The pedestal of claim 19 wherein said electrical system component is selected from the group consisting of air fresheners, air filters, air purifiers and air ionizers.

34. The electrical system component of claim 33 wherein said component is operatively integrated with at least one modular component being selected from the group consisting of a motion sensor, a timer, a communications device, an ambient sensor, and a gaseous element detector.

35. The pedestal of claim 19, which further includes at least one speaker nestable on said top of said pedestal component.
